(19) United States
(12) Patent Application Publication
(10) Pub. No.: US 2025/0362367 A1
(43) Pub. Date: Nov. 27, 2025

(54) TISSUE MIMICKING MATERIALS AND GRAVID ABDOMEN PHANTOMS THEREOF

(71) Applicants: Dafna Sussman, East York (CA); Mitchell Lee, Kanata (CA)

(72) Inventors: Dafna Sussman, East York (CA); Mitchell Lee, Kanata (CA)

(21) Appl. No.: 18/851,653

(22) PCT Filed: Mar. 31, 2022
(86) PCT No.: PCT/CA2023/050447

§ 371 Date: Sep. 26, 2024

Related U.S. Application Data
(60) Provisional application No. 63/326,265, filed on Mar. 31, 2022.

(51) Int. Cl. G01R 33/58; G01R 33/30; G01R 33/483

(52) U.S. Cl. CPC G01R 33/58; G01R 33/307; G01R 33/483

(57) ABSTRACT

The present disclosure relates to gravid abdomen phantoms and tissue mimicking materials that can be used in preparing phantoms. Specifically, the present disclosure relates to brain grey and white matter mimicking material, muscle tissue mimicking material, placenta mimicking material, and amniotic fluid mimicking compositions, and phantoms thereof. The present disclosure further relates to methods and uses of the materials and phantoms of the present application. The materials and phantoms of the present disclosure can be combined to prepare a fetal phantom of the disclosure. The present disclosure also relates to a motion assembly that can be used with the phantoms of the disclosure.

### CROSS-REFERENCE TO RELATED APPLICATIONS

The present disclosure claims the benefit of priority from U.S. patent application No. 63/326,265, filed Mar. 31, 2022, the contents of which are incorporated herein by reference in their entirety.

### FIELD

The present disclosure relates generally to gravid abdomen phantoms. Specifically, the present disclosure relates to materials that mimic tissues such as grey and white brain matter, muscle, placenta, and amniotic fluid. The present disclosure further relates to phantoms comprising the tissue mimicking materials of the present disclosure such as brain phantom, placenta phantom, body phantom, and fetal phantom. The present disclosure also relates to gravid abdomen phantoms comprising one or more phantoms of the present disclosure and a motion assembly. The present disclosure also relates to methods and uses thereof.

### INTRODUCTION

The following is not an admission that anything discussed below is part of the prior art or part of the common general knowledge of a person skilled in the art.

As a prenatal fetus develops, it exhibits relatively erratic behaviour through the movement of its limbs, head, and body through twisting, extending, and wiggling. While it may be difficult to quantify information such as the angle of the joints, force exerted, speed of contraction, and the like, the frequency of such movements are expected to be about 14.8 minutes per 10 movements and mostly lasting under 3 seconds in a third trimester fetus [1, 2]. It has further been observed that the head of a prenatal fetus may undergo a maximum displacement and speed of 55 mm and 100 mm/s respectively with 30° rotation. Furthermore, although a prenatal fetus cannot breathe due to its fluid filled lungs, it still experiences some respiratory-like movements. The average fetal respiratory rate at 28-39 weeks of gestation is 43 breaths/min, creating a maximum displacement of 3-8 mm in the abdomen [3,4].

The womb is also a lively area because of maternal activity. For example, with the gastrointestinal (GI) tract in the neighboring area, vibrations from peristalsis can generate a series of 2 to 3 waves of contractions simultaneously [5]. These waves exist in different regions of the tract with about 3 waves occurring per minute and lasting 9 seconds in length [5]. Concurrent with the peristalsis, there are also segmentation contractions which occur once per 3 minutes [6]. However, the magnitude of the effect on the womb could not be determined through existing literature.

Another source of motion within the womb is through maternal respiration which is caused from the diaphragm pushing downwards on the uterus. For example, the median breathing rate for 36-week pregnant women is 17 breaths per minute [7]. A separate study with varying ages from 25-35 weeks gestational age determined the maximum displacement of a fetal heart from maternal respiration motion is between 0.5 mm and 2.3 mm, with a median of 1.8 mm [8].

Due to the movements described above, motion artifacts are commonly observed during imaging of a prenatal fetus, such as during a magnetic resonance imaging (MRI) scan, which can severely degrade the image quality. Accordingly, there exists a need for simulating the physiological motion of a prenatal fetus in the gravid abdomen which may be used for testing imaging modalities for improving resulting image quality.

Clinical examination of the gravid abdomen can include high-quality measurements using a variety of methods including, for example, magnetic resonance imaging (MRI) for brain tissue, muscle tissue, and placenta, and nuclear magnetic resonance (NMR) for amniotic fluid. Despite the utility of these modalities, many issues persist in fetal, placental, and amniotic analysis that need to be addressed to improve diagnostic power and general healthcare quality. Despite these many advantages, the accuracy of MRI in obstetric settings is limited by motion artifacts from frequent and spontaneous fetal gross body movement, maternal movement, and passive placental movement [11]-[13].

Optimization of MRI is important for acquiring high-quality images during examination. This can be achieved rapidly and most cost-efficiently with the use of imaging phantoms, which are devices that mimic the anatomy and physiology of interest and replace the need for human participants. Phantoms are used as opposed to human participants because they are an inexpensive way to validate accuracy and assess repeatability and reproducibility of measurements without having to expose a participant to potential risk [9]. MRI phantoms have become a useful tool to characterize physical performance of MRI machines, characterize time-related changes in the performance of MRI systems, and develop authentication methods in MRI for clinical practice [9].

MRI test phantoms are often composed of TM (tissue-mimicking) materials such as water, fat, and agarose gels so that their electromagnetic properties can mimic those of the target tissue [15]. MR sequences can map quantitative and qualitative biomarkers; however, they require careful standardization of protocols and development of phantoms to validate in-vivo measurement, and to assess repeatability and reproducibility of measurements [9][16]. Validation and quantification of MR artifact correction techniques often needs a human-like phantom that has electromagnetic and chemical properties that mimic in-vivo properties [17]. Many available phantoms, however, lack physiological motion capabilities and realism; poorly reflecting the shape, size, or tissue and contrast characteristics of human tissues [18].

Aqueous phantoms are used for quality assurance in testing MRI systems and analysis of lower-field MRI. Materials used in these phantoms also have approximately equal relaxation times which is not suitable for mimicking human tissue. Additionally, such aqueous phantoms are not able to maintain their form without the use of an enclosing container [12]. The use of such an enclosure creates an artificial boundary to the anatomical shape, which is visible on the MR image, and prevents recreating realistic, human-like images. Therefore, these homogeneous aqueous phantoms are not suitable for mimicking human experiments and are not typically viable to characterize tissue interactions at high-field strengths.

On the other hand, gel-like phantoms are more suitable for human tissue phantoms as they can be made more rigid and shaped as needed, without needing an enclosing container. Anthropomorphic gel phantoms are heterogeneous and are useful for applications that require analysis of RF field interaction with biological tissues as well as comparison to human experiments [13]. Anthropomorphic MRI brain phantoms are uncommon, as most phantoms are homogeneous and very simple in structure. Of the phantoms studied, available models use either Polyvinyl alcohol (PVA) (Chen, et.al., Surry, et.al.) or agar/agarose (Rice, et.al., Khan, et.al., Gallas, et.al., Kozana, et.al., Altermatt, et.al.) [19][20][21][22][23][24]. PVA is a polymer that is synthesized from polyvinyl acetate by hydrolysis [20]. When PVA solutions are frozen at a specified temperature, freeze-thaw cycles turn the liquid PVA into a gel known as polyvinyl alcohol cryogel (PVA-C) [19]. In phantom studies, soft tissue phantoms have been made using this material because its mechanical properties and water content are similar to that of soft tissues including heart, breast, and brain [19]. However, PVA is difficult to use for fabrication of large phantoms because a sufficient degree of solidification can only be achieved through several freeze/thaw cycles [10]. Agar and agarose are more widely used as phantom material that is prepared using high thermal treatment from 80-100° C. [14]. This material has success in mimicking T2 of human tissue and T1 can be modified using paramagnetic additives [14]. These materials are commonly used homogeneously, which is suitable for quality assurance but does not represent all tissues of the brain. For example, Chen et.al., 2012 noted that their phantom only allowed for homogeneously simulated tissue with discrete punctuate insertions.

Carrageenan (CG) has been used in tissue regeneration and drug delivery. CG gels are much more elastic and crack resistant than agar gels. This allows more advantageous uses in the creation of large-scale phantoms that are moldable and versatile in shape [10]. Since CG gel has a sturdy molecular structure, it can form versatile anatomical shapes for phantoms. However, few carrageenan phantoms have been developed for MRI and none has shown great promise as an alternative to the traditional agar phantoms.

Fetal magnetic resonance imaging (MRI) is the standard for accurately diagnosing placental abnormalities suspected on ultrasound. Development of new MRI sequences optimized for fetal-placental imaging, however, is dependent on extensive testing. The current limitation with imaging the placenta is due to its passive range of motion due to fetal and maternal movement causing motion artifacts [30]. Normally this is accounted for with gestation-specific sequences that consider and correct for maternal, fetal, and placental motion. To develop such pulse sequences, volunteers are used to monitor the motion to be corrected and to test the sequence for efficiency. Using human volunteers is challenging due to the long scan times and high cost of participant recruitment. The ideal alternative is to use an anthropomorphic phantom of the human placenta that simulates placental anatomy and tissue properties in the womb. There is currently no available placental phantom that can achieve all of these objectives. Current phantoms utilize a simplified placenta structure and use an aqueous medium. Aqueous phantoms carry the disadvantage of requiring a container to maintain their form, resulting in boundary effects in the MR image which can cause artifacts and errors in relaxation properties. Previous studies of CG-based phantom materials by Hattori et al. used GdCl₃ as T₁ modifier. However, the findings of Hattori provide that the phantom cannot mimic the relaxation times of the human placenta. Thus, there is a need to develop a phantom of homogenous structure to avoid errors of this kind and be able to correctly simulate human gestational anatomy and imaging properties.

Similarly, MRI has been suggested as a complementary diagnostic tool for ultrasonography for maternal-fetal imaging due to its advantages, including high soft-tissue contrast, three-dimensional (3D) imaging, and the ability to differentiate blood from other fluid [57], [58]. Despite these many advantages, the accuracy of MRI in obstetric settings is limited by motion artifacts from frequent and spontaneous fetal gross body movement [59]-[61]. The commonly used tissue mimics for medical imaging phantoms, PVA-C and agar, have several shortcomings [62]. They have a limited shelf-life and must be carefully stored to prevent water loss and to limit mold growth over time [63]-[67]. Moreover, they easily deform and permanently lose their shape upon application of an external force. Such structural deformation renders these phantoms unusable for testing in anatomical imaging. For motion phantoms to simulate particular motions and to bear mechanical stress from the actuators, the phantom material needs sufficient strength. The currently available tissue-mimicking phantoms were designed to simulate only specific organs, such as the heart, lungs, brain, and kidney. There is currently no single MR-compatible anthropomorphic phantom of the entire pregnant gravid abdomen mimicking gross fetal body movements, including stretching, kicking, and twisting

Previous studies using carrageenan material did not produce the relaxation times of muscle tissues.

Another aspect of gravid abdomen mimicking is amniotic fluid. It can be readily understood that the process of retrieving amniotic fluid from pregnant persons, i.e. amniocentesis, is an invasive procedure. Thus, there is a need to develop an artificial amniotic fluid in order to use for example as a model in the development of medical techniques such as magnetic resonance spectroscopy (MRS). Due to the scarcity of actual amniotic fluid, currently, a full chemical profile has not been modeled.

### SUMMARY

This section is provided to introduce the reader to the more detailed discussion to follow. This section is not intended to limit or define any claimed or as yet unclaimed subject matter. One or more items of claimed subject matter may reside in any combination or sub-combination of the elements or process steps disclosed in any part of this document including its claims and figures.

It has been shown that a concentration of about 20 μmol/kg to about 45 μmol/kg GdCl₃, optionally about 38 μmol/kg, in a carrageenan-based material based on the total weight of the material mimics the T₁ and T₂ relaxation times, the conductivity of grey brain matter.

Further, it has been shown that a concentration of about 80 μmol/kg to about 120 μmol/kg GdCl₃, optionally about 95 μmol/kg, in a carrageenan-based material based on the total weight of the material mimics the T₁ and T₂ relaxation times, the dielectric constant and the conductivity of white brain matter.

It has also been shown herein that a concentration of about 15 μmol/kg to about 60 μmol/kg GdCl₃, optionally about 20 μmol/kg to about 50 μmol/kg, in a carrageenan-based material based on the total weight of the material mimics the T₁ and T₂ relaxation times, and the conductivity of muscle tissue.

It has also been shown herein that a concentration of about 0.01 mM to about 0.05 mM MnCl₂, optionally about 0.032 mM, in a carrageenan-based material based on the total weight of the material mimics the T₁ and T₂ relaxation times, the dielectric constant and the conductivity of placenta tissue.

Further, it has been shown that a composition of the present disclosure mimics the NMR spectrum of natural amniotic fluid, the composition comprising about 10 mg to about 13 mg citrate;
about 38 mg to about 44 mg glucose;
about 100 mg to about 106 mg lactic acid;
about 2 mg to about 3 mg alanine;
about 1.3 mg to about 2 mg cystine;
about 0.2 mg to about 0.3 mg ethanolamine;
about 0.3 mg to about 1 mg glutamic acid;
about 0.8 mg to about 1.4 mg glycine;
about 0.4 mg to about 1 mg histidine;
about 1.2 mg to about 2 mg lysine;
about 1 mg to about 1.7 mg proline;
about 3 mg to about 3.6 mg glutamine;
about 0.5 mg to about 1.1 mg serine;
about 1 mg to about 1.8 mg taurine;
about 1 mg to about 1.7 mg threonine;
about 1 mg to about 1.8 mg valine;
about 0.7 mg to about 1.5 mg creatine;
about 10 mg to about 16 mg calcium formate; and
balance water.

Based on the materials and compositions described herein, a fetal phantom has been made using the brain white matter mimicking material, the brain grey matter mimicking material, and the muscle tissue mimicking material of the present disclosure. Further, the fetal phantom was used in combination with the placenta mimicking material and the amniotic fluid mimicking material of the present disclosure to prepare a fetus modelling system. Additionally, a motion assembly was used in combination with the fetal phantom or the fetus modelling system to prepare a gravid abdomen phantom. Thus, it has been shown that one or more of the materials and compositions of the present application can be used together to create tissue phantoms as needed, and that the motion assembly can be added to mimic fetal movement.

It has been shown that herein that the specific concentrations of the components of the compositions of the present application can be optimized to achieve desired target relaxometry properties.

In one aspect, the present disclosure includes a gravid abdomen phantom comprising:
a tank that is insertable into a bore of a magnetic resonance imaging scanner;
a motion assembly; and
a fetal phantom positioned in the tank and mounted to the motion assembly, wherein the motion assembly is operable to simulate the movement of a prenatal fetus.

In another aspect, the present disclosure includes a brain grey matter mimicking material comprising about 1 w/w % to about 6 w/w % carrageenan;
about 0.3 w/w % to about 1 w/w % agarose;
about 20 μmol/kg to about 45 μmol/kg GdCl₃ based on the total weight of the brain grey matter mimicking material;
about 0.5 w/w % to about 5 w/w % NaCl;
about 0.01 w/w % to about 0.06 w/w % NaN₃; and balance water.

In another aspect, the present disclosure includes a brain grey matter mimicking material comprising
about 1 w/w % to about 2 w/w % carrageenan,
about 0.3 w/w % to about 1 w/w % NaCl,
about 0.01 w/w % to about 0.06 w/w % glutaraldehyde,
at least one of MnCl₂ or agarose, and
balance water; and
wherein the MnCl₂, if present, is present at a concentration of about 55 μM or less than 55 μM, and wherein the agarose, if present, is present at a concentration of about 5 w/w % or less than 5 w/w %.

In another aspect, the present disclosure includes a brain white matter mimicking material comprising
about 1 w/w % to about 6 w/w % carrageenan;
about 0.7 w/w % to about 1.5 w/w % agarose;
about 80 μmol/kg to about 120 μmol/kg GdCl₃ based on the total weight of the brain white matter mimicking material;
about 0.1 w/w % to about 2.5 w/w % NaCl;
about 0.01 w/w % to about 0.06 w/w % NaN₃; and
balance water.

In another aspect, the present disclosure includes a brain white matter mimicking material comprising
about 0.3 w/w % to about 1 w/w % NaCl,
about 0.01 w/w % to about 0.06 w/w % glutaraldehyde,
at least one of MnCl₂ and agarose, and
balance water; and
wherein the MnCl₂, if present, is present at a concentration of about 150 μM or less than 150 μM, and wherein the agarose, if present, is present at a concentration of about 5 w/w % or less than 5 w/w %.

In another aspect, the present disclosure includes a brain grey matter mimicking material of the present disclosure or a brain white matter mimicking material of the present disclosure for use in the preparation of a brain phantom.

In another aspect, the present disclosure includes a brain grey matter mimicking material of the present disclosure or a brain white matter mimicking material of the present disclosure for use in magnetic resonance imaging (MRI) measurement.

In another aspect, the present disclosure includes a use of a brain grey matter mimicking material of the present disclosure or a brain white matter mimicking material of the present disclosure in the preparation of a brain phantom.

In another aspect, the present disclosure includes a brain phantom comprising a brain grey matter mimicking material of the present disclosure and/or a brain white matter mimicking material of the present disclosure.

In another aspect, the present disclosure includes a method of preparing a brain matter mimicking material, the method comprising
combining carrageenan, agarose, NaCl, GdCl₃, and NaN₃ in water to obtain a homogenous solution, optionally the combining is carried out with heating and/or stirring;
cooling the homogenous solution;
heating the homogenous solution to about 75° C. to about 85° C. under vacuum; and
cooling the homogenous solution to room temperature.

In another aspect, the present disclosure includes a placenta mimicking material comprising
about 1 w/w % to about 6 w/w % carrageenan;
about 0.01 mM to about 0.05 mM MnCl₂;
about 0.3 w/w % to about 1 w/w % NaCl;
about 0.01 w/w % to about 0.06 w/w % of an antiseptic agent, optionally selected from glutaraldehyde, NaN₃, NaNO₃, and combinations thereof; and balance water.

In another aspect, the present disclosure includes a placenta mimicking material comprising
about 2 w/w % to about 4 w/w % carrageenan,
about 0.3 w/w % to about 1 w/w % NaCl,
about 0.01 w/w % to about 0.06 w/w % glutaraldehyde,
at least one of MnCl₂ or agarose, and
balance water; and
wherein the MnCl₂, if present, is present at a concentration of about 2 μM to about 50 μM, and wherein the agarose, if present, is present at a concentration of about 0.01 w/w % to about 3.5 w/w %.

In another aspect, the present disclosure includes a placenta mimicking material of the present disclosure for use in the preparation of a placenta phantom.

In another aspect, the present disclosure includes a placenta mimicking material of the present disclosure for use in a magnetic resonance imaging (MRI) measurement.

In another aspect, the present disclosure includes a use of a placenta mimicking material of the present disclosure in the preparation of a placenta phantom.

In another aspect, the present disclosure includes a use of a placenta mimicking material of the present disclosure in a magnetic resonance imaging (MRI) measurement.

In another aspect, the present disclosure includes a placenta phantom comprising a placenta mimicking material of the present disclosure.

In another aspect, the present disclosure includes a muscle tissue mimicking material comprising
about 1 w/w % to about 6 w/w % carrageenan;
about 1 w/w % to about 5 w/w % agarose;
about 15 μmol/kg to about 60 μmol/kg GdCl₃ based on the total weight of the muscle tissue mimicking material;
about 0.1 w/w % to about 5 w/w % NaCl;
about 0.01 w/w % to about 0.06 w/w % NaN₃; and
balance water.

In another aspect, the present disclosure includes a muscle tissue mimicking material of the present disclosure for use in the preparation of a body phantom.

In another aspect, the present disclosure includes a muscle tissue mimicking material of the present disclosure for use in a magnetic resonance imaging (MRI) measurement.

In another aspect, the present disclosure includes a use of a muscle tissue mimicking material of the present disclosure in the preparation of a body phantom, optionally a fetal body phantom.

In another aspect, the present disclosure includes a use of a muscle tissue mimicking material of the present disclosure in a magnetic resonance imaging (MRI) measurement.

In another aspect, the present disclosure includes a body phantom comprising the muscle tissue mimicking material of the present disclosure.

In another aspect, the present disclosure includes an amniotic fluid mimicking composition comprising per 100 mL of the composition about 10 mg to about 13 mg citrate;
about 38 mg to about 44 mg glucose;
about 100 mg to about 106 mg lactic acid;
about 2 mg to about 3 mg alanine;
about 1.3 mg to about 2 mg cystine;
about 0.2 mg to about 0.3 mg ethanolamine;
about 0.3 mg to about 1 mg glutamic acid;
about 0.8 mg to about 1.4 mg glycine;
about 0.4 mg to about 1 mg histidine;
about 1.2 mg to about 2 mg lysine;
about 1 mg to about 1.7 mg proline;
about 3 mg to about 3.6 mg glutamine;
about 0.5 mg to about 1.1 mg serine;
about 1 mg to about 1.8 mg taurine;
about 1 mg to about 1.7 mg threonine;
about 1 mg to about 1.8 mg valine;
about 0.7 mg to about 1.5 mg creatine;
about 10 mg to about 16 mg calcium formate; and
balance water;
wherein the composition has a pH of about 6.8 to about 7.8, about 7 to about 7.6, about 7.2 to about 7.4, about 7.2 to about 7.3, or about 7.25; and
wherein the composition has an osmolality of about 175 mM to about 275 mM, about 200 mM to about 250 mM, about 215 mM to about 235 mM, about 220 mM to about 230 mM, or about 225 mM.

In another aspect, the present disclosure includes an amniotic fluid mimicking composition of the present disclosure for use in the preparation of an artificial amniotic fluid.

In another aspect, the present disclosure includes a use of an amniotic fluid mimicking composition of the present disclosure in the preparation of an artificial amniotic fluid.

In another aspect, the present disclosure includes a use of an amniotic fluid mimicking composition of the present disclosure in a nuclear magnetic resonance measurement.

In another aspect, the present disclosure includes a brain mimicking material for use in the mimicking a T1 relaxation time and/or a T2 relaxation time of a brain tissue. For example, the brain mimicking material can mimic an average of T1 relaxation time and T2 relaxation time of a brain tissue. For example, the brain mimicking material can mimic the T1 relaxation time or the T2 relaxation time of a brain tissue. In some embodiments, the brain tissue is adult brain tissue. In some embodiments, the brain tissue is fetal brain tissue.

In another aspect, the present disclosure includes a fetal phantom comprising
a brain phantom comprising a brain grey matter mimicking material and a brain white matter mimicking material; and
a body phantom comprising a muscle tissue mimicking material.

In another aspect, the present disclosure includes a fetus modelling system comprising
a fetal phantom;
a placenta phantom comprising a placenta mimicking material; and
an artificial amniotic fluid comprising an amniotic fluid mimicking composition.

In another aspect, the present disclosure includes a motion assembly for a gravid abdomen phantom having a fetal phantom, wherein the motion assembly comprises:
a motion platform for supporting the fetal phantom;
at least one actuator for controlling movement of the motion platform; and
at least one driving linkage extending between the at least one actuator and the motion platform,
wherein the motion platform is mounted to a tank for housing the fetal phantom and is insertable into a bore of a magnetic resonance imaging scanner.

In another aspect, the present disclosure includes a gravid abdomen phantom comprising:
a motion assembly; and
a fetal phantom mounted to the motion assembly,
wherein the motion assembly is operable to simulate the movement of a prenatal fetus.

### DRAWINGS

The embodiments of the disclosure will now be described in greater detail with reference to the attached drawings in which:

FIG. 1A shows a perspective view of an embodiment of a gravid abdomen phantom;

FIG. 1B shows a perspective side view of a motion assembly within a tank of the gravid abdomen phantom of FIG. 1A;

FIG. 1C shows a perspective front view of the motion assembly within the tank of FIG. 1B;

FIG. 1D shows a perspective view of a motion platform of the motion assembly of FIG. 1C;

FIG. 1E shows a top view of the motion platform of FIG. 1D;

FIG. 1F shows a side view of the motion platform of FIG. 1D;

FIG. 1G shows a perspective view of a central brace of the motion assembly of FIG. 1C;

FIG. 1H shows a top view of the central brace of FIG. 1G;

FIG. 1I shows a side view of the central brace of FIG. 1G;

FIG. 1J shows a perspective view of a corner brace of the motion assembly of FIG. 1C;

FIG. 1K shows a top view of the corner brace of FIG. 1J;

FIG. 1L shows a side view of the corner brace of FIG. 1J;

FIG. 1M shows a perspective view of a planar brace of the motion assembly of FIG. 1C;

FIG. 1N shows a top view of the planar brace of FIG. 1M;

FIG. 1O shows a side view of the planar brace of FIG. 1M;

FIG. 1P shows a perspective view of a carriage of the motion assembly of FIG. 1C;

FIG. 1Q shows a top view of the wedge of FIG. 1P;

FIG. 1R shows a front view of the wedge of FIG. 1P;

FIG. 1S shows a side view of the wedge of FIG. 1P;

FIG. 2A shows a perspective view of an alternative embodiment of a motion assembly;

FIG. 2B shows an enlarged portion of the motion assembly of FIG. 2A;

FIG. 2C shows a perspective view of an alternative embodiment of a gravid abdomen phantom with the motion assembly of FIG. 2A;

FIG. 2D shows a perspective view of the gravid abdomen phantom of FIG. 2C;

FIG. 2E shows a top view of the gravid abdomen phantom of FIG. 2C, shown with a base of the motion assembly transparent;

FIG. 2F shows a perspective view of the gravid abdomen phantom of FIG. 2C positioned within a bore of an MRI scanner;

FIG. 3 shows MRI image of CG samples using Medviso segment program.

FIG. 4A shows T1 of CG Grey matter samples vs. concentration of NaCl between 1.04%-2.54%.

FIG. 4B shows T2 of CG Grey matter samples vs. concentration of NaCl between 1.04%-2.54%.

FIG. 5A shows T1 of CG White matter samples vs. concentration of NaCl between 0.459%-1.209%.

FIG. 5B shows T2 of CG White matter samples vs. concentration of NaCl between 0.459%-1.209%.

FIG. 6A shows T1 of CG White matter samples vs. concentration of GdCl₃ between 75 μmol/kg-95 μmol/kg.

FIG. 6B shows T2 of CG White matter samples vs. concentration of GdCl₃ between 75 μmol/kg-95 μmol/kg.

FIG. 7 shows dielectric constant measurement of CG white matter samples (1-3) using Keysight Network Analyzer in frequency range 10-200.

FIG. 8 shows dielectric constant measurement of CG grey matter samples (1-3) using Keysight Network Analyzer in frequency range 10-200.

FIG. 9 shows MR images of samples 1-50 (A) and samples 51-90 (B) taken using inversion recovery sequence, and sample calculation of the fit used to extract the resulting T1 relaxation time in the Segment software (C). MR image of samples 1-50 (D) and samples 51-90 (E) taken using multi-echo spin echo sequence, and sample calculation of the fit used to extract the resulting T2 relaxation time in the Segment software (F).

FIG. 10 shows a four step summary procedure for the creation of the placenta mould. Sample segmentation of the placenta from one slice in the coronal plane of fetal MRI scan highlighted in green (A). Segmentation is exported as 3D model file format (STL) to be open and viewed in modelling software (B). Negative mould consisting of two pieces created from 3D model in Blender software (C). Mould is printed using Zortax m300 filament-based 3D printer (D).

FIG. 11 shows sample inversion recovery slice of the placenta phantom (A). The selected region of interest (ROI) is shown highlighted in pink. The associated ROI area and signal intensity are displayed under the title. Sample calculations of the fit used to extract the resulting (B) T1 and (C) T2 relaxation times in the Segment software.

FIG. 12 shows T1 relaxation rate (ms⁻¹) for MnCl₂ in varying concentrations of agarose from 0-1.5 w/w %.

FIG. 13 shows T2 relaxation rate (ms⁻¹) for MnCl₂ in varying concentrations of agarose from 0-1.5 w/w %.

FIG. 14 shows T1 relaxation rate (ms⁻¹) for agarose in varying concentrations of MnCl₂ from 0-0.5 mM.

FIG. 15 shows T2 relaxation rate (ms⁻¹) for agarose in varying concentrations of MnCl₂ from 0-0.5 mM.

FIG. 16 shows a graphical representation of relaxation empirical formula describing the relationship between the T1 and T2 values for varying concentrations of MnCl₂ and agarose. The circular points represent the calculated relaxation times utilizing the formulas, and the star (*) points represent the measured relaxation time. Each vertical line represents the change in relaxation time over varying concentrations of MnCl₂ for each respectively labelled concentration of agarose. The dashed lines represent the change in relaxation time over varying concentrations of agarose for each concentration of MnCl₂.

FIG. 17 shows segmented placenta labelled Placenta 1. (A) Fetal facing side of the placenta. Note the longer height compared to the width. (B) Maternal facing side of the placenta. (C) Side view showing the thickness of the placenta. (D) Non uniform shape extruding from the side of the placenta.

FIG. 18 shows segmented placenta labelled Placenta Model 2. (A) Fetal facing side of the placenta. Note the more uniform diameter when compared to Model 2 (B) Maternal facing side of the placenta. (C) Side views showing the thickness of the placenta. (D) Additional side view of the placenta.

FIG. 19 shows (A, C) Interior view of the bottom section of the mould. (B, D) Interior view of the top section of the mould. The three holes seen are the infill holes.

FIG. 20 shows bottom of the (A) bottom section and (B) top section of the mould. Side views of the (C) bottom section and (D) top section of the mould.

FIG. 21 shows a 3D printed placenta mould. (A) Interior view of the bottom section (left) and top section (right) of the printed mould. (C-D) Assembled mould sealed together with silicone adhesive.

FIG. 22 shows resulting placenta phantom cast. (A) Placenta cast removed from 1 piece of the mould. (B-C) Side views of the placenta phantom showing the texture kept from the mould and 3D model. (D) Fetal facing side of the placenta.

FIG. 23 shows slices 1-5 of the placenta phantom using an inversion recovery sequence using the Skyra 3.0 T scanner. Slice 1 shows the maternal facing side of the placenta, and slice 5 shows the fetal facing side of the placenta. The resulting IR image and associated T1 maps are shown displaying the homogeneity of the phantom.

FIG. 24 shows slices 1-5 of the placenta phantom using a multi-echo spin echo sequence using the Skyra 3.0 T scanner. Slice 1 shows the maternal facing side of the placenta, and slice 5 shows the fetal facing side of the placenta. The resulting ME SE image and associated T2 maps are shown displaying the homogeneity of the phantom.

FIG. 25 shows MRI image of some CAGN samples acquired with (a) inversion recovery sequence and (b) multi-echo sequence.

FIG. 26 shows relaxation times of muscle CAGN phantoms relative to the concentrations of gadolinium trichloride and agarose. (a) T1 of muscle CAGN phantoms vs. gadolinium trichloride concentration. (b) T2 of muscle CAGN phantoms vs. gadolinium trichloride concentration. (c) T1 of muscle CAGN phantom vs. agarose concentration. (d) T2 of muscle CAGN phantom vs. agarose concentration

FIG. 27 shows dielectric properties of muscle CAGN phantom relative to various chemical concentrations. (a) Dielectric constant of muscle CAGN phantom relative to gadolinium trichloride concentration. (b) Conductivity of muscle CAGN phantom relative to gadolinium trichloride concentration. (c) Dielectric constant of muscle CAGN phantom relative to agarose concentration. (d) Conductivity of muscle CAGN phantom relative to agarose concentration. (e) Dielectric constant of muscle CAGN phantom relative to NaCl concentration. (f) Conductivity of muscle CAGN phantom relative to NaCl concentration.

FIG. 28 shows a 3D reconstructed model of the gross body of 35-week old fetus (a) right (b) left (c) front (d) back.

FIG. 29 shows a 3D reconstructed model of an entire brain of a 35-week old fetus (a) side (b) front (c) bottom.

FIG. 30 shows a 3D reconstructed model of the brain of a 35-week old fetus except gray matter (a) side (b) front (c) bottom.

FIG. 31 shows mold design for the gross body phantom of a 22-week old fetus (a) left and center parts assembled (b) right part (c) entire parts assembled, injection holes viewed from the top.

FIG. 32 shows mold design for the gross body phantom of a 35-week old fetus (a) top right part (b) top right part assembled with other inner parts (c) top left part (d) top left part assembled with other inner parts (e) bottom parts.

FIG. 33 shows assembled gross body phantom mold with injection holes (a) side view (b) top view.

FIG. 34 shows a 3D reconstructed model of lateral ventricle (a) right (b) left (c) front (d) back (e) top (f) bottom.

FIG. 35 shows a white matter phantom casting mold (a) top part (b) top part with scaffolding (c) bottom part (d) top part and bottom part assembled without scaffolding (e) transparent model of the previous image (f) side view of the top part with scaffolding (f) side view of top part and bottom part assembled without scaffolding (two injection holes are shown) (g) transparent model of the previous image.

FIG. 36 shows a white matter phantom shell (a) before dividing (b) top part of the shell (c) bottom part of the shell (d) interior of top part (d) interior of bottom part.

FIG. 37 shows a gray matter phantom casting mold (a) top part (b) bottom part (c) assembled parts with injection holes (d) transparent model of the previous image.

FIG. 38 shows a gray matter phantom shell (a) before dividing (b) top part of the shell (c) bottom part of the shell (d) interior of top part (d) interior of bottom part.

FIG. 39 shows 1D 700 MHz ¹H NMR spectrum of artificial amniotic fluid, after lyophilization and reconstitution in D₂O.

FIG. 40 shows 1D 700 MHz ¹H NMR spectrum of artificial amniotic fluid with magnifications at ranges across the spectra of interest.

FIG. 41 shows 1D 700 MHz ¹H NMR spectrum of artificial amniotic fluid from 0-5.0 ppm.

FIG. 42 shows magnified 1D ¹H NMR spectrum showing metabolites of artificial amniotic fluid within ranges of 0.8-2.8 ppm. Assignments of peaks: 1. Valine, 2. Lactic Acid, 3. Alanine, 4. Lysine, 5. Proline, 6. Glutamine, 7. Citrate.

FIG. 43 shows magnified 1D ¹H NMR spectrum showing metabolites of artificial amniotic fluid within ranges of 2.8-4.0 ppm. Assignments of peaks: 8. Cysteine, 9. Taurine, 10. Threonine, 11. Glycine, 12. Glutamic Acid**, 13. Ethanolamine, 14. Serine, 15. Creatinine, 17. Histidine**.

FIG. 44 shows Magnified 1D ¹H NMR spectrum showing metabolites of artificial amniotic fluid within ranges of 3.75-4.25 ppm. Assignment of peaks: 2. Lactic Acid, 14. Serine, 15. Creatinine, 16. Glucose **.

FIG. 45 shows magnified 1H NMR spectrum showing metabolites of artificial amniotic fluid within ranges of 5-8.7 ppm. Peak assignment: 18. Calcium Formate (qNMR standard analyte).

FIG. 46 shows 2D ¹H NMR 700 Mhz TOCSY Spectra showing metabolites of artificial amniotic fluid within aliphatic regions.

FIG. 47 shows normalized concentrations of literature data collected from studies utilized to create artificial amniotic fluid. Experimental concentration averages derived from NMR analysis are shown using a ‘dot’ as they appear along the distribution of literature values. Experimental results for Glutamic Acid and Histidine were not quantifiable and are, therefore, shown as 0 on this graph.

FIG. 48 depicts the concentrations of each metabolite used in the artificial amniotic fluid as they appear in the literature (blue) versus in the experiment (orange). Metabolites that were found to be statistically significantly different in their concentration spreads are indicated with an asterisk above their respective bars.

FIG. 49 shows the distribution of concentrations of proline as they appear in the literature and through experimental values. Here, proline is studied across four different studies, and their normalized values are compared to those found experimentally. This metabolite was found to be statistically different from the literature values, (p=0.005, a=0.05). A) Bland-Altman plot representing the concentrations (umol/L) of proline in the literature studied. The upper and lower limits are shown to approximate whether experimental concentrations fall within this region. Here, experimental average falls below lower limits of the literature data spread. B) Box and whisker plot of spread in literature data in comparison to experimental average derived.

FIG. 50 shows the distribution of citrate concentrations as they appear in the literature and through experimental values. Here, citrate is studied across three different studies, and their normalized values are compared to those found experimentally. This metabolite was found to be statistically different from the literature values, (p=0.007, a=0.05). A) Bland-Altman plot representing the concentrations (umol/L) of citrate in the literature studied. The upper and lower limits are shown to approximate whether experimental concentrations fall within this region. Here, experimental average falls above upper limits of the literature data spread. B) Box and whisker plot of spread in literature data in comparison to experimental average derived.

FIG. 51 shows the distribution of glucose concentrations as they appear in the literature and through experimental values. Here, glucose is studied across three different studies, and their normalized values are compared to those found experimentally. This metabolite was found to be statistically different from the literature values, (p=0.04993, a=0.05). A) Bland-Altman plot representing the concentrations (umol/L) of glucose in the literature studied. The upper and lower limits are shown to approximate whether experimental concentrations fall within this region. Here, experimental average falls above upper limits of the literature data spread. B) Box and whisker plot of spread in literature data in comparison to experimental average derived.

FIG. 52 shows the distribution of alanine concentrations as they appear in the literature and through experimental values. Experimental values and literature averages are statistically equivalent (p=0.34, a=0.05).

FIG. 53 shows the distribution of cystine concentrations as they appear in the literature and through experimental values. Experimental values and literature averages are statistically equivalent (p=0.06, a=0.05).

FIG. 54 shows the distribution of ethanolamine concentrations as they appear in the literature and through experimental values. Experimental values and literature averages are statistically equivalent (p=0.46, a=0.05).

FIG. 55 shows the distribution of glycine concentrations as they appear in the literature and through experimental values. Experimental values and literature averages are statistically equivalent (p=0.43, a=0.05).

FIG. 56 shows the distribution of lysine concentrations as they appear in the literature and through experimental values. Experimental values and literature averages are statistically equivalent (p=0.43, a=0.05).

FIG. 57 shows the distribution of glutamine concentrations as they appear in the literature and through experimental values. Experimental values and literature averages are statistically equivalent (p=0.49, a=0.05).

FIG. 58 shows the distribution of serine concentrations as they appear in the literature and through experimental values. Experimental values and literature averages are statistically equivalent (p=0.38, a=0.05).

FIG. 59 shows the distribution of taurine concentrations as they appear in the literature and through experimental values. Experimental values and literature averages are statistically equivalent (p=0.34, a=0.05).

FIG. 60 shows the distribution of threonine concentrations as they appear in the literature and through experimental values. Experimental values and literature averages are statistically equivalent (p=0.36, a=0.05).

FIG. 61 shows the distribution of valine concentrations as they appear in the literature and through experimental values. Experimental values and literature averages are statistically equivalent (p=0.48, a=0.05).

FIG. 62 shows the distribution of creatinine concentrations as they appear in the literature and through experimental values. Experimental values and literature averages are statistically equivalent (p=0.37, a=0.05).

FIG. 63 shows the distribution of lactic acid concentrations as they appear in the literature and through experimental values. Experimental values and literature averages are statistically equivalent (p=0.11, a=0.05).

FIG. 64A shows a perspective view of an alternative embodiment of a motion assembly;

FIG. 64B shows a perspective view of an alternative embodiment of a motion assembly;

FIG. 64C shows a perspective view of an alternative embodiment of a motion assembly;

FIG. 64D shows a perspective view of an alternative embodiment of a motion assembly;

FIG. 65A shows a perspective view of a fetal phantom of the gravid abdomen phantom of FIG. 1A;

FIG. 65B shows a side view of the fetal phantom of FIG. 65A;

FIG. 65C shows a bottom view of the fetal phantom of FIG. 65A;

FIG. 65D shows a cross-sectional view of the fetal phantom of FIG. 65A, taken along line A-B in FIG. 65C;

FIG. 66A shows a perspective view of an placental phantom of the gravid abdomen phantom of FIG. 1A;

FIG. 66B shows a front view of the placental phantom of FIG. 66A;

FIG. 66C shows a bottom view of the placental phantom of FIG. 66A;

FIG. 66D shows a side view of the placental phantom of FIG. 66A; and

FIG. 67 shows a schematic illustration of hardware and software components that may be used to operate the motion assembly of FIG. 1C;

FIG. 68A shows a partial perspective view of an alternative embodiment of a gravid abdomen phantom.

FIG. 68B shows a top view of the gravid abdomen phantom of FIG. 68A;

FIG. 68C shows a top view of the gravid abdomen phantom of FIG. 68A;

FIG. 68D shows a perspective of a motion assembly of the gravid abdomen phantom of FIG. 68A;

FIG. 68E shows an enlarged portion of the motion assembly of FIG. 68D;

FIG. 68F shows the gravid abdomen phantom of FIG. 68A positioned within a bore of an MRI scanner;

FIG. 68G shows the gravid abdomen phantom of FIG. 68A; and

FIG. 68H shows a perspective view of an actuator support of the gravid abdomen phantom of FIG. 68G.

Other features and advantages of the present disclosure will become apparent from the following detailed description. It should be understood, however, that the detailed description and the specific examples, while indicating embodiments of the disclosure, are given by way of illustration only and the scope of the claims should not be limited by these embodiments, but should be given the broadest interpretation consistent with the description as a whole.

### DESCRIPTION OF VARIOUS EMBODIMENTS

Various apparatuses are described below to provide an example of an embodiment of potentially claimed subject matter. No embodiment described below limits any claimed subject matter and any claimed subject matter may cover apparatuses, components and methods that differ from those described below. The claimed subject matter is not limited to apparatuses, materials, and methods having all of the features of any one apparatus or method described below or to features common to multiple or all of the apparatuses, compositions, or methods described below. It is possible that an apparatus, composition, or method described below is not an embodiment of any claimed subject matter. Any subject matter disclosed in an apparatus, composition, or method described below that is not claimed in this document may be the subject matter of another protective instrument, for example, a continuing patent application, and the applicant(s), inventor(s), and/or owner(s) do not intend to abandon, disclaim, or dedicate to the public any such subject matter by its disclosure in this document.

It will be appreciated that for simplicity and clarity of illustration, where considered appropriate, reference numerals may be repeated among the figures to indicate corresponding or analogous elements, steps, or materials. In addition, numerous specific details are set forth in order to provide a thorough understanding of the embodiments described herein. However, it will be understood by those of ordinary skill in the art that the embodiments described herein may be practiced without these specific details. In other instances, well-known methods, procedures, and components have not been described in detail so as not to obscure the embodiments described herein. Also, the description is not to be considered as limiting the scope of the embodiments described herein.

In the description that follows there are the following subsections:
I. Definitions;
II. General Description of Phantoms and Systems thereof
III. General Description of Brain Matter Mimicking Material;
IV. General Description of Muscle Tissue Mimicking Material;
V. General Description of Placenta Mimicking Material;
VI. General Description of Amniotic Fluid Mimicking Composition; and
VII. General Description of Motion Assemblies.

Each of subsections III to VII describe at least one feature of the gravid abdomen phantom that can be used alone or in combination with at least one feature of at least one of the other subsections.

### I. Definitions

Unless otherwise indicated, the definitions and embodiments described in this and other sections are intended to be applicable to all embodiments and aspects of the present disclosure herein described for which they are suitable as would be understood by a person skilled in the art.

The terms “coupled” or “coupling” as used herein can have several different meanings depending on the context in which these terms are used. For example, the terms “coupled” or “coupling” can have a mechanical, electrical, chemical, or fluidic connotation. For example, as used herein, the terms coupled or coupling can indicate that two elements or devices can be directly connected to one another or connected to one another through one or more intermediate elements via an electrical element, an electrical signal, a mechanical element, or a fluid pathway, depending on the particular context.

Various terms used throughout the present description may be read and understood as follows, unless the context indicates otherwise: singular articles and pronouns as used throughout include their plural forms, and vice versa; similarly, gendered pronouns include their counterpart pronouns so that pronouns should not be understood as limiting anything described herein to use, implementation, performance, etc. by a single gender. Further definitions for terms may be set out herein; these may apply to prior and subsequent instances of those terms, as will be understood from a reading of the present description.

The wording “and/or” is intended to represent an inclusive-or. That is, “X and/or Y” is intended to mean X or Y or both, for example. As a further example, “X, Y, and/or Z” is intended to mean X or Y or Z or any combination thereof. In effect, this term means that “at least one of” or “one or more” of the listed items is used or present. For example, the term “and/or” with respect to pharmaceutically acceptable salts and/or solvates thereof means that the compounds of the disclosure exist as individual salts and hydrates, as well as a combination of, for example, a solvate of a salt of a compound of the disclosure.

Terms of degree such as “substantially”, “about”, and “approximately” as used herein mean a reasonable amount of deviation of the modified term such that the end result is not significantly changed. These terms of degree may also be construed as including a deviation of the modified term, such as by 1%, 2%, 5% or 10%, for example, if this deviation does not negate the meaning of the term it modifies.

The recitation of numerical ranges by endpoints herein includes all numbers and fractions subsumed within that range (e.g., 1 to 5 includes 1, 1.5, 2, 2.75, 3, 3.90, 4, and 5). It is also to be understood that all numbers and fractions thereof are presumed to be modified by the term “about” which means a variation of up to a certain amount of the number to which reference is being made if the end result is not significantly changed, such as 1%, 2%, 5%, or 10%, for example.

Reference throughout this specification to “one embodiment”, “an embodiment”, “at least one embodiment” or “some embodiments” means that one or more particular features, structures, or characteristics may be combined in any suitable manner in one or more embodiments, unless otherwise specified to be not combinable or to be alternative options.

As used in this specification and the appended claims, the singular forms “a,” “an,” and “the” include plural referents unless the content clearly dictates otherwise. For example, an embodiment including “a compound” should be understood to present certain aspects with one compound, or two or more additional compounds. It should also be noted that the term “or” is generally employed in its broadest sense, that is, as meaning “and/or” unless the content clearly dictates otherwise.

Similarly, throughout this specification and the appended claims the term “communicative” as in “communicative pathway” “communicative coupling,” and in variants such as “communicatively coupled,” is generally used to refer to any engineered arrangement for transferring and/or exchanging information. Examples of communicative pathways include, but are not limited to, electrically conductive pathways (e.g., electrically conductive wires, physiological signal conduction), electromagnetically radiative pathways (e.g., radio waves), or any combination thereof. Examples of communicative couplings include, but are not limited to, electrical couplings, magnetic couplings, radio couplings, or any combination thereof.

Throughout this specification and the appended claims, infinitive verb forms are often used. Examples include, without limitation: “to detect,” “to provide,” “to transmit,” “to communicate,” “to process,” “to route,” and the like. Unless the specific context requires otherwise, such infinitive verb forms are used in an open, inclusive sense, that is as “to, at least, detect,” to, at least, provide,” “to, at least, transmit,” and so on.

In embodiments comprising an “additional” or “second” component, such as an additional or second compound, the second component as used herein is chemically different from the other components or first component. A “third” component is different from the other, first, and second components, and further enumerated or “additional” components are similarly different.

As used in this disclosure and claim(s), the words “comprising” (and any form of comprising, such as “comprise” and “comprises”), “having” (and any form of having, such as “have” and “has”), “including” (and any form of including, such as “include” and “includes”) or “containing” (and any form of containing, such as “contain” and “contains”), are inclusive or open-ended, such as “including, but not limited to”, and do not exclude additional, unrecited elements or process steps.

The term “consisting” and its derivatives as used herein are intended to be closed terms that specify the presence of the stated features, elements, components, groups, integers, and/or steps, and also exclude the presence of other unstated features, elements, components, groups, integers and/or steps.

The term “consisting essentially of”, as used herein, is intended to specify the presence of the stated features, elements, components, groups, integers, and/or steps as well as those that do not materially affect the basic and novel characteristic(s) of these features, elements, components, groups, integers, and/or steps.

In addition, it should be noted that a portion of the example embodiments of the systems, devices, or methods described in accordance with the teachings herein may be implemented as a combination of hardware or software. For example, a portion of the embodiments described herein may be implemented, at least in part, by using one or more computer programs, executing on one or more programmable devices comprising at least one processing element, and at least one data storage element (including volatile and non-volatile memory). These devices may also have at least one input device (e.g., a keyboard, a mouse, a touchscreen, and the like) and at least one output device (e.g., a display screen, a printer, a wireless radio, and the like) depending on the nature of the device.

It should also be noted that there may be some elements that are used to implement at least part of the embodiments described herein that may be implemented via software that is written in a high-level procedural language such as object-oriented programming. The program code may be written in C, C⁺⁺ or any other suitable programming language and may comprise modules or classes, as is known to those skilled in object-oriented programming. Alternatively, or in addition thereto, some of these elements implemented via software may be written in assembly language, machine language, or firmware as needed.

At least some of the software programs used to implement at least one of the embodiments described herein may be stored on a storage media or a device that is readable by a general or special purpose programmable device. The software program code, when read by the programmable device, configures the programmable device to operate in a new, specific and predefined manner in order to perform at least one of the methods described herein.

Furthermore, at least some of the programs associated with the systems and methods of the embodiments described herein may be capable of being distributed in a computer program product comprising a computer readable medium that bears computer usable instructions, such as program code, for one or more processors. The program code may be preinstalled and embedded during manufacture and/or may be later installed as an update for an already deployed computing system. The medium may be provided in various forms, including non-transitory forms such as, but not limited to, one or more diskettes, compact disks, tapes, chips, and magnetic and electronic storage. In alternative embodiments, the medium may be transitory in nature such as, but not limited to, wire-line transmissions, satellite transmissions, internet transmissions (e.g., downloads), media, digital and analog signals, and the like. The computer useable instructions may also be in various formats, including compiled and non-compiled code.

Accordingly, any module, unit, component, server, computer, terminal or device described herein that executes software instructions may include or otherwise have access to computer readable media such as storage media, computer storage media, or data storage devices (removable and/or non-removable) such as, for example, magnetic disks, optical disks, or tape. Computer storage media may include volatile and non-volatile, removable and non-removable media implemented in any method or technology for storage of information, such as computer readable instructions, data structures, program modules, or other data. Examples of computer storage media include RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which can be used to store the desired information, and which can be accessed by an application, module, or both. Any such computer storage media may be part of the device or accessible or connectable thereto.

### II. General Description of Embodiments of Phantoms and Systems Thereof

In one aspect, in accordance with the teachings herein, a fetal phantom 1008 along with a motion assembly 1004 is provided to simulate the physiological motion of a prenatal fetus in the gravid abdomen for purposes of testing imaging modalities, such as under an MRI scanner. The anatomical regions of interest in the fetal phantom 1008 include the boundaries of the placenta, gross body (e.g., head, limbs, and trunk), and the brain (e.g., grey matter, white matter, and ventricles). Performing testing during imaging is important for improving the signal-to-noise ratio of the resulting images since motion artifacts are commonly observed during an MRI scan of a fetus which can severely degrade the image quality. The embodiments described herein may be used to create a reproducible motion profile for sequence optimization during imaging.

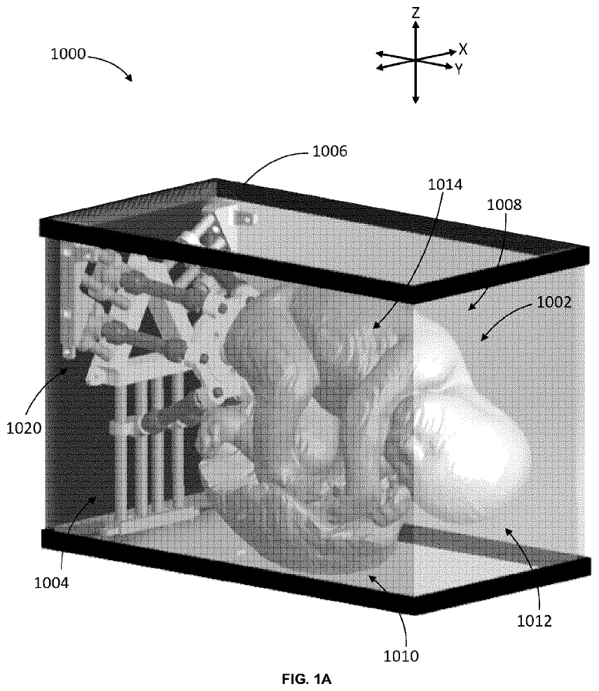

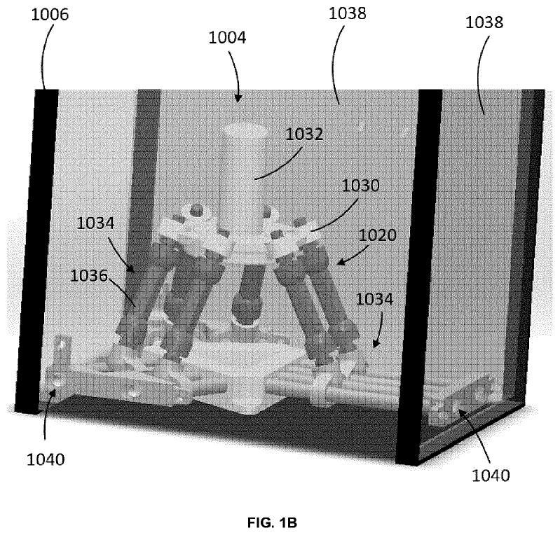

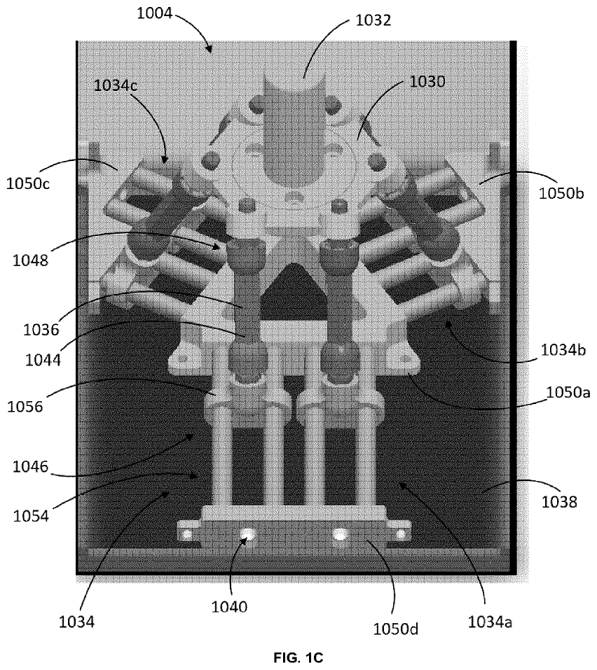

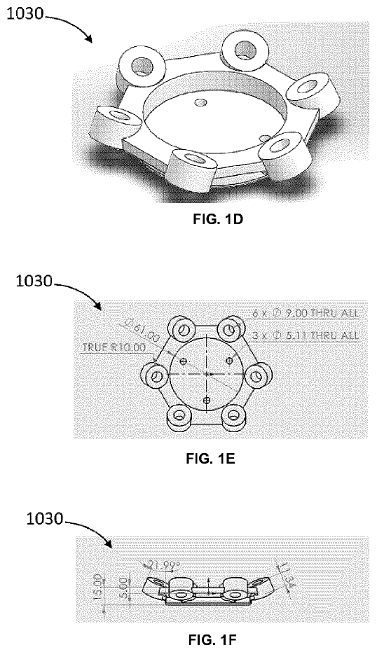

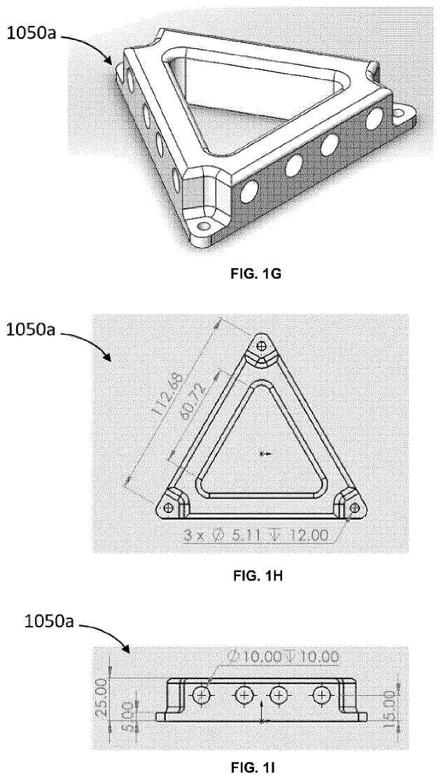

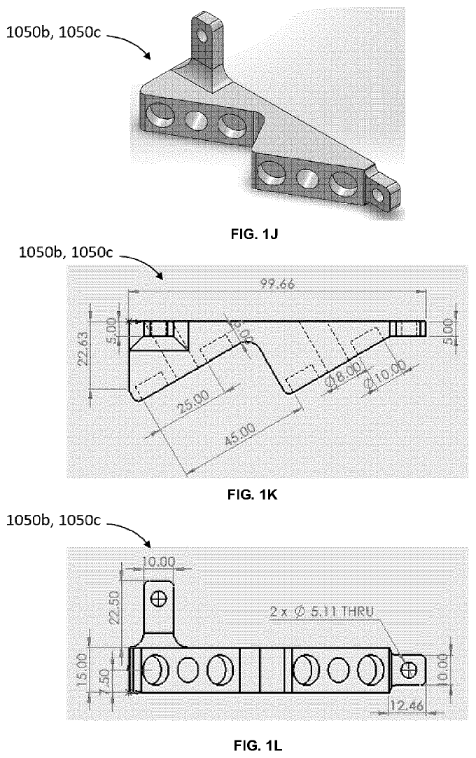

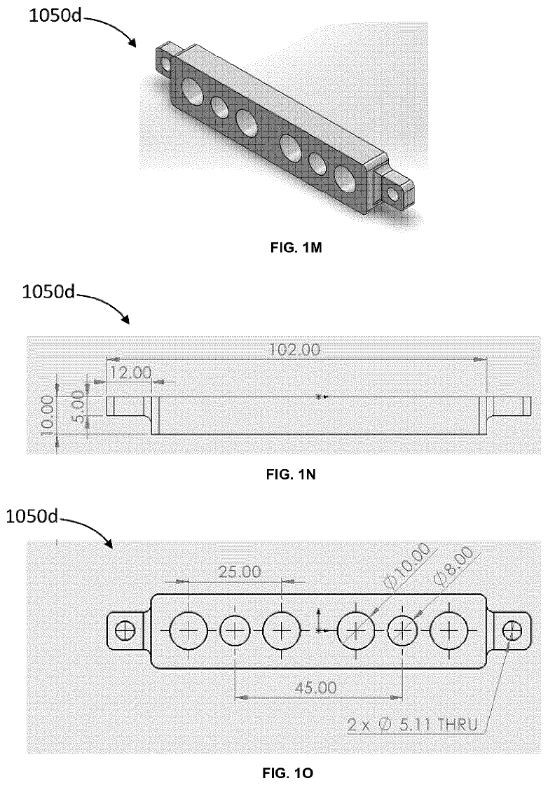

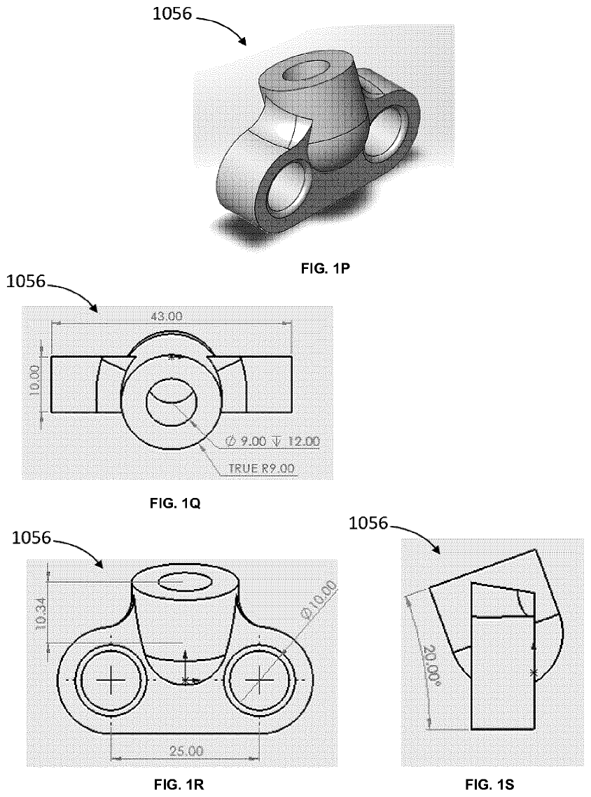

Referring first to FIG. 1A, shown therein is an example embodiment of a gravid abdomen phantom 1000. In the example illustrated, the gravid abdomen phantom 1000 includes a fetal modeling system 1002, a motion assembly 1004, and a tank 1006. In some examples, the motion assembly 1004 is operable to move the fetal modeling system 1002 in such a way that it simulates the physiological motion of a prenatal fetus, such as, for example, a third trimester prenatal fetus.

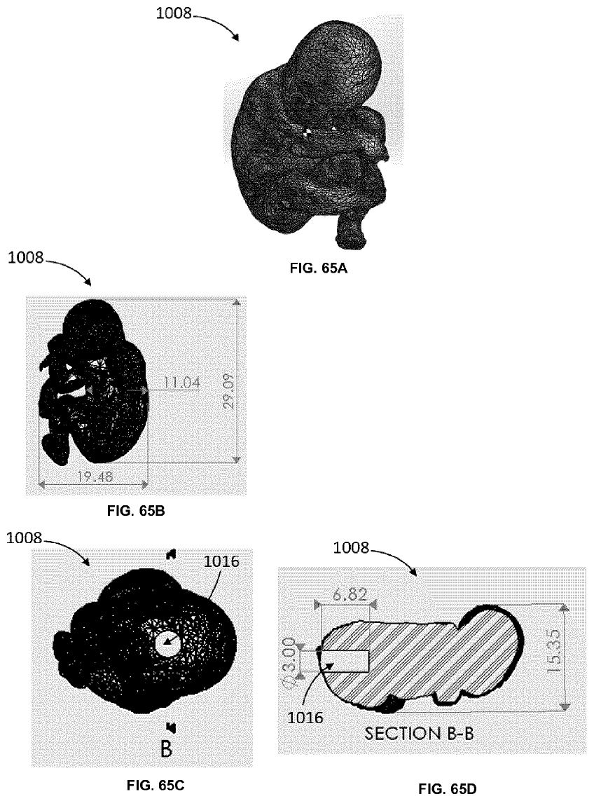

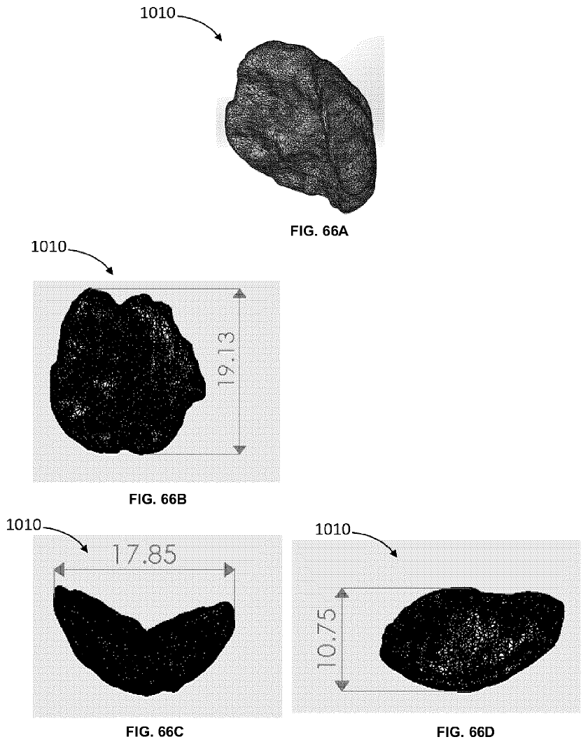

The fetal modeling system 1002 may include at least one of a fetal phantom 1008 (see, e.g., FIGS. 65A-65D), artificial amniotic fluid (not shown), and a placental phantom 1010 (see, e.g., FIGS. 66A-66D). In the example illustrated in FIG. 1A, the fetal modeling system 1002 includes the fetal phantom 1008, artificial amniotic fluid, and placental phantom 1010. In other examples, the fetal modeling system 1002 may include additional body part phantoms, for example, a heart phantom and/or lung phantom. The additional body part phantoms may be prepared by any means known in the art. Any fetal phantom 1008, artificial amniotic fluid, and/or placental phantom 1010 known in the art may be used.

Properties of example embodiments of artificial amniotic fluid and placental phantoms 1010 are described in more detail below. Among other components, the fetal phantom 1008 may include at least one of a brain phantom and muscle tissue phantom. Properties of example embodiments of brain phantoms and muscle tissue phantoms are described in more detail below.

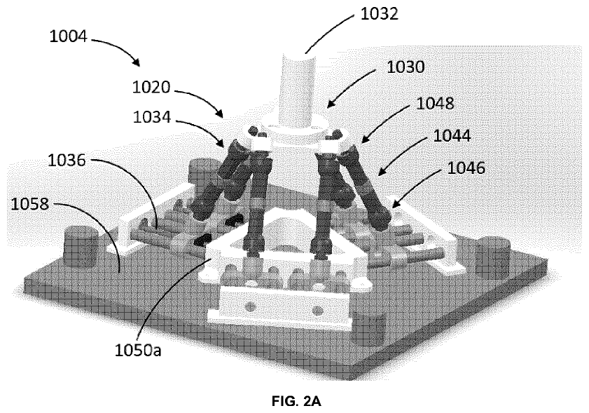

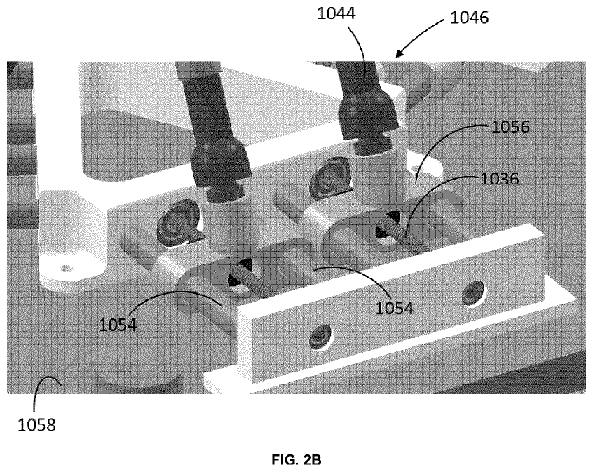

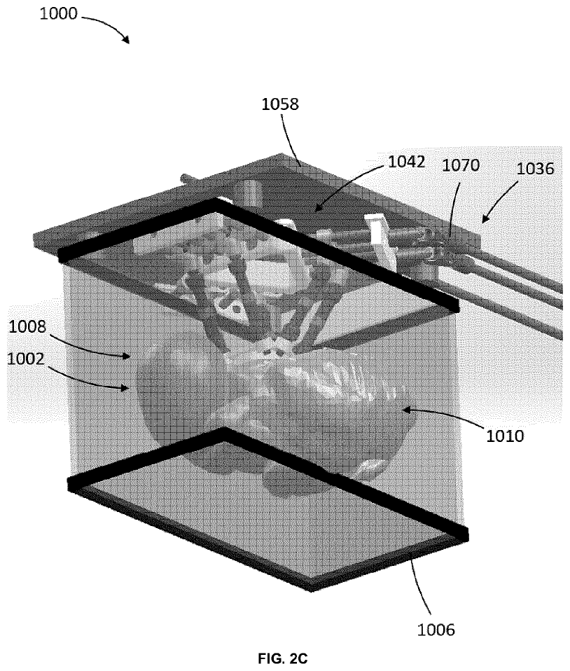

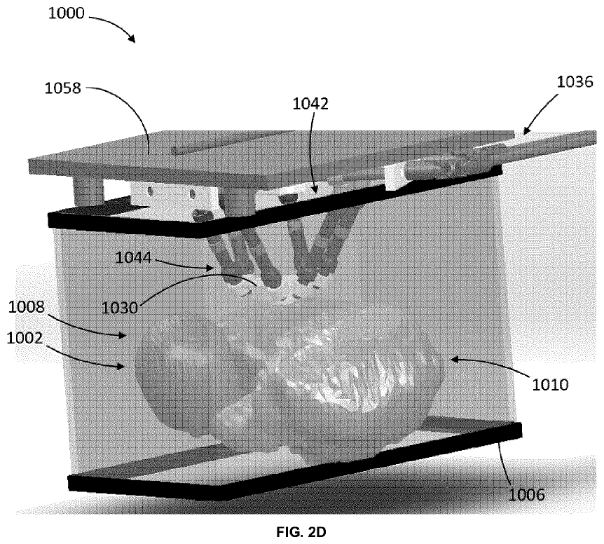

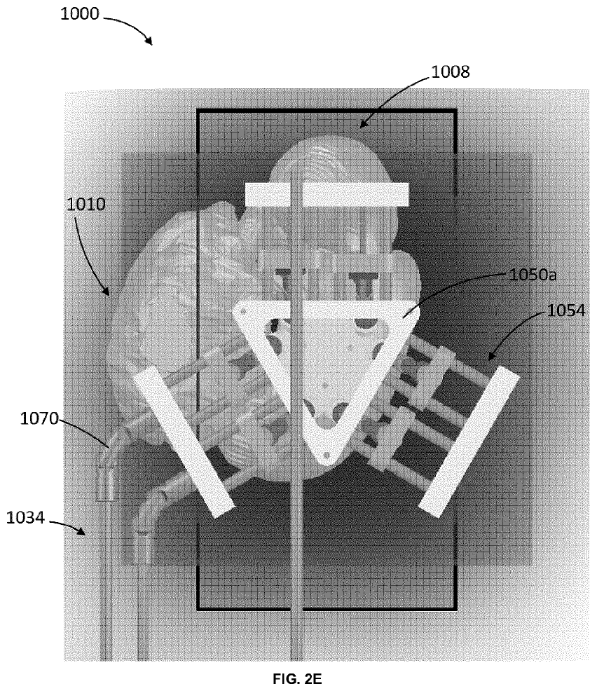

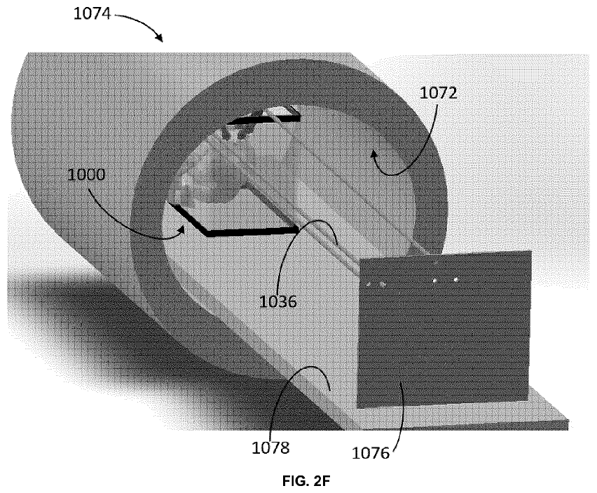

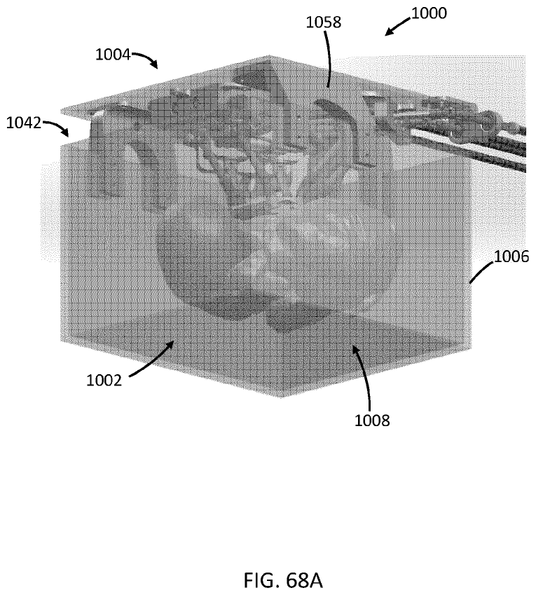

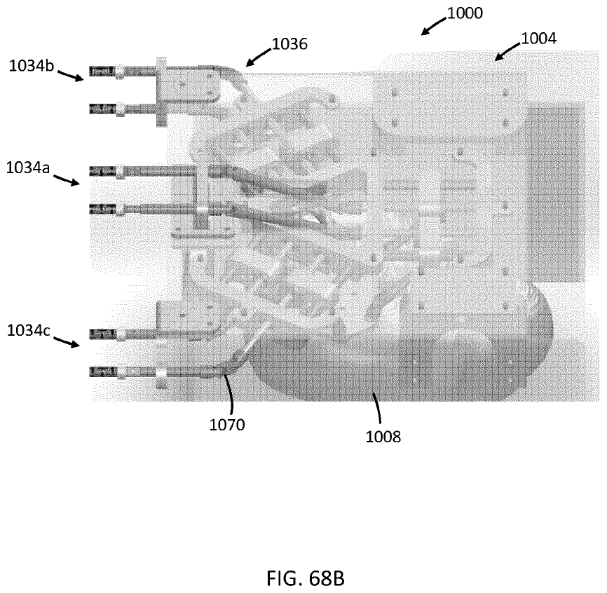

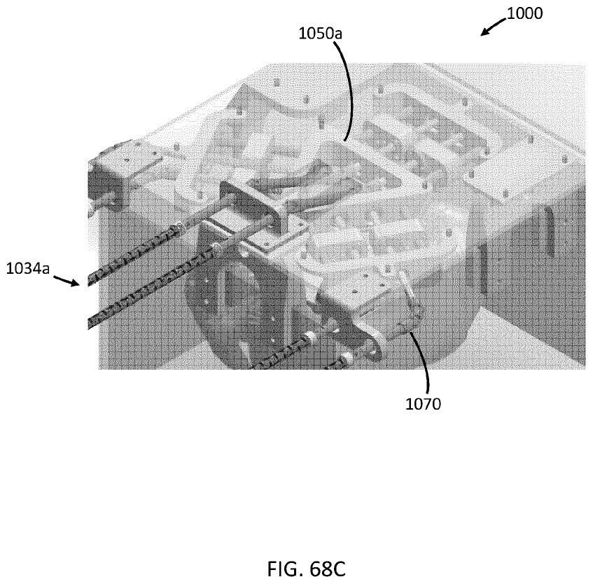

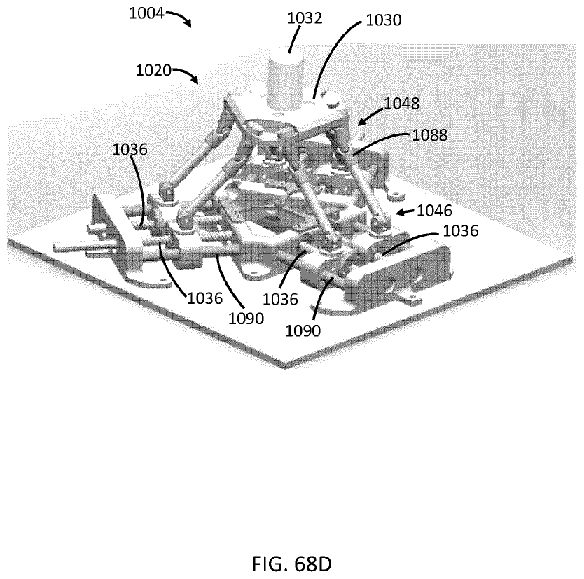

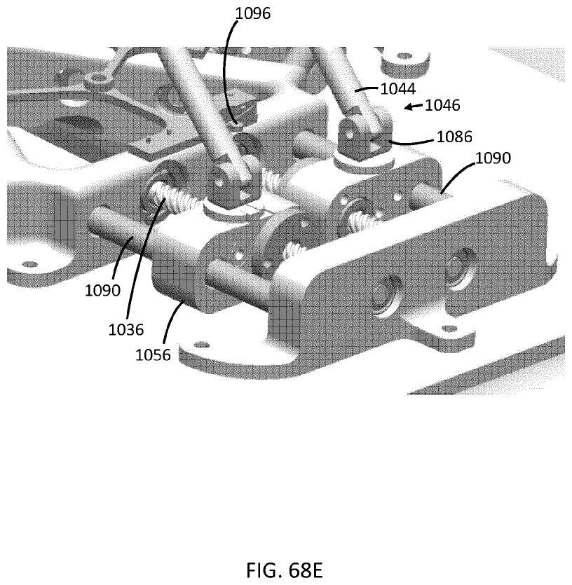

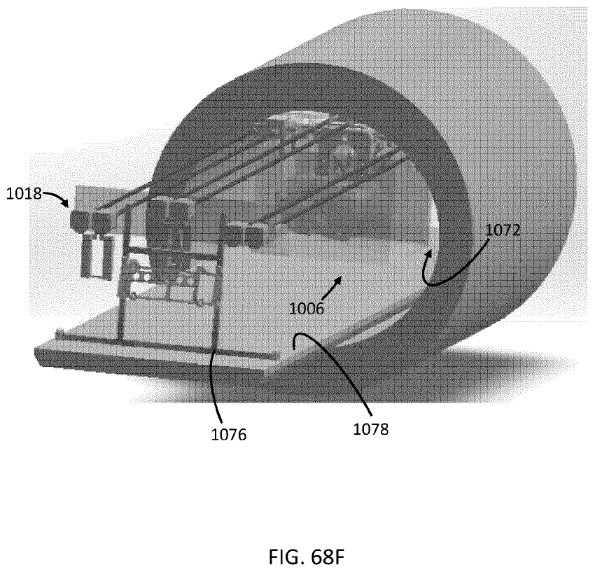

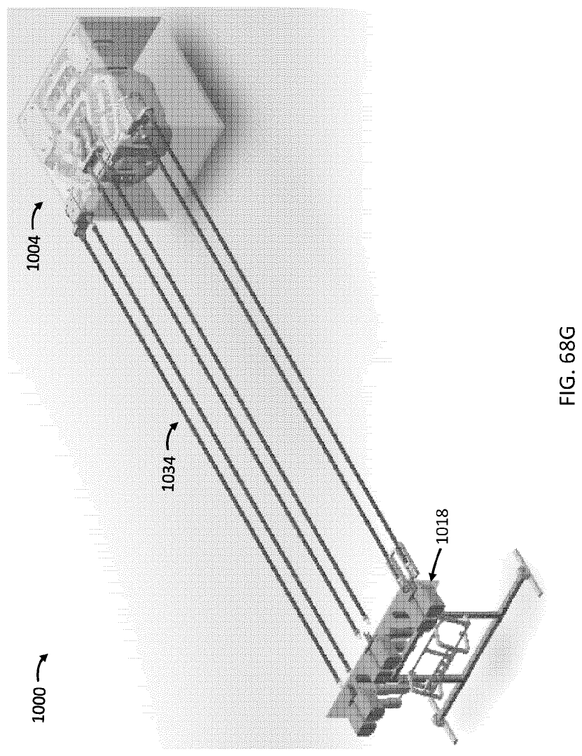

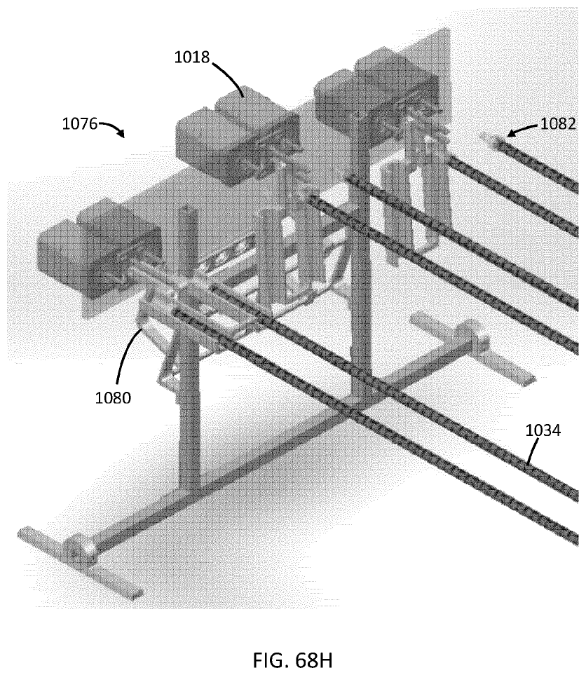

As shown in FIG. 1A, the fetal phantom 1008 may be supported within the tank 1006. While the tank 1006 illustrated is rectangular, it is to be understood that the tank may be any shape and size. The tank 1006 may also hold a volume of the artificial amniotic fluid when the fetal modeling system 1002 includes artificial amniotic fluid. When the fetal modeling system 1002 includes placental phantom 1010, the tank 1006 may support the placental phantom 1010 in a position relative to the fetal phantom 1008 which approximates the location of placenta relative to a fetus within a gravid abdomen, as is illustrated. The tank 1006 may be sized to be positionable within the bore 1072 of an imaging device such as an MRI machine 1074 (as shown in FIGS. 2F and 68F). In some examples (not illustrated), the gravid abdomen phantom 1000 may not include a tank 1006. The gravid abdomen phantom 1000 may include a tank when it is desired to mimic the motion of a fetus within a fluid (e.g., amniotic fluid). However, in some cases, it may not be required to mimic the motion of a fetus within a fluid (i.e., it may be desirable to study the gravid abdomen phantom 1000 not immersed in a fluid) and accordingly a tank 1006 may not be required. In this example, the motion assembly 1004 may be supported by any other support structure known in the art.

Still referring to FIG. 1A, the fetal phantom 1008 may be connected to the motion assembly 1004 which may be operable to move the fetal phantom 1008 so that it may simulate the motion of a prenatal fetus. Any motion assembly 1004 known in the art may be used. The motion assembly 1004 may be operable to simulate at least one of motion of a prenatal fetus, respiration of a prenatal fetus, and motion of a prenatal fetus due to maternal respiration. Since the gravid abdomen phantom 1000 may be studied while inserted within the bore 1072 of an MRI machine 1074, the components of the motion assembly 1004 may be MR compatible. That is, the motion assembly 1004 may be at least partially constructed out of materials which do not introduce image artifacts when imaged using an MRI machine (i.e., the fetal phantom and portions of the motion assembly 1004 may be formed of non-magnetic materials). Alternatively, components of the motion assembly 1004 may be positionable outside of the bore 1072 of the MRI machine 1074 to not introduce image artifacts (as shown in FIG. 68F).

To simulate the motion of a prenatal fetus, the motion assembly 1004 may be operable to reposition the fetal phantom 1008 such that the head 1012 of the fetal phantom 1008 undergoes certain types of movement such as, but not limited to, a linear displacement of about 55 mm at a speed of about 100 mm/s and/or a rotational displacement of about 30°. The motion assembly 1004 may be operable to continuously move the fetal phantom 1008 for a predetermined period of time such as, but not limited to, at least three seconds, for example.

To simulate the respiration of a prenatal fetus, the motion assembly 1004 may be operable to reposition the fetal phantom 1008 such that the trunk 1014 of the fetal phantom 1008 undergoes a certain linear displacement such as but not limited to between about 3 mm and about 8 mm at a speed of about 10 mm/s. The motion assembly 1004 may be operable to move the fetal phantom at a frequency of about 43 counts/min (i.e., move the abdomen of the fetal phantom about 8 mm at a speed of about 10 mm/s at least about 43 times per minute).

To simulate the motion of a prenatal fetus due to maternal respiration, the motion assembly 1004 may be operable to move the position of where the heart (not shown) of the fetal phantom 1008 would be located between about 0.5 mm and about 2.3 mm about seventeen times per minute.

It is to be understood that the specific examples of motion described above are non-limiting examples, and the motion assembly may be configured to move and/or rotate the fetal phantom in any direction at any speed.

In addition to translation and/or rotational type movement of the phantom fetus 1008, the motion assembly 1004 may be operable to simulate respiratory motion of a prenatal fetus. To do so, the motion assembly 1004 may include a tube (not shown) which may be insertable into a lung cavity of the trunk 1014 of the fetal phantom 1008 and at least the lung cavity of the trunk 1014 may be made of a pliable flexible material. A fluid (e.g., artificial amniotic fluid, air, etc.) may be pumped through the tube by a pump to simulate respiratory motion of a prenatal fetus by displacing the pliable flexible material of the lung cavity. More specifically, the pump may push one of air and fluid through the tube and into the lung cavity, creating an expansion in the trunk 1014. When the pressure from the pump is released, the trunk 1014 may return to a resting state. The pump may be located external to the tank 1006. In some embodiments, the tube may pass through a respective port 1040 in a wall 1038 of the tank 1006. In other embodiments, the tank 1006 may have an open upper end 1042 (see, e.g., FIG. 2C), and the tube may pass into the tank via the open upper end 1042. When included, the tube may be made of a thin material so that it does not introduce an image artifact by displacing amniotic fluid during simulation.

In another aspect, the present disclosure includes a brain phantom comprising a brain grey matter mimicking material of the present disclosure and/or a brain white matter mimicking material of the present disclosure.

In another aspect, the present disclosure includes a fetal phantom comprising
a brain phantom comprising a brain grey matter mimicking material of the present disclosure and a brain white matter mimicking material of the present disclosure; and
a body phantom comprising a muscle tissue mimicking material of the present disclosure.

In another aspect, the present disclosure includes a fetal phantom for use in the modelling of a fetus. In some embodiments, the fetal phantom is for use in the modelling of a movement of the fetus.

In another aspect, the present disclosure includes a fetus modelling system comprising
a fetal phantom of the present disclosure;
a placenta phantom comprising a placenta mimicking material of the present disclosure; and
an artificial amniotic fluid comprising an amniotic fluid mimicking composition of the present disclosure.

In another aspect, the present disclosure includes a gravid abdomen phantom comprising:
a tank that is insertable into a bore of a magnetic resonance imaging scanner;
a motion assembly; and
a fetal phantom positioned in the tank and mounted to the motion assembly,
wherein the motion assembly is operable to simulate the movement of a prenatal fetus.

In another aspect, the present disclosure includes a gravid abdomen phantom comprising:
a motion assembly; and
a fetal phantom mounted to the motion assembly,
wherein the motion assembly is operable to simulate the movement of a prenatal fetus.

In some embodiments, the gravid abdomen phantom may include a tank that is insertable into a bore of a magnetic resonance imaging scanner and the fetal phantom is positioned in the tank.

In some embodiments, the motion assembly comprises
a motion platform for supporting the fetal phantom;
at least one actuator for controlling movement of the motion platform; and
at least one driving linkage extending between the at least one actuator and the motion platform,
wherein the motion platform is mounted to the tank for housing the fetal phantom.

In some embodiments, the fetal phantom comprises a brain phantom and a body phantom.

In some embodiments, the brain phantom comprises a brain grey matter mimicking material and a brain white matter mimicking material.

In some embodiments, the brain grey matter mimicking material comprises
about 1 w/w % to about 6 w/w % carrageenan;
about 0.3 w/w % to about 1 w/w % agarose;
about 20 μmol/kg to about 45 μmol/kg GdCl₃ based on the total weight of the brain grey matter mimicking material;
about 0.5 w/w % to about 5 w/w % NaCl;
about 0.01 w/w % to about 0.06 w/w % NaN₃; and
balance water.

In some embodiments, the brain grey matter mimicking material comprises
about 1 w/w % to about 2 w/w % carrageenan,
about 0.3 w/w % to about 1 w/w % NaCl,
about 0.01 w/w % to about 0.06 w/w % glutaraldehyde,
at least one of MnCl₂ or agarose, and
balance water; and
wherein the MnCl₂, if present, is present at a concentration of about 55 μM or less than 55 μM, and wherein the agarose, if present, is present at a concentration of about 5 w/w % or less than 5 w/w %.

In some embodiments, the brain white matter mimicking material comprises
about 1 w/w % to about 6 w/w % carrageenan;
about 0.7 w/w % to about 1.5 w/w % agarose;
about 80 μmol/kg to about 120 μmol/kg GdCl₃ based on the total weight of the brain white matter mimicking material;
about 0.1 w/w % to about 2.5 w/w % NaCl;
about 0.01 w/w % to about 0.06 w/w % NaN₃; and
balance water.

In some embodiments, the brain white matter mimicking material comprises
about 0.3 w/w % to about 1 w/w % NaCl,
about 0.01 w/w % to about 0.06 w/w % glutaraldehyde,
at least one of MnCl₂ and agarose, and
balance water; and
wherein the MnCl2, if present, is present at a concentration of about 150 μM or less than 150 M, and wherein the agarose, if present, is present at a concentration of about 5 w/w % or less than 5 w/w %.

In some embodiments, the body phantom comprises a muscle tissue mimicking material.

In some embodiments, the muscle mimicking material comprises
about 1 w/w % to about 6 w/w % carrageenan;
about 1 w/w % to about 5 w/w % agarose;
about 15 μmol/kg to about 60 μmol/kg GdCl₃ based on the total weight of the muscle tissue mimicking material;
about 0.1 w/w % to about 5 w/w % NaCl;
about 0.01 w/w % to about 0.06 w/w % NaN₃; and
balance water.

In some embodiments, the gravid abdomen phantom further comprises a volume of an artificial amniotic fluid held within the tank.

In some embodiments, the amniotic fluid mimicking composition comprises per 100 mL of the amniotic fluid mimicking composition about 10 mg to about 13 mg citrate;
about 38 mg to about 44 mg glucose;
about 100 mg to about 106 mg lactic acid;
about 2 mg to about 3 mg alanine;
about 1.3 mg to about 2 mg cystine;
about 0.2 mg to about 0.3 mg ethanolamine;
about 0.3 mg to about 1 mg glutamic acid;
about 0.8 mg to about 1.4 mg glycine;
about 0.4 mg to about 1 mg histidine;
about 1.2 mg to about 2 mg lysine;
about 1 mg to about 1.7 mg proline;
about 3 mg to about 3.6 mg glutamine;
about 0.5 mg to about 1.1 mg serine;
about 1 mg to about 1.8 mg taurine;
about 1 mg to about 1.7 mg threonine;
about 1 mg to about 1.8 mg valine;
about 0.7 mg to about 1.5 mg creatine;
about 10 mg to about 16 mg calcium formate; and
balance water;
wherein the artificial amniotic fluid has a pH of about 6.8 to about 7.8; and
wherein the artificial amniotic fluid has an osmolality of about 175 mM to about 275 mM.

In some embodiments, the gravid abdomen phantom further comprises a placenta phantom supported within the tank.

In some embodiments, the placenta phantom comprises a placenta mimicking material. In some embodiments, the placenta mimicking material comprises
about 1 w/w % to about 6 w/w % carrageenan;
about 0.01 mM to about 0.05 mM MnCl₂;
about 0.3 w/w % to about 1 w/w % NaCl;
about 0.01 w/w % to about 0.06 w/w % of an antiseptic agent, optionally selected from glutaraldehyde, NaN₃, NaNO₃, and combinations thereof; and
balance water.

In some embodiments, the placenta mimicking material comprises
about 2 w/w % to about 4 w/w % carrageenan,
about 0.3 w/w % to about 1 w/w % NaCl,
about 0.01 w/w % to about 0.06 w/w % glutaraldehyde,
at least one of MnCl₂ or agarose, and
balance water; and
wherein the MnCl₂, if present, is present at a concentration of about 2 μM to about 50 μM, and wherein the agarose, if present, is present at a concentration of about 0.01 w/w % to about 3.5 w/w %.

### III. General Description of Embodiments of Brain Matter Mimicking Material

In one aspect, the present disclosure includes a brain grey matter mimicking material comprising
about 1 w/w % to about 6 w/w % carrageenan;
about 0.3 w/w % to about 1 w/w % agarose;
about 20 μmol/kg to about 45 μmol/kg GdCl₃ based on the total weight of the brain grey matter mimicking material;
about 0.5 w/w % to about 5 w/w % NaCl;
about 0.01 w/w % to about 0.06 w/w % NaN₃; and
balance water.

In some embodiments, the brain grey matter mimicking material comprises
about 2 w/w % to about 4 w/w % carrageenan;
about 0.5 w/w % to about 0.8 w/w % agarose;
about 30 μmol/kg to about 40 μmol/kg GdCl₃;
about 1 w/w % to about 3 w/w % NaCl;
about 0.02 w/w % to about 0.04 w/w % NaN₃; and
balance water.

In some embodiments, the brain grey matter mimicking material comprises
about 2.5 w/w % to about 3.5 w/w % carrageenan;
about 0.6 w/w % to about 0.7 w/w % agarose;
about 35 μmol/kg to about 40 μmol/kg GdCl₃;
about 1.5 w/w % to about 2.5 w/w % NaCl;
about 0.025 w/w % to about 0.035 w/w % NaN₃; and
balance water.

In some embodiments, the brain grey matter mimicking material comprises
about 3 w/w % carrageenan;
about 0.68 w/w % agarose;
about 38 μmol/kg GdCl₃;
about 1.8 w/w % NaCl;
about 0.03 w/w %; and
balance water.

In some embodiments, the brain grey matter mimicking material has a T₁ relaxation time at about 3T of about 1100 ms to about 1850 ms, about 1150 ms to about 1800 ms, about 1200 ms to about 1800 ms, about 1250 ms to about 1785 ms, or about 1275 ms to about 1763 ms.

In some embodiments, the brain grey matter mimicking material has a T₂ relaxation time of about 40 ms to about 130 ms, about 50 ms to about 120 ms, about 60 to about 115 ms, or about 66 ms to about 110 ms.

In some embodiments, the brain grey matter mimicking material has a dielectric constant at about 127.5 MHz of about 75 F/m to about 95 F/m, about 80 F/m to about 90 F/m, or about 83 F/m to about 87 F/m, or about 84 F/m.

In some embodiments, the brain grey matter mimicking material has a conductivity of about 0.3 S/m to about 0.75 S/m, about 0.4 S/m to about 0.7 S/m, about 0.45 S/m to about 0.6 S/m, about 0.5 S/m to about 0.6 S/m, or about 0.54 S/m to about 0.56 S/m.

In another aspect, the present disclosure includes a brain grey matter mimicking material comprising
about 1 w/w % to about 2 w/w % carrageenan,
about 0.3 w/w % to about 1 w/w % NaCl,
about 0.01 w/w % to about 0.06 w/w % glutaraldehyde,
at least one of MnCl₂ or agarose, and
balance water; and
wherein the MnCl₂, if present, is present at a concentration of about 55 μM or less than 55 μM, and wherein the agarose, if present, is present at a concentration of about 5 w/w % or less than 5 w/w %.

In some embodiments, the brain grey matter mimicking material comprises about 1.2 w/w % to about 1.8 w/w % carrageenan, about 1.4 w/w % to about 1.6 w/w % carrageenan, or about 1.5 w/w % carrageenan.

In some embodiments, the brain grey matter mimicking material comprises about 50 μM or less than 50 μM MnCl₂, about 45 μM or less than 45 μM MnCl₂, or about 44 μM or less than 44 μM MnCl₂.

In some embodiments, the brain grey matter mimicking material comprises about 4 w/w % or less than 4 w/w % agarose, about 3 w/w % or less than 3 w/w % agarose, or about 2.33 w/w % or less than 2.33 w/w % agarose.

In some embodiments, the brain grey matter mimicking material comprises about 0.4 w/w % to about 0.8 w/w % NaCl, about 0.55 w/w % to about 0.75 w/w % NaCl, or about 0.63 w/w % to about 0.66 w/w % NaCl.

In some embodiments, the brain grey matter mimicking material comprises about 0.02 w/w % to about 0.05 w/w % glutaraldehyde, about 0.025 w/w % to about 0.04 w/w % glutaraldehyde, or about 0.03 w/w % glutaraldehyde.

In some embodiments, the brain grey matter mimicking material has a T₁ relaxation time at about 3T of about 1050 ms to about 2200 ms, about 1100 ms to about 2100 ms, of about 1200 ms to about 2050 ms, about 1250 ms to about 2050 ms, or about 1274 ms to about 2022 ms.

In some embodiments, the brain grey matter mimicking material has a T₂ relaxation time at about 3T of about 30 ms to about 350 ms, about 35 ms to about 300 ms, of about 40 ms to about 280 ms, or about 43 ms to about 275 ms.

It is contemplated that as the brain grey matter mimicking material of the present application mimics at least the T1/T2 relaxometry properties of fetal brain grey matter, in some embodiments, the brain grey matter mimicking material of the present application is a fetal brain grey matter mimicking material.

In another aspect, the present disclosure includes a brain white matter mimicking material comprising
about 1 w/w % to about 6 w/w % carrageenan;
about 0.7 w/w % to about 1.5 w/w % agarose;
about 80 μmol/kg to about 120 μmol/kg GdCl₃ based on the total weight of the brain white matter mimicking material;
about 0.1 w/w % to about 2.5 w/w % NaCl;
about 0.01 w/w % to about 0.06 w/w % NaN₃; and
balance water.

In some embodiments, the brain white matter mimicking material comprises
about 2 w/w % to about 4 w/w % carrageenan;
about 0.85 w/w % to about 1.3 w/w % agarose;
about 85 μmol/kg to about 110 μmol/kg GdCl₃;
about 0.3 w/w % to about 3 w/w % NaCl;
about 0.02 w/w % to about 0.04 w/w % NaN₃; and
balance water.

In some embodiments, the brain white matter mimicking material comprises
about 2.5 w/w % to about 3.5 w/w % carrageenan;
about 1 w/w % to about 1.3 w/w % agarose;
about 90 μmol/kg to about 100 μmol/kg GdCl₃;
about 0.4 w/w % to about 1.3 w/w % NaCl;
about 0.025 w/w % to about 0.035 w/w % NaN₃; and
balance water.

In some embodiments, the brain white matter mimicking material comprises
about 3 w/w % carrageenan;
about 1.14 w/w % agarose;
about 95 μmol/kg GdCl₃;
about 0.83 w/w % NaCl;
about 0.03 w/w % NaN₃; and
balance water.

In some embodiments, the brain white matter mimicking material has a T₁ relaxation time at about 3T of about 900 ms to about 1425 ms, about 1000 ms to about 1400 ms, about 1050 ms to about 1350 ms, about 1100 ms to about 1300 ms, or about 1100 ms to about 1225 ms.

In some embodiments, the brain white matter mimicking material has a T₂ relaxation time at about 3T of about 30 ms to about 100 ms, about 40 ms to about 90 ms, about 35 to about 95 ms, about 45 ms to about 90 ms, or about 50 ms to about 80 ms.

In some embodiments, the brain white matter mimicking material has a dielectric constant at about 127.5 MHz of about 70 F/m to about 100 F/m, about 75 F/m to about 90 F/m, or about 80 F/m to about 85 F/m, or about 81 F/m to about 82 F/m.

In some embodiments, the brain white matter mimicking material has a conductivity of about 0.2 S/m to about 0.45 S/m, about 0.25 S/m to about 0.4 S/m, about 0.3 S/m to about 0.37 S/m, or about 0.34 S/m.

In some embodiments, the brain white matter mimicking material further comprises brain metabolites. For example, the brain metabolites can be selected from N-acetylaspartate (NAA), creatine, choline, lactate, and combinations thereof.

In another aspect, the present disclosure includes a brain white matter mimicking material comprising
about 0.3 w/w % to about 1 w/w % NaCl,
about 0.01 w/w % to about 0.06 w/w % glutaraldehyde,
at least one of MnCl₂ and agarose, and
balance water; and
wherein the MnCl₂, if present, is present at a concentration of about 150 μM or less than 150 μM, and wherein the agarose, if present, is present at a concentration of about 5 w/w % or less than 5 w/w %.

In some embodiments, the brain white matter mimicking material comprises about 140 μM or less than 140 μM MnCl₂, about 130 μM or less than 130 μM MnCl₂, about 120 μM or less than 120 M MnCl₂, or about 116 μM or less than 116 μM MnCl₂.

In some embodiments, the brain white matter mimicking material comprises about 4 w/w % or less than 4 w/w % agarose, about 3 w/w % or less than 3 w/w % agarose, or about 2.5 w/w % or less than 2.5 w/w % agarose.

In some embodiments, the brain white matter mimicking material has a T₁ relaxation time at about 3T of about 650 ms to about 3000 ms, about 700 ms to about 2900 ms, about 750 ms to about 2800 ms, about 800 ms to about 2700 ms, or about 810 ms to about 2600 ms.

In some embodiments, the brain white matter mimicking material has a T₂ relaxation time at about 3T of about 30 ms to about 350 ms, about 35 ms to about 300 ms, of about 40 ms to about 280 ms, or about 43 ms to about 273 ms.

In another aspect, the present disclosure includes a brain grey matter mimicking material of the present disclosure or a brain white matter mimicking material of the present disclosure for use in the preparation of a brain phantom.

In some embodiments, the preparation of the brain phantom comprises casting the brain grey matter mimicking material or the brain white matter mimicking material in a 3-dimensional mould.

In another aspect, the present disclosure includes a brain grey matter mimicking material of the present disclosure or a brain white matter mimicking material of the present disclosure for use in magnetic resonance imaging (MRI) measurement.

In another aspect, the present disclosure includes a use of a brain grey matter mimicking material of the present disclosure or a brain white matter mimicking material of the present disclosure in the preparation of a brain phantom.

In some embodiments, the brain phantom is a fetal brain phantom.

In another aspect, the present disclosure includes a method of preparing a brain matter mimicking material, the method comprising
combining carrageenan, agarose, NaCl, GdCl₃, and NaN₃ in water to obtain a homogenous solution, optionally the combining is carried out with heating and/or stirring;
cooling the homogenous solution;
heating the homogenous solution to about 75° C. to about 85° C. under vacuum; and
cooling the homogenous solution to room temperature.

In some embodiments, the combining is carried out with heating and/or stirring, optionally at about 80° C. to about 100° C., about 85° C. to about 95° C., or about 90° C.

In some embodiments, the cooling homogenous solution is cooled to about 65° C. to about 80° C., about 70° C. to about 75° C., or about 75° C.

### IV. General Description of Embodiments of Muscle Tissue Mimicking Material

In another aspect, the present disclosure includes a muscle tissue mimicking material comprising
about 1 w/w % to about 6 w/w % carrageenan;
about 1 w/w % to about 5 w/w % agarose;
about 15 μmol/kg to about 60 μmol/kg GdCl₃ based on the total weight of the muscle tissue mimicking material;
about 0.1 w/w % to about 5 w/w % NaCl;
about 0.01 w/w % to about 0.06 w/w % NaN₃; and
balance water.

In some embodiments, the muscle tissue mimicking material comprises
about 2 w/w % to about 4 w/w % carrageenan;
about 1.2 w/w % to about 4.5 w/w % agarose;
about 17 μmol/kg to about 55 μmol/kg GdCl₃;
about 0.2 w/w % to about 4.5 w/w % NaCl;
about 0.02 w/w % to about 0.04 w/w % NaN₃; and
balance water.

In some embodiments, the muscle tissue mimicking material comprises
about 2.5 w/w % to about 3.5 w/w % carrageenan;
about 1.5 w/w % to about 4 w/w % agarose;
about 20 μmol/kg to about 50 μmol/kg GdCl₃;
about 0.2 w/w % to about 4 w/w % NaCl;
about 0.025 w/w % to about 0.035 w/w % NaN₃; and
balance water.

In some embodiments, the muscle tissue mimicking material comprises
about 3 w/w % carrageenan;
about 1.8 w/w % to about 3.2 w/w % agarose;
about 20 μmol/kg to about 50 μmol/kg GdCl₃;
about 0.25 w/w % to about 3.5 w/w % NaCl;
about 0.03 w/w % NaN₃; and
balance water.

In some embodiments, the muscle tissue mimicking material has a T₁ relaxation time at about 3T of about 1000 ms to about 1750 ms, about 1100 ms to about 1700 ms, about 1150 ms to about 1650 ms, about 1200 ms to about 1600 ms, about 1200 ms to about 1550 ms, or about 1216 ms to about 1540 ms.

In some embodiments, the muscle tissue mimicking material has a T₂ relaxation time of about 20 ms to about 80 ms, about 25 to about 75 ms, about 30 ms to about 70 ms, about 35 to about 60 ms, about 37 ms to about 60 ms, or about 40 ms to about 55 ms.

In some embodiments, the muscle tissue mimicking material has a dielectric constant at about 127.5 MHz of about 50 F/m to about 100 F/m, about 60 F/m to about 95 F/m, about 65 F/m to about 90 F/m, about 70 F/m to about 90 F/m, or about 75 F/m to about 87 F/m.

In some embodiments, the muscle tissue mimicking material has a conductivity of about 0.075 S/m to about 1.2 S/m, about 0.1 S/m to about 1 S/m, about 0.13 S/m to about 0.9 S/m, about 0.18 S/m to about 0.85 S/m, or about 0.2 S/m to about 0.75 S/m.

In another aspect, the present disclosure includes a muscle tissue mimicking material of the present disclosure for use in the preparation of a body phantom.

In another aspect, the present disclosure includes a muscle tissue mimicking material of the present disclosure for use in a magnetic resonance imaging (MRI) measurement.

In another aspect, the present disclosure includes a use of a muscle tissue mimicking material of the present disclosure in the preparation of a body phantom.

In some embodiments, the body phantom is a fetal body phantom.

In some embodiments, the preparation comprises casting the material in a 3-dimensional mould.

In another aspect, the present disclosure includes a use of a muscle tissue mimicking material of the present disclosure in a magnetic resonance imaging (MRI) measurement.

In another aspect, the present disclosure includes a body phantom comprising a muscle tissue mimicking material of the present disclosure.

In some embodiments, the body phantom has a cavity for housing a brain phantom. In some embodiments, the brain phantom is a brain phantom of the present disclosure. In some embodiments, the body phantom is in the shape of a fetus. In some embodiments, the fetus is a third trimester fetus.

### V. General Description of Embodiments of Placenta Mimicking Material

In another aspect, the present disclosure includes a placenta mimicking material comprising
about 1 w/w % to about 6 w/w % carrageenan;
about 0.01 mM to about 0.05 mM MnCl₂;
about 0.3 w/w % to about 1 w/w % NaCl;
about 0.01 w/w % to about 0.06 w/w % of an antiseptic agent; and
balance water.

In some embodiments, the placenta mimicking material comprises
about 2 w/w % to about 4 w/w % carrageenan;
about 0.02 mM to about 0.04 mM MnCl₂;
about 0.4 w/w % to about 0.8 w/w % NaCl;
about 0.02 w/w % to about 0.05 w/w % of the antiseptic agent; and
balance water.

In some embodiments, the placenta mimicking material comprises
about 2.5 w/w % to about 3.5 w/w % carrageenan;
about 0.03 mM to about 0.035 mM MnCl₂;
about 0.55 w/w % to about 0.75 w/w % NaCl;
about 0.025 w/w % to about 0.04 w/w % of the antiseptic agent; and
balance water.

In some embodiments, the placenta mimicking material comprises
about 3 w/w % carrageenan;
about 0.032 mM MnCl₂;
about 0.63 w/w % to about 0.66 w/w % NaCl;
about 0.03 w/w % of the antiseptic agent; and
balance water.

In some embodiments, the antiseptic agent is selected from glutaraldehyde, NaN₃, NaNO₃, and combinations thereof. In some embodiments, the antiseptic agent is glutaraldehyde.

In some embodiments, the placenta mimicking material further comprises agarose. In some embodiments, the placenta mimicking material comprises less than 0.5 w/w %, less than 0.4 w/w %, less than 0.3 w/w %, less than 0.2 w/w % or less than 0.1 w/w % agarose. In some embodiments, the placenta mimicking material comprises about 0.01 w/w % to about 0.5 w/w %, about 0.01 w/w % to about 0.4 w/w %, about 0.01 w/w % to about 0.3 w/w %, about 0.01 w/w % to about 0.2 w/w %, about 0.01 w/w % to about 0.1 w/w %, or about 0.01 w/w % to about 0.05 w/w % agarose.

In some embodiments, the placenta mimicking material further comprises one or more metabolites selected from citrate, glucose, lactic acid, alanine, cystine, ethanolamine, glutamic acid, glycine, histidine, lysine, proline, glutamine, serine, taurine, threonine, valine, creatine, calcium formate, salts thereof, and mixtures thereof.

In some embodiments, the placenta mimicking material has a T₁ relaxation time at about 3T of about 1200 ms to about 1700 ms, about 1300 ms to about 1600 ms, about 1350 ms to about 1550 ms, about 1400 ms to about 1550 ms, or about 1450 ms to about 1530 ms.

In some embodiments, the placenta mimicking material has a T₂ relaxation time at about 3T of about 200 ms to about 320 ms, about 220 ms to about 300 ms, about 240 ms to about 300 ms, about 260 ms to about 290 ms, or about 270 ms to about 285 ms.

In some embodiments, the placenta mimicking material has a dielectric constant at about 127.5 MHz of about 60 F/m to about 100 F/m, about 70 F/m to about 90 F/m, or about 80 F/m.

In some embodiments, the placenta mimicking material has a conductivity at 127.5 MHz of about 1 S/m to about 2.75 S/m, about 1.3 S/m to about 2.5 S/m, about 1.6 S/m to about 2 S/m, or about 1.85 S/m.

In another aspect, the present disclosure includes a placenta mimicking material of the present disclosure for use in the preparation of a placenta phantom.

In another aspect, the present disclosure includes a use of a placenta mimicking material of the present disclosure in the preparation of a placenta phantom.

In some embodiments, the preparation comprises casting the placenta mimicking material in a 3-dimensional mould.

In another aspect, the present disclosure includes a use of a placenta mimicking material of the present disclosure in a magnetic resonance imaging (MRI) measurement.

In some embodiments, the placenta mimicking material is used in the form of a placenta phantom.

In another aspect, the present disclosure includes a placenta phantom comprising a placenta mimicking material of the present disclosure.

In some embodiments, the placenta phantom mimics a third trimester placenta.

In another aspect, the present disclosure includes a placenta mimicking material comprising
about 2 w/w % to about 4 w/w % carrageenan,
about 0.3 w/w % to about 1 w/w % NaCl,
about 0.01 w/w % to about 0.06 w/w % glutaraldehyde,
at least one of MnCl₂ or agarose, and
balance water; and
wherein the MnCl₂, if present, is present at a concentration of about 2 μM to about 50 μM, and wherein the agarose, if present, is present at a concentration of about 0.01 w/w % to about 3.5 w/w %.

In some embodiments, the placenta mimicking material comprises about 2.2 w/w % to about 3.8 w/w %, about 2.4 w/w % to about 3.6 w/w %, about 2.4 w/w % to about 3.4 w/w %, about 2.6 w/w % to about 3.2 w/w %, or about 3 w/w % carrageenan.

In some embodiments, the placenta mimicking material comprises about 3 μM to about 45 μM MnCl₂, about 4 μM to about 40 μM MnCl₂, about 5 μM to about 38 μM MnCl₂, or about 5.9 μM to about 35 μM MnCl₂.

In some embodiments, the placenta mimicking material comprises about 0.01 w/w % to about 3 w/w % agarose, about 0.01 w/w % to about 2.5 w/w % agarose, or about 0.01 w/w % to about 2.2 w/w % agarose.

In some embodiments, the placenta mimicking material has a T1 relaxation time at about 3T of about 1200 ms to about 2500 ms, about 1300 ms to about 2400 ms, about 1350 ms to about 2300 ms, about 1400 ms to about 2000 ms, or about 1445 ms to about 1950 ms.

In some embodiments, the placenta mimicking material has a T2 relaxation time at about 3T of about 30 ms to about 350 ms, about 35 ms to about 340 ms, of about 40 ms to about 320 ms, or about 45 ms to about 305 ms.

### VI. General Description of Embodiments of Amniotic Fluid Mimicking Composition

In another aspect, the present disclosure includes an amniotic fluid mimicking composition comprising per 100 mL of the composition
about 10 mg to about 13 mg citrate;
about 38 mg to about 44 mg glucose;
about 100 mg to about 106 mg lactic acid;
about 2 mg to about 3 mg alanine;
about 1.3 mg to about 2 mg cystine;
about 0.2 mg to about 0.3 mg ethanolamine;
about 0.3 mg to about 1 mg glutamic acid;
about 0.8 mg to about 1.4 mg glycine;
about 0.4 mg to about 1 mg histidine;
about 1.2 mg to about 2 mg lysine;
about 1 mg to about 1.7 mg proline;
about 3 mg to about 3.6 mg glutamine;
about 0.5 mg to about 1.1 mg serine;
about 1 mg to about 1.8 mg taurine;
about 1 mg to about 1.7 mg threonine;
about 1 mg to about 1.8 mg valine;
about 0.7 mg to about 1.5 mg creatine;
about 10 mg to about 16 mg calcium formate; and
balance water;
wherein the composition has a pH of about 6.8 to about 7.8, about 7 to about 7.6, about 7.2 to about 7.4, about 7.2 to about 7.3, or about 7.25; and
wherein the composition has an osmolality of about 175 mM to about 275 mM, about 200 mM to about 250 mM, about 215 mM to about 235 mM, about 220 mM to about 230 mM, or about 225 mM.

In some embodiments, the amniotic fluid mimicking composition comprises
about 11 mg to about 12 mg citrate;
about 38 mg to about 42 mg glucose;
about 102 mg to about 105 mg lactic acid;
about 2.2 mg to about 2.8 mg alanine;
about 1.4 mg to about 1.8 mg cystine;
about 0.23 mg to about 0.28 mg ethanolamine;
about 0.4 mg to about 0.8 mg glutamic acid;
about 0.9 mg to about 1.2 mg glycine;
about 0.6 mg to about 0.85 mg histidine;
about 1.3 mg to about 1.8 mg lysine;
about 1.15 mg to about 1.55 mg proline;
about 3.15 mg to about 3.45 mg glutamine;
about 0.6 mg to about 0.95 mg serine;
about 1.2 mg to about 1.7 mg taurine;
about 1.2 mg to about 1.6 mg threonine;
about 1.2 mg to about 1.7 mg valine;
about 0.9 mg to about 1.3 mg creatine;
about 11 mg to about 15 mg calcium formate; and
balance water.

In some embodiments, the amniotic fluid mimicking composition comprises
about 11.1 mg to about 11.5 mq citrate:
about 40 mg to about 42 mg glucose;
about 102 mg to about 104 mg lactic acid;
about 2.4 mg to about 2.7 mg alanine;
about 1.5 mg to about 1.7 mg cystine;
about 0.23 mg to about 0.28 mg ethanolamine;
about 0.5 mg to about 0.7 mg glutamic acid;
about 1 mg to about 1.1 mg glycine;
about 0.7 mg to about 0.8 mg histidine;
about 1.4 mg to about 1.7 mg lysine;
about 1.25 mg to about 1.45 mg proline;
about 3.2 mg to about 3.4 mg glutamine;
about 0.7 mg to about 0.85 mg serine;
about 1.3 mg to about 1.6 mg taurine;
about 1.3 mg to about 1.5 mg threonine;
about 1.3 mg to about 1.6 mg valine;
about 1 mg to about 1.2 mg creatine;
about 12 mg to about 14 mg calcium formate; and
balance water.

In some embodiments, the amniotic fluid mimicking composition comprises
about 11.3 mg citrate;
about 41.3 mg glucose;
about 103.1 mg lactic acid;
about 2.6 mg alanine;
about 1.6 mg cystine;
about 0.27 mg ethanolamine;
about 0.6 mg glutamic acid;
about 1 mg glycine;
about 0.76 mg histidine;
about 1.54 mg lysine;
about 1.3 mg proline;
about 3.3 mg glutamine;
about 0.8 mg serine;
about 1.5 mg taurine;
about 1.4 mg threonine;
about 1.5 mg valine;
about 1.1 mg creatine;
about 13 mg calcium formate; and
balance water.

In some embodiments, the amniotic fluid mimicking composition has a pH of about 7.2 to about 7.3, or about 7.25.

In some embodiments, the amniotic fluid mimicking composition has an osmolality of about 220 mM to about 230 mM, or about 225 mM.

In some embodiments, the amniotic fluid mimicking composition further comprises a surfactant, a hormone, a preservative, or a combination thereof. In some embodiments, the surfactant is dipalmitoyl lecithin. In some embodiments, the hormone is prolactin. In some embodiments, the preservative is chlorhexidine.

In another aspect, the present disclosure includes an amniotic fluid mimicking composition of the present disclosure for use in the preparation of an artificial amniotic fluid.

In another aspect, the present disclosure includes a use of an amniotic fluid mimicking composition of the present disclosure in the preparation of an artificial amniotic fluid.

In another aspect, the present disclosure includes a use of an amniotic fluid mimicking composition of the present disclosure in a nuclear magnetic resonance measurement.

In some embodiments, the amniotic fluid mimicking composition mimics the nuclear magnetic resonance spectrum of a human third trimester amniotic fluid.

### VII. General Description of Embodiments of Motion Assemblies

In another aspect, the present disclosure includes a motion assembly for a gravid abdomen phantom having a fetal phantom, wherein the motion assembly comprises:
a motion platform for supporting the fetal phantom;
at least one actuator for controlling movement of the motion platform; and
at least one driving linkage extending between the at least one actuator and the motion platform,
wherein the motion platform is mounted to a tank for housing the fetal phantom and is insertable into a bore of a magnetic resonance imaging scanner.

In accordance with this aspect of this disclosure, which may be used by itself or in combination with one or more other aspects of this disclosure, a fetal phantom 1008 may be supported by a motion assembly 1004. The motion assembly 1004 may be operable to move the fetal phantom 1008 in such a way that it simulates movement of a prenatal fetus. While the description that follows describes the motion assembly for supporting a fetal phantom, it is to be understood that the example motion assemblies described herein may be used to mimic the motion of other phantoms. In addition, as mentioned above, while the description that follows describes the motion assembly mounted to a tank, in other examples, not shown, the motion assembly may be mounted to any support known in the art as it may be desirable to mimic the motion of a phantom with the phantom not positioned within a fluid.

Accordingly, in another aspect, the present disclosure includes a motion assembly, wherein the motion assembly comprises:
a motion platform;
at least one actuator for controlling movement of the motion platform; and
at least one driving linkage extending between the at least one actuator and the motion platform,
wherein the motion platform is mounted to a support and is insertable into a bore of a magnetic resonance imaging scanner.

To simulate the motion of a prenatal fetus, the motion assembly 1004 may be configured to provide the fetal phantom 1008 with up to six degrees of freedom (i.e., may be operable to translate the fetal phantom 1008 along the x, y, and z axes and rotate the fetal phantom 1008 about the x, y, and z axes). In other examples, the motion assembly 1004 may be configured to provide the fetal phantom 1008 with five or less degrees of freedom, for example, four degrees, three degrees, two degrees, one degree, or no degrees of freedom. The motion assembly 1004 is preferably operable to move a fetal phantom 1008 within a tank 1006 at least partially filled with a volume of a liquid. For example, the tank 1006 may contain a volume of artificial amniotic fluid. In a second example, the tank 1006 may contain multiple fluids. Optionally, the tank 1006 may be filled with, for example, water, and a volume of artificial amniotic fluid that may be contained within a silicon bag within the water within the tank 1006. While specific embodiments of examples of motion assemblies 1004 are described below, it is to be understood other suitable motion assemblies 1004, not described, that provide the same functionality, may be used.

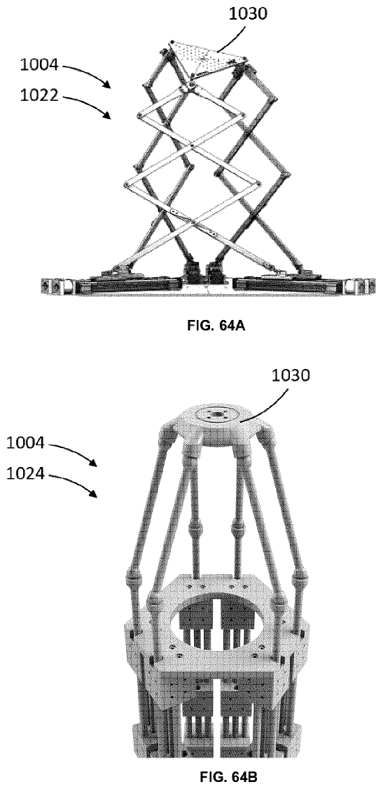

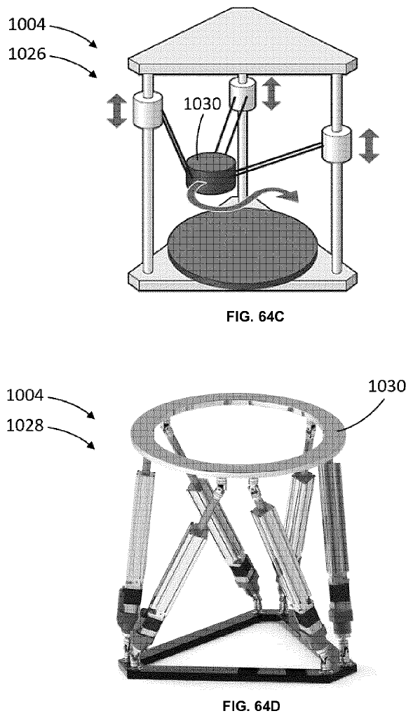

In the examples illustrated in FIGS. 1A,2A, and 68D the motion assembly 1004 resembles a Hexapod 1020 (also known as a Gough-Stewart platform). In other embodiments, the motion assembly 1004 may resemble a six degree of freedom robotic arm, a triple scissor motion mechanism 1022 as shown in FIG. 64A, a hexa-legged with parallel shaft motion mechanism 1024 as shown in FIG. 64B, a delta robot 1026 as shown in FIG. 64C, or a Stewart platform 1028 as shown in FIG. 64D.

As shown in FIGS. 1B and 68D, the motion assembly 1004 may have a motion platform 1030 (see also FIGS. 1D-1F) which may support the fetal phantom 1008. In the example illustrated in FIGS. 1B and 68D, the motion platform 1030 in connected to a rod 1032 which is insertable into a cavity 1016 (see, e.g., FIGS. 65C and 65D) of the fetal phantom 1008 to secure the fetal phantom 1008 to the motion platform 1030. However, it is to be understood that any securement mechanism may be used to connect the motion assembly 1004 (e.g., the motion platform 1030) to the fetal phantom 1008. Further, it is to be understood that the securement mechanism may connect to any part at any position on the fetal phantom 1008.

Movement of the motion platform 1030 may be controlled by a plurality of drivers and/or actuators 1018 (see, e.g., FIGS. 68F-68H). The drivers and/or actuators 1018 may be any drivers and/or actuators or combination of drivers and/or actuators known in the art. For example, the actuators may be hydraulic actuators, pneumatic actuators, piezoelectric motors (optionally non-magnetic piezoelectric motors), and/or DC stepper motors.

As shown in FIG. 68G, driving linkages 1034 may connect an actuator of the plurality of actuators to the motion platform 1030. Any driving linkage 1034 known in the art may be used. In the examples illustrated in FIGS. 1B and 68G, the motion assembly 1004 includes six driving linkages 1034, each of which have a plurality of driving members 1036 which cooperate to transform an output from a respective actuator to movement of the motion platform 1030 within the six degrees of freedom. While not shown, in the example illustrated, each of the six driving linkages 1034 is drivingly connected to a respective actuator.

As described above, the motion platform 1030 may be positioned (a) within the tank 1006 which may be filled with a fluid; and/or (b) within the bore of an MRI scanner. Accordingly, the actuators may be designed to operate within I a fluid and/or within the bore of an MRI scanner, or alternatively, may be positionable outside of the artificial amniotic fluid and/or the bore of the MRI scanner (i.e., be positionable outside the tank 1006).

When the actuators are positioned outside of the tank 1006, the driving linkages 1034 may extend through a respective port 1040 of a plurality of ports within a respective wall 1038 of the tank 1006 to connect the respective actuator to the motion platform 1030. A seal (not shown) may be used to ensure no fluid escapes through the ports 1040 where the driving linkages 1034 extend through the walls 1038 of the tank 1006. Alternatively, as shown in FIG. 2C, the tank 1006 may have an open upper end 1042, and the driving linkages 1034 may extend through the open upper end 1042 of the tank 1006 to connect the respective actuators to the motion platform 1030.

In the example illustrated in FIG. 1A, the motion assembly 1004 resembles a Hexapod 1020 which is positioned within a rectangular tank 1006 having six walls 1038. As shown in FIG. 1C, the motion platform 1030 of the motion assembly 1004 may be driven by three pairs of driving linkages 1034a, 1034b, 1034c. Each pair of driving linkages 1034a, 1034b, 1034c may be positioned at a 120° angle from an adjacent pair of driving linkages 1034a, 1034b, 1034c.

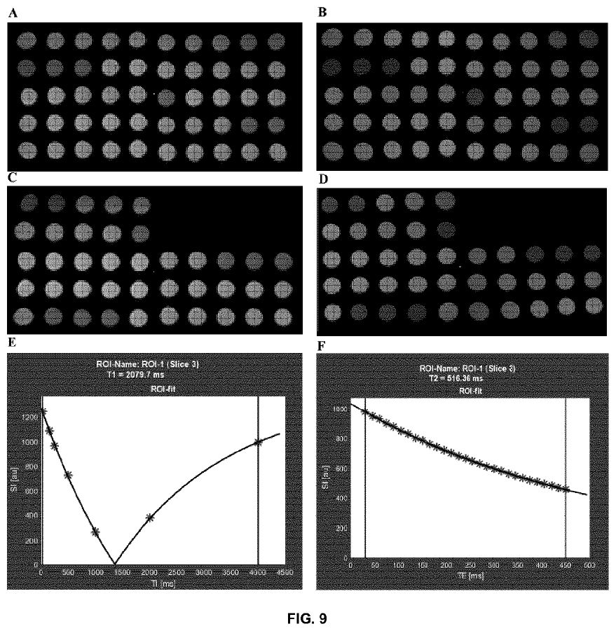

As shown in FIG. 1C, the motion assembly 1004 may further include a plurality of braces 1050 for supporting the driving linkages 1034 within the tank 1006. In the example illustrated, there is one central brace 1050a (see also FIGS. 1G-11), two corner braces 1050b, 1050c (see also FIGS. 1J-1L), and one planar brace 1050d (see also FIGS. 1M-10). It is to be understood that the braces 1050 may have different configurations depending on the shape of the tank 1006, and/or if the motion assembly 1004 resembles something other than a Hexapod 1020.

Still referring to FIG. 1C, in the example illustrated, each driving linkage 1034 includes a driving member 1036 in the form of a lead screw 1036 (the lead screw 1036 is not shown in FIG. 1C, but an example of a lead screw 1036 is shown in FIG. 2B) which is rotatable by the actuator. As exemplified, the lead screws 1036 may extend through a respective wall 1038 of the tank 1006 (specifically, through a respective port 1040). In the example illustrated in FIG. 1C, each of the driving linkages 1034 further includes a driving member 1036 in the form of a leg 1044 that has a first end 1046 that is drivingly connected to the lead screw 1036 and a second end 1048 that is drivingly connected to the motion platform 1030. Accordingly, rotation of the respective lead screw 1036 by a respective actuator will cause a first end 1046 of a respective leg 1044 to translate along the lead screw 1036 either towards or away from the central brace 1050a, depending on the direction of rotation (e.g., clockwise rotation of the lead screw 1036 may cause the first end 1046 of the leg 1044 to translate toward the central brace 1050a and counterclockwise rotation of the lead screw 1036 may cause the first end 1046 of the leg 1044 to translate away from the central brace 1050a).

In the example illustrated in FIG. 1C, the first end 1046 of each leg 1044 is also connected to a respective pair of rails 1054 which may extend parallel to a respective lead screw 1036. As shown, the first end 1046 of each leg 1044 may include a carriage 1056 (see also FIGS. 1P-1S) which may connect the leg 1044 to the respective pair of rails 1054 and to the lead screw 1036. It may be desirable for the first end 1046 of each leg 1044 to be connected to a lead screw 1036 and a pair of rails 1054 to limit twisting/rotation of the carriage 1056. In the example illustrated, the lead screws 1036 pass through a respective port 1040 in a respective wall 1038 of the tank 1006 whereas the rails 1054 only extend between the central brace 1050a and one of the corner braces 1050b, 1050c or the planar brace 1050d.

Referring now to FIG. 2A, a second example of a motion assembly 1004 is illustrated. The motion assembly 1004 shown in FIG. 2A operates in a similar manner to that described with reference to FIGS. 1A-1S. However, as shown in FIG. 2A, the motion assembly 1004 illustrated is mounted to a base 1058, which is mountable to a tank 1006.

More specifically, as shown in FIG. 2C, the base 1058 may be mounted at an open end 1042 of the tank. Accordingly, the motion assembly 1004 may suspend a fetal phantom 1008 within the tank 1006. It is to be understood that the motion assembly 1004 may not include a base 1058, and components of the motion assembly 1004 may be secured directly to the tank 1006. It may be desirable to position components of the motion assembly 1004 external to the tank 1006, as is shown in FIG. 2C, so that at least a subset of the components of the motion assembly 1004 are not subjected to liquid that may be within the tank 1006.

In the example illustrated in FIG. 2C, not all driving linkages 1034 that would connect respective actuators to the motion platform 1030 are illustrated. As shown, the driving linkages 1034 may include a driving member 1036 in the form of an elbow 1070 (e.g., a universal joint) to change the angle between connected driving members.

Referring now to FIG. 2F, the gravid abdomen phantom illustrated in FIG. 2C is shown positioned in the bore 1072 of an MRI scanner 1074. As shown, an actuator support 1076 may be mounted to a patient table 1078 of the MRI scanner 1074. The actuator support 1076 may support the actuators which drive movement of the motion platform 1070. The actuator support 1076 may be otherwise positioned. For example, the actuator support 1076 may not be mounted to the patient table 1078, and the actuators may be external to room housing the MRI scanner 1074. As a second example, the actuators may be positioned on a table which may be brought into the room housing the MRI scanner. In the example illustrated, the actuator support 1076 is positioned a sufficient distance from the bore 1072 for it to be constructed of at least one of aluminum and plastic.

Referring now to FIGS. 68A to 68H, a third example of a motion assembly 1004 is illustrated. The motion assembly 1004 shown in FIG. 68A to 68H operates in a similar manner to that described with reference to FIGS. 2A to 2F. Like the embodiment shown in FIG. 2A, the motion assembly 1004 illustrated in FIG. 68A is mounted to a base 1058, which is mountable to a tank 1006.

As shown in FIG. 68A, the base 1058 may be mounted at an open end 1042 of the tank. Accordingly, the motion assembly 1004 may suspend a fetal phantom 1008 within the tank 1006. It is to be understood that the motion assembly 1004 may not include a base 1058, and components of the motion assembly 1004 may be secured directly to the tank 1006. It may be desirable to position components of the motion assembly 1004 external to the tank 1006, as is shown in FIG. 68A, so that at least a subset of the components of the motion assembly 1004 are not subjected to liquid that may be within the tank 1006.

Like the example shown in FIGS. 2A to 2F, in the example shown in FIGS. 68A to 68E, the driving linkages 1034 may include a plurality of driving members 1036 which cooperate to transform an output from a respective actuator to movement of the motion platform 1030. The example shown in FIG. 68A to 68E differs from that of FIGS. 2A to 2F in that the driving linkages 1034 in the example shown approach the tank 1006 (i.e., enter within an upward projection of the tank 1006) proximate the same end of the tank 1006.

Accordingly, as shown in FIG. 68C, the driving linkage 1034a may extend above the fetal modeling system 1002. More specifically, the driving linkage 1034a may extend above central brace 1050a.

Like the example illustrated in FIGS. 1A to 1S, in the example illustrated in FIGS. 68A to 68E, each driving linkage 1034 includes a driving member 1036 in the form of a lead screw 1036 which is rotatable by the actuator 1018. In the example shown in FIGS. 2A to 2F, each of the lead screws 1036 connects to an adjacent driving member 1036 (i.e., drive members provided between the actuators 1018 and the lead screw 1036) proximate the tank sidewall. In the example shown in FIG. 68C, a pair of lead screws connect to adjacent driving members proximate the central brace 1050a. In the example illustrated in FIG. 1C, each of the driving linkages 1034 further includes a driving member 1036 in the form of a leg 1044 that has a first end 1046 that is drivingly connected to the lead screw 1036 and a second end 1048 that is drivingly connected to the motion platform 1030. With reference to FIG. 68E, in the example shown, the first end 1046 of the leg 1044 includes a clevis joint 1086. With reference to FIG. 68D, in the example shown, the second end 1048 of the leg 1044 includes a u-joint 1088.

Referring now to FIG. 68E, in the example illustrated, the first end 1046 of each leg 1044 is also connected to a respective rail 1090 which may extend parallel to a respective lead screw 1036. As described above, it may be desirable for the first end 1046 of each leg 1044 to be connected to a lead screw 1036 and a rail 1090 to limit twisting/rotation of the carriage 1056.

Referring now to FIG. 68F, the gravid abdomen phantom illustrated in FIG. 68A is shown positioned in the bore 1072 of an MRI scanner 1074. As shown, an actuator support 1076 may be mounted to a patient table 1078 of the MRI scanner 1074. The actuator support 1076 may support the actuators 1018 which drive movement of the motion platform 1070. The actuator support 1076 may be otherwise positioned. For example, the actuator support 1076 may not be mounted to the patient table 1078, and the actuators may be external to the room housing the MRI scanner 1074. In the example illustrated, the actuator support 1076 is positioned a sufficient distance from the bore 1072 for it to be constructed of at least one of aluminum and plastic.

Referring now to FIG. 68H, the actuator support 1076 may include driving linkage mounts 1080. As shown, the driving linkage mounts 1080 may be retractable. The driving linkage mounts 1080 may support a distal end 1082 of the driving linkages 1034 while assembling the gravid abdomen phantom 1000. The driving linkage mounts 1080 may also support the distal ends 1082 of the driving linkages 1034 when in use to reduce the stress applied to the actuators 1018 due to the weight of the driving linkages 1034.

It is to be understood that in other embodiments, the motion assembly 1004 may resemble something other than a Hexapod 1020, e.g., may resemble a motion assembly 1004 as shown in any one of FIGS. 2A-2D, and may similarly be positioned within a tank 1006 and be connected to external actuators.

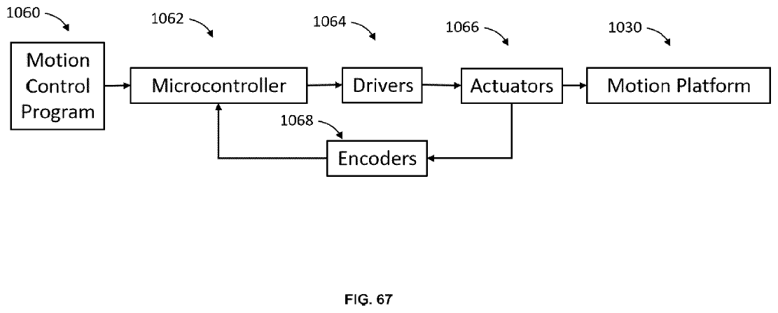

Referring now to FIG. 67, the motion assembly 1004 may include additional hardware and software components to those described above. For example, as shown in FIG. 67, a motion control program 1060 (e.g., MATLAB) may be used to generate a script which, when executed, will cause the fetal phantom 1008 to simulate the motion of a prenatal fetus.

More specifically, in one example, based on desired prenatal movements selected by an operator, the motion control program 1060 may be used to generate a script which may determine the number and sequence of revolutions each lead screw 1036 is to turn to cause the fetal phantom 1008 to simulate a specific motion or series of motions. A microcontroller 1062 (e.g., an Arduino) may issue commands to each actuator 1066 via a respective driver 1064 so they step about simultaneously. It is noted that the microcontroller 1062 may only issue one command at a time, however, when the microcontroller 1062 can process commands at high frequencies (i.e., about 84 MHZ) the delay between the commands is negligible.

If there is a discrepancy between the planned actuator positioning and the actual actuator positioning, an encoder 1068 may correct for that error. Additionally, there may be limit switches 1096 (see FIG. 68E) for each actuator 1066 to home the motion assembly 1004 each time it is started up. Since the encoders 1068 trigger interrupt sequences from the microcontroller 1062 (a type of blocking function), no command is issued until the position of the actuator 1066 is corrected. The missed steps can be assumed to be very few and can be quickly corrected for, therefore the delay it will cause will be negligible.

### EXAMPLES

The following non-limiting examples are illustrative of the present disclosure.

### Relaxation Time T1/T2 and Conductivity

Many physical phantoms only mimic either T₁ or T₂ relaxation times of a chosen simulated tissue. Yet, it is desirable that both relaxation times are mimicked to be able to test quantitative MR sequences and to ensure versatility of the phantom. This may be attributed to the acquisition of reference MR patient scans, and unique purposes of the phantom study.

### Phantom Manufacturing

Suitable phantom manufacturing techniques can range from simple to complex depending on the phantom requirements. For example, phantom development can consist of an aqueous-based medium doped with a contrast agent. However, when geometry is considered, in order for the aqueous solution to retain a desired shape, an external housing can be used which would result in boundary effects creating artifacts in the image [30], [38]. Hydrogels provide an excellent alternative due to their tissue mimicking properties and ability to retain shape [33].

3D printing can be used in conjunction with phantom manufacturing. A 3D printer allows for direct printing of phantoms, or indirect printing of a negative phantom mould, which can then be filled with the desired material. In combination with imaging modalities such as MRI, PET, SPECT, or ultrasonography, the design of the mould can be created with accurate dimensions, and near perfect anatomical accuracy limited by the quality of the image acquisition [39].

An exemplary 3D-printed mould was used to create a placenta phantom as shown in Examples 2 and 3.

### Example 1 Brain Matter Mimicking Material

### Preparation of Brain Matter Mimicking Material

NaCl was tested in the range of 1.04%-2.54% for grey matter, and 0.459%-1.209% for white matter. Each sample was replicated three times to prepare a total of 42 samples for this experiment. In order to decrease the relaxation times of the white matter phantom, GdCl₃ was tested in the range of 75 μmol/kg to 95 μmol/kg. A 100 μmol/kg stock solution was prepared for each concentration of GdCl₃. A total of 15 samples were made for this experiment and each concentration had 3 replicate samples. Serial dilution was done for each replicate sample to show reproducibility. The chemical formulation of these protocols can be found in Table 1.

TABLE 1
CG sample experimental concentrations

| | | | | |
|---|---|---|---|---|
| Carrageenan | Agarose | GdCl₃ | NaCl | NaN₃ |
| (W/W %) | (W/W %) | (umol/kg) | (W/W %) | (W/W %) |

Experiment 1: NaCl concentration

| | | | | | |
|---|---|---|---|---|---|
| White | 3% | 0.681% | 37.9 | 0.459%-1.209% | 0.03% |
| Matter | | | | | |
| Grey | 3% | 1.139% | 75.8 | 1.04%-2.54% | 0.03% |
| Matter | | | | | |

Experiment 2: GdCl₃ concentration

| | | | | |
|---|---|---|---|---|
| White | 3% | 1.139% | 75-95 umol/kg | 0.834% |
| Matter | | | | |

All sample components were premeasured and dissolved in distilled water. Samples were then stirred to mix all components together before being heated to approximately 90° C. to dissolve agarose and stirred frequently to create a homogeneous solution. Samples were then removed from heat until they reached 75° C., and then transferred into 50 ml Falcon tubes. The tubes were quickly placed in a hot water bath of approximately 80° C. to remove remaining air bubbles. Completed samples were stored in a refrigerator and taken out to reach room temperature before being scanned using MRI.

### Characterisation of MR Images

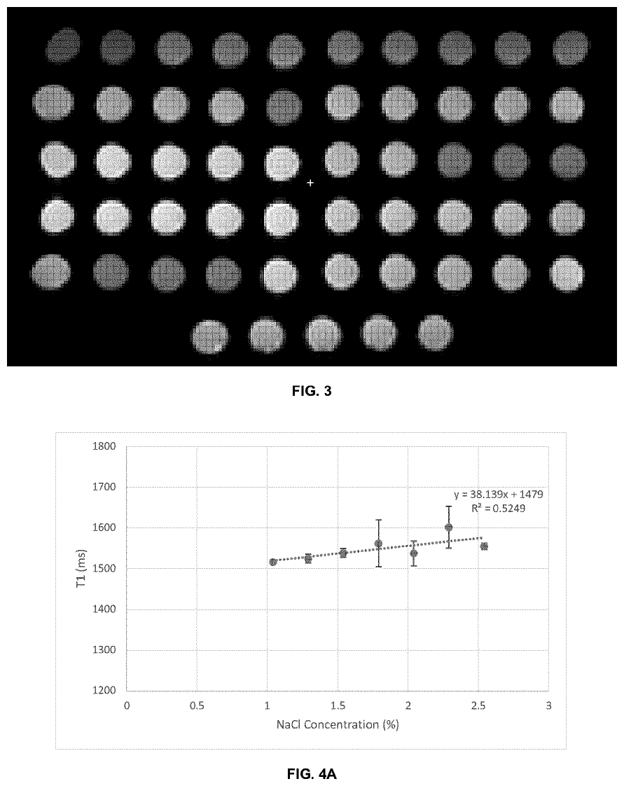

The CG phantoms were placed in sample trays and T1 and T2 relaxation times were measured and collected using a 3.0 T MRI scanner (Skyra, Siemens, Erlangen, Germany). Five slices of the transverse plane were collected using the scanner. The inversion recovery sequence included inversion times (TI=23, 150, 250, 500, 1000, 2000, 4000 ms), fixed echo time (TE=8.1 ms) and repetition time (TR=9000 ms) was used to acquire the T1 relaxation times. T2 values were acquired using a multi-echo sequence with echo times (TE=8.5, 17, 25.5, 34, 42.5, 51, 59.5, 68, 76.5, 85, 93.5, 102, 110.5, 119, 127.5, 136, 144.5, 153, 161.5, 170. 178.5, 187, 195.5, 204, 212.5, 221, 229.5, 238, 246.5, 255, 263.5, 272 ms) and a fixed repetition time (TR=500 ms). Once images were acquired. a program called Segment (Medviso, Lund, Sweden) was used to quantify T₁ and T₂ relaxation times of each sample from MR images (FIG. 3). The theoretical MRI signal(S) in an image is dependent on the following equation.

$$S = {S}_{0} ( 1 - exp ( - \frac{TR}{T 1} ) ) exp ( - \frac{TE}{T 2} )$$

So represents the maximal measurable signal, TR is the interval between excitation RF pulses, and TE represents the time between the excitation RF pulse and the echo. This equation indicates that slight alterations in TR and TE values can alter the measured signal. For images with greater T₁-weighted effects, shorter TR and TE are used, and images with greater T₂-weighted effects, longer TR and TE are used [43].

### Graph and Statistical Analysis

Extracted relaxation times were then copied into an excel spreadsheet. Scatter plot graphs were then created to plot concentration of either NaCl or GdCl₃ against T₁ and T₂ times. Error bars were added using standard error of the mean (SEM), and trendline was added to visualize correlation of relaxation time and chemical concentration. R² values were calculated for each experiment to measure goodness-of-fit in the regression line on the scatter plots. It determines how well the model explains changes in T₁ and T₂ relaxation times. To test the statistical significance of the data, an ANOVA with a post-hoc Tukey Honestly Significant Difference (HSD) statistical tests were done to compare the different sample groups in each experiment. P values were calculated at a confidence level of 95%, where values <0.05 were considered statistically significant.

### Dielectric Measurements

The conductivity and dielectric constants of the CG phantom were tested with appropriate relaxation times within the range of human white and grey matter brain tissues. Electric properties of the CG phantom were compared to specific target tissues. Human tissues have a wide range of conductivities that makes them unique from one another. To create an accurate phantom for white and grey brain matter, it is desirable that conductivity values of the phantom are similar. Keysight N5232B PNA-L Network Analyzer (Keysight, Santa Rosa, California) was used along with a high-temperature probe N1501A (Keysight, Santa Rosa, California) in the frequency range of 1-201 Mz to measure conductivity and dielectric constant. Preparation of CG samples followed the same procedure as for the relaxometry. The samples were prepared in 150 ml beakers to account for the size of the probe. Once samples were heated, they were placed in a vacuum desiccator to remove air bubbles before measurement. White and grey matter samples were replicated three times each to demonstrate reproducibility of measurement. Conductivity and dielectric constant of the samples were extracted at 127 MHz, which is the resonant frequency of hydrogen atoms in the 3.0T MRI scanner. Keysight material measurement suite 2018 (Keysight, Santa Rosa, California) collected dielectric constant (ε′) and dielectric loss (ε″) values and were extracted in to excel charts. Conductivities of samples were calculated using the following equation where ω=γB, γ=42.57747×10⁶ rad·s⁻¹·T⁻¹, B=3.0T, εₒ=8.85×10⁻¹² F/m, and tan δ=ε″/ε′.

$$σ = {ε}_{0} \times ω \times {ε}^{′} \times tan δ$$

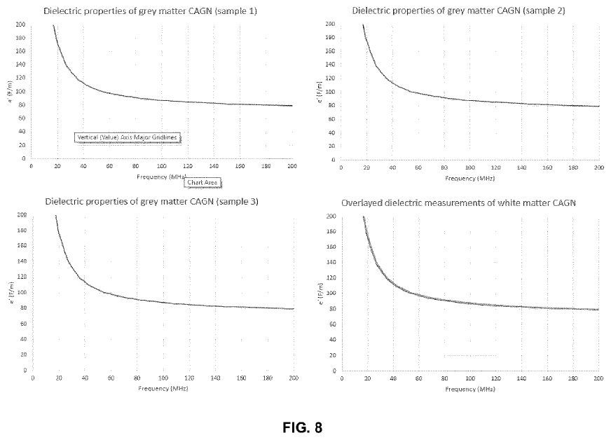

Conductivity and dielectric constant of phantom samples were then compared to dielectrics of white and grey matter brain tissue (Table 2). A line graph was then plotted using the dielectric constant of the material at a given frequency (MHZ) (FIGS. 7 and 8). A Dielectric Assessment Kit (DAK) (Speag, Switzerland) was also used to verify these measurements. This system is a precision dielectric measurement system that can measure dielectric properties in the frequency range of 4 MHz to 67 GHz. This is an open-ended coaxial probe and is designed for liquids, solids, and semi-solids. The DAK extracts dielectric constant (ε′), dielectric loss (ε″), conductivity (σ), loss tangent (tan δ), and reflectance into an excel sheet for frequencies in a selected range.

### Relaxometry and Dielectric Testing Results

### Relaxometry: NaCl and GdCl₃ Concentration in CG Phantom

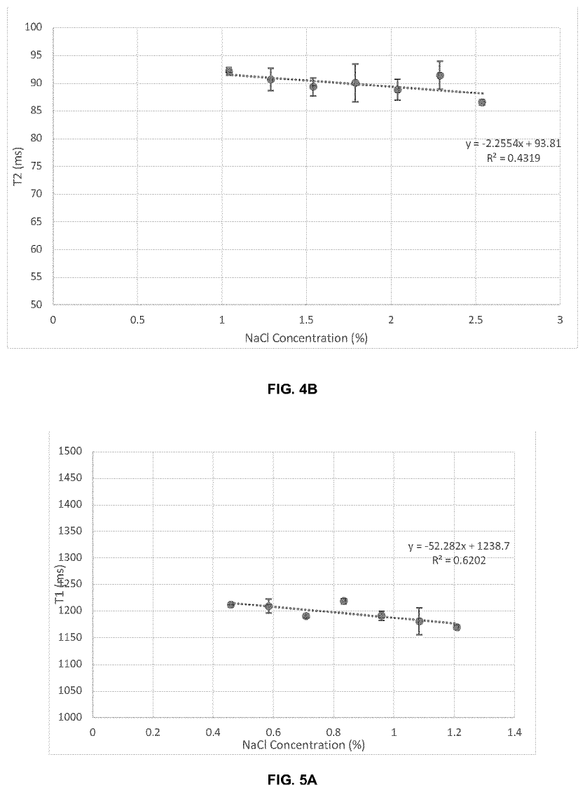

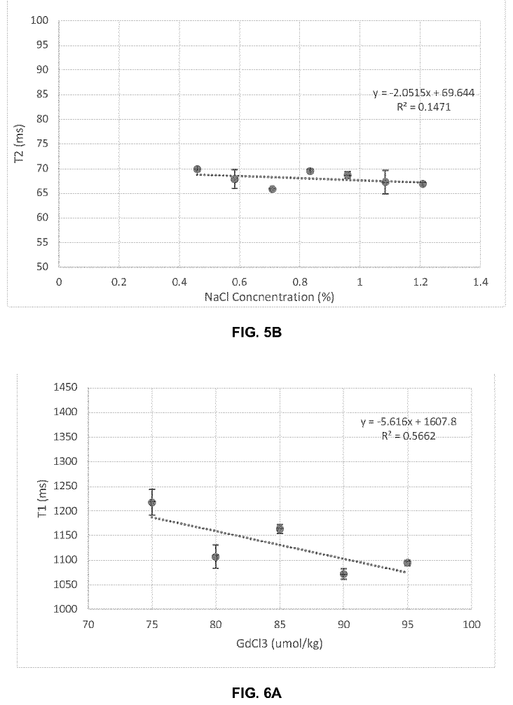

Results of all experiments were displayed using scatter plot graphs, T₁ and T₂ values presented represent the average of all three replicates for each respective concentration. Error bars represent the SEM between the replicate samples in each concentration group (FIGS. 4 to 6). The first experiment conducted was to test the relationship between NaCl and relaxation times in the CG phantom samples. The results revealed that NaCl concentration ranging from 1.04%-2.54% did not affect the T₁ of the grey matter phantom significantly (p>0.05) with a linear regression R² value of 0.5249 (FIG. 4A). The trendline showed only a slight increase in T₁ which was not a significant difference across all 7 samples. The spread of T₁ values was over less than 100 ms range (1515.6 ms-1601.1 ms). Similarly, grey matter T₂ values samples showed a small decrease in T₂ values as NaCl increased; however, the difference was insignificant p>0.05 (FIG. 4B). T₂ values varied by less than 10 ms throughout all tested NaCl concentrations (86.5 ms-92.1 ms). The linear regression resulted in an R² value of 0.4319. White matter phantom produced a similar relationship with NaCl concentrations ranging from 0.459%-1.209%. T₁ of white matter phantom showed a slight decrease in the linear regression trendline, but there was no significant difference in values with p>0.05 (R²=0.6202) (FIG. 5A). T1 values ranged by less than 50 ms across all samples (1168.8 ms-1217.9 ms). T2 in the white matter phantom was also not significantly affected by NaCl concentration, p>0.05, R²=0.1471 (FIG. 5B). The range of T₂ values was less than 3 ms through all samples (66.9 ms-69.8 ms).

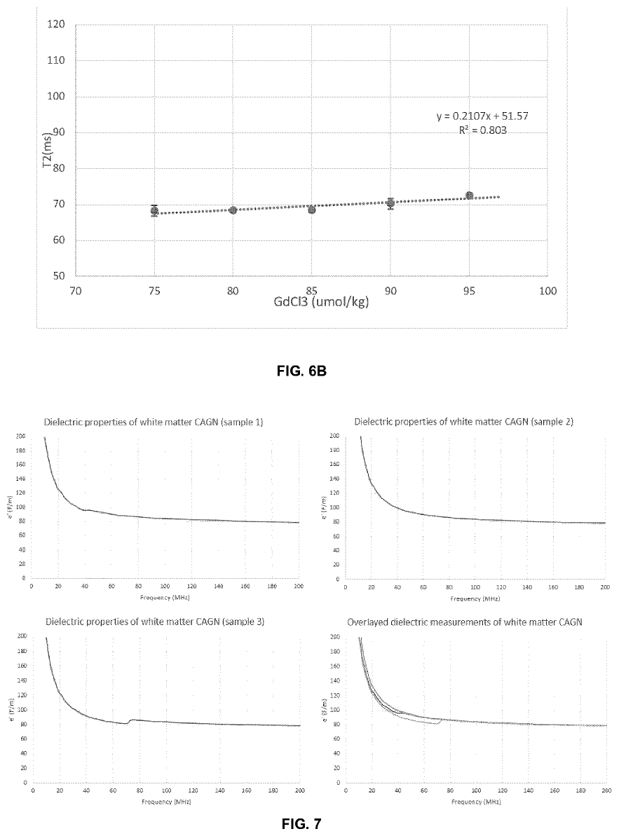

The second experiment conducted tested the relationship between GdCl₃ and relaxation times of the white matter CG phantom. Additionally, this experiment determined the appropriate concentration of GdCl₃ for the white matter phantom. The previous research protocol had a lower GdCl₃ concentration, which produced white matter phantom samples with T₁ much higher than the average human brain. The range of GdCl₃ concentrations for the current experiment was 75 μmol/kg-95 μmol/kg. As the concentration of GdCl₃ increased, the T1 of the phantom decreased, as seen in the linear trendline of FIG. 6A. The varied GdCl₃ concentrations produced a significant difference in T₁ values with a p-value<0.05 (R²=0.5662). The range of T₁ values was almost 150 ms throughout all concentrations. (1071.6 ms-1217.1 ms). The T₂ of the phantom, however, did not show a significant difference in T₁ values with a change in GdCl₃ concentration. The linear trendline showed a slight increase in concentration, but there was no significant relationship (p>0.05) (R²=0.803). The range of T₂ values through all samples was less than 5 ms (68.1 ms-72.5 ms).

The results of experiment 1 demonstrated that NaCl does not have a significant effect on T₁ or T₂. The second relaxometry experiment was done to test the effect of GdCl₃ on T₁ and T₂ of CG phantom, and to modify the T₁ of the white matter CG phantom. Experiment 2 determined that the increase of GdCl₃ was proportional to the decrease of T₁, and no significant relationship for T₂ relaxation time. The data shows that the CG phantom produced relaxation times that mimic white brain matter. The GdCl₃ concentration 95 μmol/kg was able to lower the T₁ of the white matter phantom from an average of 1225 ms to 1100 ms, which is within the range of T₁ white matter values of human brain tissue (812 ms-1110 ms).

Using 3.0T MRI, the normal ranges of relaxation times in white and grey matter in the brain are as follows: white matter T₁ values range from 812.3-1110.0 ms and T₂ ranges from 49.5-79.6 ms, and grey matter T₁ and T₂ values range from 1275.0-1763.0 ms and 66.0-110.0 ms, respectively [27]. In the NaCl experiment 1, the T₁ white matter values did not fall within the normal range of human tissue. However, all other relaxation times covered the spectrum of human tissues in white matter and grey matter. In the second experiment, GdCl₃ modified the T₁ of white matter to fall within the range of human tissues. Accordingly, this CG phantom is suitable to mimic the relaxation times of brain tissue.

### Dielectric Testing Results

TABLE 2
Dielectric properties of CG phantoms

| | | Dielectric | |
|---|---|---|---|
| | Tissue | constant | Conductivity |
| | Type | (F/m) | (S/m) |
| CG phantom | White matter | 81.8 | 0.34 |
| updated protocol | Grey matter | 84.2 | 0.56 |
| Human brain | White matter | 53 | 0.34 |
| tissue | Grey matter | 74 | 0.59 |

Dielectric properties of the CG phantom mimicked both white and grey matter of human brain tissue. Dielectric constant and conductivity of each phantom was measured using the Keysight dielectric assessment equipment. The dielectric properties were measured from three replicate samples of each brain tissue to ensure reproducibility. The average measured values at 127 MHz were compared to our previous CG protocol, as well as to values of actual human tissue (Table 2).

For white matter samples, the dielectric constant and conductivity ranged from 81.6-82.0 F/m and 0.34-0.35 S/m respectively (FIG. 7). The average dielectric constant and conductivity of the sample was 54.3% and 0% different from the human tissue values. For grey matter samples, the dielectric constant and conductivity ranged from 83.8-84.5 F/m and 0.54-0.56 S/m respectively (FIG. 8). The average dielectric constant and conductivity of the sample was 14% and 5.1% different from the human tissue values respectively.

The modification of GdCl₃ concentration in the white matter phantom did not affect the dielectric properties of the material. This is consistent with previous literature, in that addition of relaxation time modifiers have little effect on conductivity due to the small concentrations of these chemicals in the phantom [11]. The relationship between the dielectric constant of CG in white and grey matter and frequency can be found in (FIGS. 7 and 8). The results of these measurements demonstrated great reproducibility of white and grey matter CG phantom samples with consistent dielectric properties.

### Conclusion

MRI relaxometry included testing of both white and grey matter using varying concentrations of GdCl₃ and NaCl. The first experiment demonstrated that NaCl concentration did not have a significant effect on T1 and T2 relaxation times of either white or grey matter. Concentrations of NaCl ranged from 1.04%-2.54% and 0.459%-1.209% for white and grey matter, respectively. T1 relaxation was modified using gadolinium chloride since the unpaired electrons in gadolinium chloride render it paramagnetic, which causes T1 shortening [26]. T2 relaxation time modifier used was the gelling agent agarose gel. T2 relaxation times of agarose is very similar to that of human tissues, and thus can be modified by altering the concentration of the gelling agent [14]. Prior studies demonstrate a slight increase in T2 with low concentrations of agarose below 0.5 w/w % and increasing concentrations of NaCl; however, this was not seen in the present results, as the present experiment had fixed agarose concentrations that were higher than 0.5 w/w % for both white and grey matter. The second experiment demonstrated that GdCl₃ concentration has a significant effect on T1 relaxation. As GdCl₃ concentration increased in the range of 75 μmol/kg-95 μmol/kg, the T1 decreased significantly. As a paramagnetic additive, GdCl₃ is an efficient source of relaxation that affects the relaxation times of liquids even when present at low concentrations. The large number of unpaired electrons in this additive acts as a magnetic dipole that creates a large local field distortion [28]. Thus, increasing relaxation rates of neighboring molecules, and shortening relaxation time. Gadolinium has paramagnetic properties which shorten both T1 and T2; however, it has a dominant shortening effect on T1 relaxation because in most tissues T1 is much longer than T2 [29]. As shown herein, a change in GdCl₃ concentration did not have a significant effect on T2 relaxation. It is shown here that the T1 of the white matter can be attained when GdCl₃ concentration is about 80 μmol/kg to about 120 μmol/kg based on the total weight of the brain white matter mimicking material, for example about 95 μmol/kg.

Dielectric measurement of the CG phantom included measuring the dielectric constant of the materials as well as the conductivity. Both white and grey matter phantoms had measurements very close to human brain tissues.

Taken together, hydrogel phantoms are attractive for MRI studies and have chemical and mechanical properties that are very similar to many human soft tissues. These materials are highly useful for phantom studies that require large and sturdy phantoms able to mimic conductivity and T1 and T2 relaxation times. Many studies report homogeneous phantoms that are only used for quality assurance purposes and cannot mimic specific tissues. In the current study, the hydrogel CG along with a contrast agent was used. It was shown that this material is suitable for use in making MRI phantoms that mimic a variety of human tissues' relaxation times, including those of white and grey matter. These CG phantoms can be cast to provide an anthropomorphic model of the human brain.

### Example 2 Placenta Mimicking Material

Previous studies of phantom materials by Hattori et al. used GdCl₃ as T₁ modifier. However, based on the description in Hattori et al., their phantom material cannot achieve combinations of relaxation values of the human placenta. In the present study, the T₁ modifier from GdCl₃ to MnCl₂ due to the slightly weaker relaxivity properties of MnCl₂ caused by a smaller number of unpaired electrons. This weaker relaxivity will allow for a wider range of relaxation values, specifically the inclusion of relaxation properties with lower T₁ and higher T₂ values needed to mimic the placenta.

### Preparation of Carrageenan Hydrogel

The exemplary placenta mimicking material created for the phantom consisted of deionized water mixed with 3 w/w % carrageenan as a gelatinizer base, and 0.656 w/w % NaCl to match the dielectric properties of blood due to blood sharing similar dielectric properties as the placenta [41]. To prevent bacterial growth within the carrageenan, an antimicrobial agent was used. For example, 0.03 w/w % glutaraldehyde was used to replace sodium azide used by Hattori et al due to glutaraldehyde's safer handling and disposal [42]-[44]. Manganese Chloride (MnCl₂) was used as a T₁ modifier, and agarose was used as a T2 modifier. To create a wide range of relaxation values, concentrations were used in the range of 0-0.5 mM for MnCl2, and 0-1.5 w/w % for agarose. The samples were prepared in 50 ml conical tubes in triplicate, for a total of 90 samples. The exact contents of each sample are described in Table 3.

TABLE 3
Concentrations of agarose and MnCl₂ for each
triplicate, with corresponding sample number

| | Agarose | MnCl₂ |
|---|---|---|
| Sample # | (w/w %) | (mM) |
| 1-3 | 0 | 0 |
| 4-6 | 0 | 0.01 |
| 7-9 | 0 | 0.03 |
| 10-12 | 0 | 0.06 |
| 13-15 | 0 | 0.15 |
| 16-18 | 0 | 0.5 |
| 19-21 | 0.1 | 0 |
| 22-24 | 0.1 | 0.01 |
| 25-27 | 0.1 | 0.03 |
| 28-30 | 0.1 | 0.06 |
| 31-33 | 0.1 | 0.15 |
| 34-36 | 0.1 | 0.5 |
| 37-39 | 0.5 | 0 |
| 40-42 | 0.5 | 0.01 |
| 43-45 | 0.5 | 0.03 |
| 46-48 | 0.5 | 0.06 |
| 49-51 | 0.5 | 0.15 |
| 52-54 | 0.5 | 0.5 |
| 55-57 | 1.0 | 0 |
| 58-60 | 1.0 | 0.01 |
| 61-63 | 1.0 | 0.03 |
| 64-66 | 1.0 | 0.06 |
| 67-69 | 1.0 | 0.15 |
| 70-72 | 1.0 | 0.5 |
| 73-75 | 1.5 | 0 |
| 76-78 | 1.5 | 0.01 |
| 79-81 | 1.5 | 0.03 |
| 82-84 | 1.5 | 0.06 |
| 85-87 | 1.5 | 0.15 |
| 88-90 | 1.5 | 0.5 |

To prepare each sample, 3% w/w carrageenan (Sigma Aldrich, Canada), 0.656 w/w % NaCl (VWR, Canada), and 0.03% glutaraldehyde (VWR, Canada) were pre-measured using an analytical balance. Type 1 low EEO agarose powder (Sigma Aldrich, Canada), and manganese (II) chloride tetrahydrate (MnCl2·4H2O) stock solution were measured in amounts according to the associated sample number. The samples were dissolved in deionized water to create a 50 ml sample. The samples were vigorously mixed at room temperature in order to disperse the carrageenan and agarose powders, then slowly heated to 90° C. to fully dissolve the carrageenan and agarose solutes. Once heated, the samples were immediately transferred to a 50 mL falcon tube, then placed in a desiccator under vacuum to degas the gel. Degassing aids in eliminating any air bubbles present in the material to ensure homogeneity. Once cooled to room temperature, the samples were stored at 4.1° C. until needed for testing. 24 hours before the samples were used for imaging, they were placed at room temperature to allow the samples to come to equilibrium with the environment.

### Relaxometry Measurements

To measure the relaxation properties of the samples, images were acquired using the body coil of a Skyra™ 3.0 T scanner (Siemens, Erlangen, Germany). To acquire information about T1, an inversion recovery sequence was used with logarithmically spaced inversion times (TI=23, 150, 250, 500, 1000, 2000, 4000 ms). The repetition time (TR) was set to 9000 ms for all images, with a fixed echo time of 8.1 ms.

A multi-echo spin echo sequence was used to acquire T2 values, with 32 echo times (TE=15, 30, 45, 60, 75, 90, 105, 120, 135, 150, 165, 180, 195, 210, 225, 240, 255, 270, 285, 300, 315, 330, 345, 360, 375, 390, 405, 420, 435, 450 ms) and with TR set to 9000 ms for all images.

The slice thickness for both sequences were 6 mm with a 9 mm slice gap, for a total of 5 image slices with an X and Y resolution of 2.3438 mm. The samples were arranged in trays holding 25 samples in a 5×5 grid with the scanner fitting two trays per scan.

Post-processing was performed using Segment software (Medviso, Lund, Sweden) for the calculation of T1 and T2 values. Circular ROIs with a 2 cm diameter were manually selected at the center of each sample for each slice to avoid the possibility of any edge artifacts. The resulting signal intensities for each ROI were determined using Segment. The signal intensities were fitted to the mono-exponential equations from which the associated T1 and T2 relaxation times were determined.

The T1 and T2 relaxation rates (1/T1 and 1/T2) were plotted as a function of varying MnCl₂ concentrations for each concentration of agarose. Additionally, the relaxation rates were plotted as a function of varying agarose concentrations for each concentration of MnCl₂. Linear least-squares regression was used on each plot, from which the slope was used to determine the relaxivities of MnCl₂ in each concentration of agarose. This method was repeated to determine the relaxivities of agarose in each concentration of MnCl₂. The goodness of fit was evaluated using the 95% confidence interval and associated R2 value. Using these values, the relaxation time of the material can be predicted given the concentrations of the contrast agents utilizing the equation

$$\frac{1}{{T}_{i}} = \frac{1}{{T}_{i}^{0}} + {r}_{iM} [ M ] + {r}_{iA} [ A ] ; i = 1 , 2$$

### Placenta Mould Design and 3D Printing

### Design of an Anatomically Correct Placenta

To make an exemplary placenta phantom that had accurate anatomical structure and dimensions, an MRI data set consisting of 26 anonymized 35-37-week-old fetal scans were obtained. The data set was examined in the image processing software Amira™ (Therma Fisher Scientific, Waltham, MA), and 5 artifact-free fetal scans were selected where the placenta could be easily identified and had a largest diameter between 17-21 cm. The diameter was measured using the built-in measuring tools in Amira. This range of size represented the average diameter of a healthy 3^{rd} trimester placenta [31], [32].

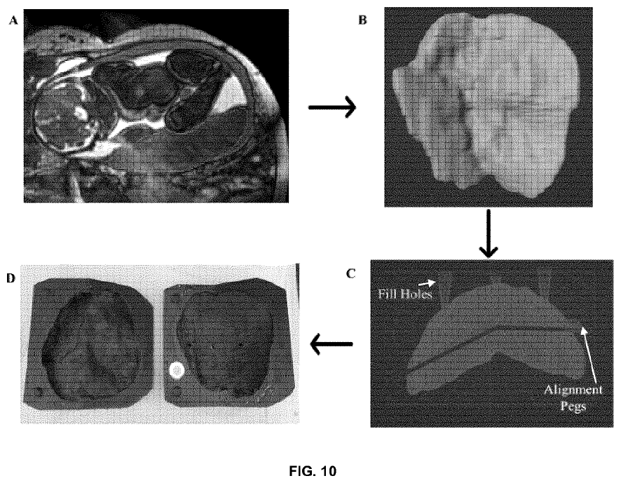

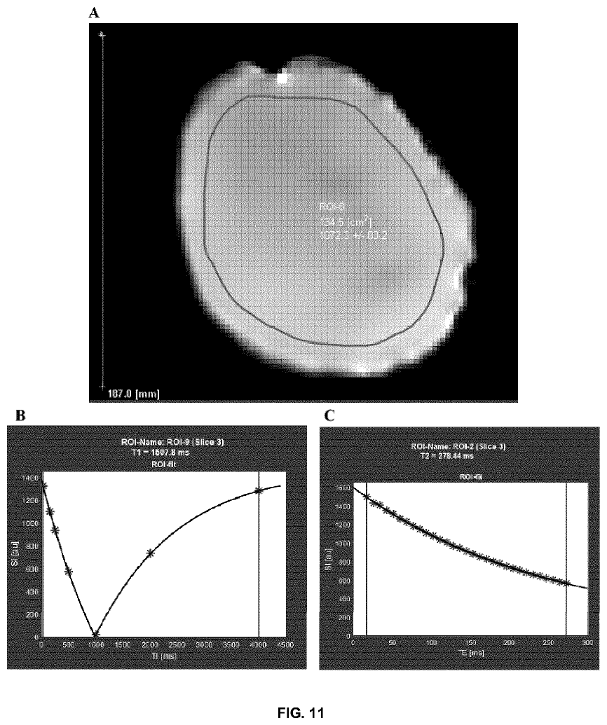

From the selected scans, the placenta was manually segmented by selecting the region in which the placenta was present in every slice (FIG. 10). This process was facilitated using the image processing software Amira allowing the segmented slices to be reconstructed to a single 3D image of the placenta. Once the individual placenta models were reconstructed, the geometrical shape, volume, and dimensions of the placentas were evaluated and compared with the anticipated literature values. Then a single placenta that closely represents a typical third-trimester placenta was selected. From Amira, this 3D image was then exported as an STL file (Standard Tessellation Language) readable by 3D modelling software.

Using the modeling software Blender™ (Blender Foundation, Amsterdam, Netherland), a negative mould was created from the selected 3D placental model. The negative mould had multiple funnel shaped fill holes at the top to allow the hydrogel solution to be poured in, as well as the ability to split into two halves for easy removal of the phantom once the hydrogel has solidified. An interlocking system was present on each half to ensure that the mould was sealed in the proper orientation, and to prevent movement throughout the gel solidification process.

### 3D Model Printing of Placenta

A filament-based 3D printer (Zortax™ m300, Zortax Olsztyn, Poland) was selected for printing the two halves of the placenta mold using PLA (Polylactic Acid) filament. Due to the large size of the mould, precautions were made to ensure minimal warping occurred during printing to preserve the accuracy of the geometrical shape of the 3D placenta model. This was completed by rounding the edges in the design of the placenta mould to minimize flat surfaces. Furthermore, support structures along with a large raft were generated using the Z-SUITE™ slicing software (Zortax Olsztyn, Poland) to maintain the outer shape of the phantom until the print was complete. These components were then removed afterwards.

### Placenta Phantom Validation

The placenta mould was prepared by sealing each of the two 3D printed halves with quick drying silicone sealant on both the inner and outer gaps, and was set to dry for 1 hour. The silicone sealant was used to minimize any leakage of the carrageenan gel between the gaps of the two separate halves, and hold the halves in place during the solidification process.

To prepare the carrageenan hydrogel, the relaxation equations and plot generated in in the present Example were used to select the appropriate concentrations of MnCl₂ and agarose required to mimic the relaxation times of the placenta. The approximate relaxation times of a placenta measured at 3T have been reported to be on the range of 1500±50 ms for T₁ and 275±25 ms for T₂ [40]. Given the range of possible relaxation times, the concentration of MnCl₂ was selected to be 0.032 mM, with no agarose being used (0 w/w %) to give the optimal theoretical relaxation times of 1527 ms for T1 and 272 ms for T2.

Following a similar procedure as detailed in the present Example, two separate 1 L beakers were used to prepare 700 mL of the carrageenan and MnCl₂ gel simultaneously. To prepare each beaker, 3 w/w % carrageenan, 0.033 mM manganese (II) chloride tetrahydrate (MnCl₂·4H2O) stock solution, 0.656 w/w % NaCl and 0.03% glutaraldehyde were pre-measured and dissolved in de-ionized water to make a 700 mL solution. The two beakers were vigorously mixed at room temperature in order to disperse the solutes, then slowly heated to 90° C. to fully dissolve the carrageenan solutes. Once fully dissolved, the solutions were cooled to 70° C. to prevent softening of the PLA material of the mould. In the cooled state, the solution was carefully poured into the injection holes at the top of the 3D mould utilizing a funnel. The injection site was frequently varied between one of the three injection holes to ensure the carrageenan solution was evenly distributed throughout the inner space of the mould. After the mould could no longer contain any additional carrageenan solution, the injection holes were sealed with parafilm to prevent any water loss, and the mould was set aside for 24 hours to allow the carrageenan gel to completely solidify. Once completely solidified, the outer silicone seal was carefully removed, and the halves were carefully separated to ensure the gel casting remained intact.

To measure the relaxation times of the placenta phantom, images were acquired using the body coil of a Skyra™ 3.0 T scanner (Siemens, Erlangen, Germany). To assess the T1, the same inversion recovery sequence as mentioned previously was used with logarithmically spaced inversion times (TI=23, 150, 250, 500, 1000, 2000, 4000 ms). The repetition time (TR) was set to 9000 ms for all images, with a fixed echo time of 8.1 ms.

A multi-echo spin echo sequence was used to acquire T2 values, with 30 echo times (TE=15, 30, 45, 60, 75, 90, 105, 120, 135, 150, 165, 180, 195, 210, 225, 240, 255, 270, 285, 300, 315, 330, 345, 360, 375, 390, 405, 420, 435, 450 ms), and with TR set to 9000 ms for all images.

The slice thickness for both sequences were 6 mm with a 4.8 mm slice gap, for a total of 5 image slices with an X and Y resolution of 2.3438 mm.

To evaluate the relaxation times, the image processing software Segment was used. Regions of interest were selected in each slice covering the inner section of the placenta, as seen in FIG. 11, measuring the signal intensity for each inversion time for the inversion recovery sequence, and for each echo time for the multi-echo spin echo sequence. The resulting signal intensities were plotted using Segment from which the associated T1 and T2 relaxation times could be calculated using the appropriate fit equations (FIG. 11).

### Material Property Testing

### Dielectric Constant and Conductivity

To measure the dielectric constant (ε′) and the conductivity (o) of the final placenta mould, a Keysight™ N5242B PNA-X Network Analyzer with a high-temperature probe N1501A (Keysight, Santa Rosa, California) was used. The Keysight material measurement suite (Keysight, Santa Rosa, California) was used to perform a parametric frequency sweep between 2.1-200 MHz, measuring the dielectric constant (¿′) and dielectric loss (ε″). The dielectric constant was determined by selecting the measured value associated with a frequency of 127.5 MHZ, the associated frequency of MRI at 3T. The conductivity was calculated using the following conductivity equation:

$$σ = {ϵ}_{0} \times ω \times {ϵ}^{′} \times tan δ$$

Using a 3T primary field strength (B₀),

$$ω = \frac{γ}{2 π} {B}_{0} ,$$

where γ is the gyromagnetic ratio of hydrogen γ=42.57747×10⁶·s⁻¹·T⁻¹, ∈0=8.85418782×10-12 F/m, and tan δ=∈″/∈′.

### Results

### Agar-MnCl₂ Relaxometry

T₁ and T₂ Measurements

The T₁ and T₂ values for each sample were measured at about 127 MHz to about 127.5 MHZ (corresponding to about 3T of magnetic strength), and the triplicate average was calculated along with the associated standard deviation (o) seen in Tables 4 and 5. The values ranged from 240-2165 ms for T₁, and 23-499 ms for T₂.

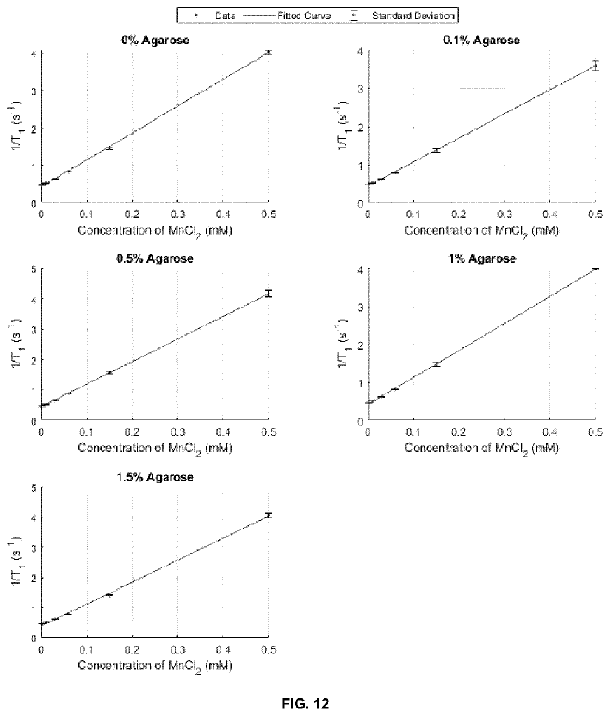

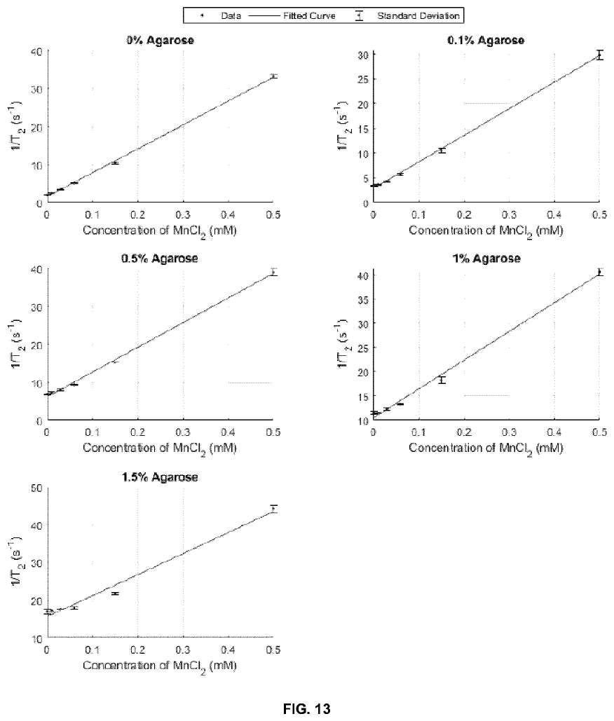

Shown in FIGS. 12 and 13, the T₁ and T₂ rates for each concentration of agarose (1/T₁, 1/T₂) were plotted against the concentration of MnCl₂. A linear trendline was plotted, from which the slope was used to determine the relaxivity of MnCl₂ in each concentration of agarose. The relaxivities, along with the associated 95% confidence intervals and R², are summarized in Table 6.

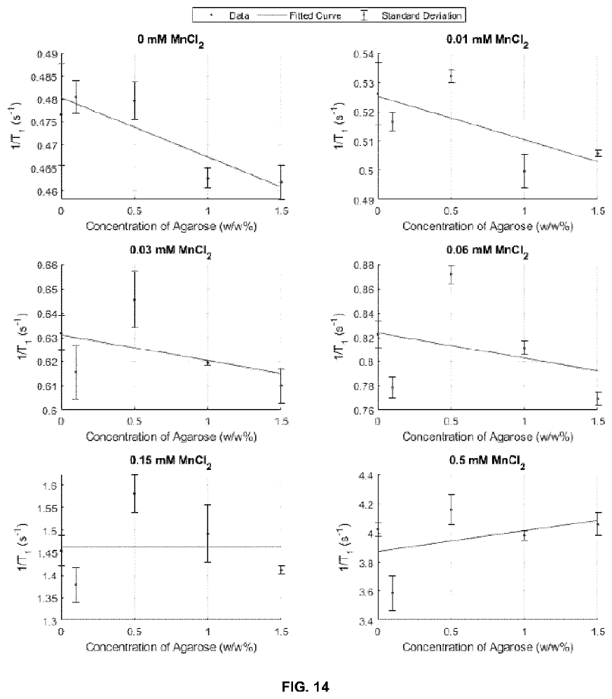

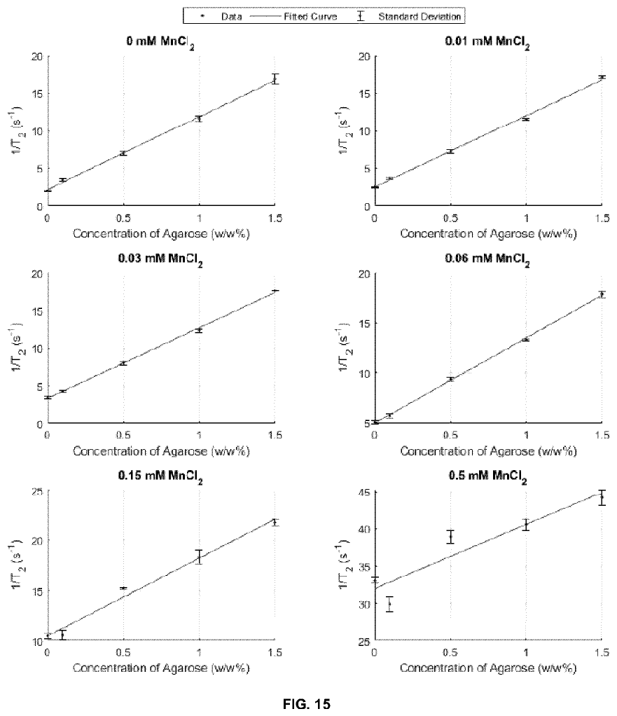

FIGS. 14 and 15 show the T₁ and T₂ relaxation rates of MnCl₂ plotted against the concentrations for agarose. Following a similar process, a linear trendline was plotted, from which the slope was used to determine the relaxivity of Agarose in each concentration of MnCl₂. The relaxivities, along with the associated 95% confidence intervals and R², are summarized in Table 7. A strong linear fit was observed for the relationship between the concentrations of MnCl₂ and both r₁ and r₂, as well as agarose and r₂, shown by a high R² value (R²>0.9). However, there was a weak correlation between agarose and r₁ suggesting agarose does not have a statistically significant effect on T₁ relaxation. The average relaxivity and associated standard deviation were determined for each contrast agent and are summarized in Tables 6 and 7.

TABLE 4
T₁ relaxation times (ms) for phantoms of varying concentrations of
agarose and MnCl₂ between 0 to 1.5 w/w % and 0-0.5 mM respectively.

| Agarose | MnCl2 | | T₁Avg | SD | Agarose | MnCl2 | | T₁Avg | SD |
|---|---|---|---|---|---|---|---|---|---|
| (w/w %) | (mM) | T₁(ms) | (ms) | (ms) | (w/w %) | (mM) | T₁(ms) | (ms) | (ms) |
| 0 | 0 | 2079 | 2098 | 49 | 0.5 | 0.06 | 1158 | 1147 | 10 |
| | | 2061 | | | | | 1144 | | |
| | | 2153 | | | | | 1140 | | |
| 0 | 0.01 | 1943 | 1900 | 38 | 0.5 | 0.15 | 615 | 633 | 17 |
| | | 1869 | | | | | 635 | | |
| | | 1890 | | | | | 648 | | |
| 0 | 0.03 | 1600 | 1583 | 18 | 0.5 | 0.5 | 242 | 240 | 6 |
| | | 1585 | | | | | 246 | | |
| | | 1564 | | | | | 234 | | |
| 0 | 0.06 | 1201 | 1216 | 16 | 1 | 0 | 2159 | 2161 | 10 |
| | | 1232 | | | | | 2152 | | |
| | | 1215 | | | | | 2172 | | |
| 0 | 0.15 | 684 | 687 | 16 | 1 | 0.01 | 1975 | 2001 | 23 |
| | | 674 | | | | | 2009 | | |
| | | 705 | | | | | 2020 | | |
| 0 | 0.5 | 247 | 248 | 3 | 1 | 0.03 | 1618 | 1615 | 3 |
| | | 252 | | | | | 1615 | | |
| | | 246 | | | | | 1612 | | |
| 0.1 | 0 | 2077 | 2081 | 16 | 1 | 0.06 | 1226 | 1233 | 9 |
| | | 2068 | | | | | 1242 | | |
| | | 2099 | | | | | 1230 | | |
| 0.1 | 0.01 | 1937 | 1936 | 12 | 1 | 0.15 | 646 | 670 | 29 |
| | | 1924 | | | | | 663 | | |
| | | 1947 | | | | | 702 | | |
| 0.1 | 0.03 | 1596 | 1624 | 29 | 1 | 0.5 | 249 | 251 | 2 |
| | | 1623 | | | | | 253 | | |
| | | 1654 | | | | | 251 | | |
| 0.1 | 0.06 | 1291 | 1285 | 14 | 1.5 | 0 | 2170 | 2165 | 18 |
| | | 1295 | | | | | 2180 | | |
| | | 1269 | | | | | 2145 | | |
| 0.1 | 0.15 | 721 | 725 | 20 | 1.5 | 0.01 | 1980 | 1977 | 5 |
| | | 708 | | | | | 1972 | | |
| | | 748 | | | | | 1980 | | |
| 0.1 | 0.5 | 276 | 279 | 9 | 1.5 | 0.03 | 1636 | 1640 | 19 |
| | | 289 | | | | | 1660 | | |
| | | 271 | | | | | 1623 | | |
| 0.5 | 0 | 2088 | 2085 | 18 | 1.5 | 0.06 | 1308 | 1300 | 9 |
| | | 2065 | | | | | 1300 | | |
| | | 2101 | | | | | 1291 | | |
| 0.5 | 0.01 | 1871 | 1879 | 8 | 1.5 | 0.15 | 710 | 708 | 4 |
| | | 1886 | | | | | 712 | | |
| | | 1880 | | | | | 703 | | |
| 0.5 | 0.03 | 1518 | 1549 | 28 | 1.5 | 0.5 | 249 | 246 | 5 |
| | | 1570 | | | | | 241 | | |
| | | 1560 | | | | | 249 | | |

TABLE 5
T₂ Relaxation times (ms) for phantoms of varying concentrations of
agarose and MnCl₂ between 0-1.5 w/w % and 0-0.5 mM respectively.

| Agarose | MnCl2 | | T₂Avg | SD | Agarose | MnCl2 | | T₂Avg | SD |
|---|---|---|---|---|---|---|---|---|---|
| (w/w %) | (mM) | T₂(ms) | (ms) | (ms) | (w/w %) | (mM) | T₂(ms) | (ms) | (ms) |
| 0 | 0 | 518 | 499 | 18 | 0.5 | 0.06 | 109 | 107 | 2 |
| | | 497 | | | | | 106 | | |
| | | 482 | | | | | 106 | | |
| 0 | 0.01 | 396 | 399 | 10 | 0.5 | 0.15 | 65 | 66 | 1 |
| | | 410 | | | | | 66 | | |
| | | 390 | | | | | 66 | | |
| 0 | 0.03 | 300 | 289 | 11 | 0.5 | 0.5 | 26 | 26 | 1 |
| | | 289 | | | | | 26 | | |
| | | 277 | | | | | 25 | | |
| 0 | 0.06 | 192 | 197 | 6 | 1 | 0 | 84 | 86 | 3 |
| | | 203 | | | | | 89 | | |
| | | 195 | | | | | 85 | | |
| 0 | 0.15 | 95 | 96 | 3 | 1 | 0.01 | 87 | 87 | 1 |
| | | 93 | | | | | 87 | | |
| | | 98 | | | | | 86 | | |
| 0 | 0.5 | 30 | 30 | 1 | 1 | 0.03 | 83 | 81 | 2 |
| | | 30 | | | | | 82 | | |
| | | 29 | | | | | 79 | | |
| 0.1 | 0 | 282 | 291 | 11 | 1 | 0.06 | 76 | 75 | 1 |
| | | 286 | | | | | 75 | | |
| | | 303 | | | | | 76 | | |
| 0.1 | 0.01 | 280 | 274 | 8 | 1 | 0.15 | 53 | 55 | 2 |
| | | 276 | | | | | 55 | | |
| | | 265 | | | | | 57 | | |
| 0.1 | 0.03 | 233 | 234 | 4 | 1 | 0.5 | 24 | 25 | 1 |
| | | 230 | | | | | 25 | | |
| | | 238 | | | | | 25 | | |
| 0.1 | 0.06 | 184 | 176 | 7 | 1.5 | 0 | 60 | 59 | 2 |
| | | 176 | | | | | 61 | | |
| | | 170 | | | | | 56 | | |
| 0.1 | 0.15 | 93 | 95 | 4 | 1.5 | 0.01 | 58 | 58 | 1 |
| | | 92 | | | | | 58 | | |
| | | 99 | | | | | 59 | | |
| 0.1 | 0.5 | 33 | 34 | 1 | 1.5 | 0.03 | 57 | 57 | 5E−2 |
| | | 35 | | | | | 57 | | |
| | | 33 | | | | | 57 | | |
| 0.5 | 0 | 148 | 144 | 5 | 1.5 | 0.06 | 57 | 56 | 1 |
| | | 146 | | | | | 55 | | |
| | | 138 | | | | | 55 | | |
| 0.5 | 0.01 | 133 | 138 | 5 | 1.5 | 0.15 | 45 | 46 | 1 |
| | | 141 | | | | | 47 | | |
| | | 141 | | | | | 46 | | |
| 0.5 | 0.03 | 121 | 125 | 4 | 1.5 | 0.5 | 23 | 22 | 5E−1 |
| | | 128 | | | | | 22 | | |
| | | 126 | | | | | 23 | | |

The triplicate samples were averaged, and their associated standard deviations are shown.

TABLE 6
T₁ and T₂ relaxivities (r₁ and r₂) MnCl₂ in each concentration
of agarose with the associated confidence intervals and R². The
average relaxivity and associated standard deviation is shown

| | T₁ | | | T₂ | | |
|---|---|---|---|---|---|---|
| Agarose Conc | r₁ (mM⁻¹s⁻¹) | Conf Int | | r₂ (mM⁻¹s⁻¹) | Conf Int | |
| (w/w %) | of MnCl₂ | (±) | R² | of MnCl₂ | (±) | R² |
| 0 | 7.2 | 0.3 | 0.9993 | 62.5 | 2.5 | 0.9991 |
| 0.1 | 6.3 | 0.2 | 0.9995 | 53.6 | 2.8 | 0.9986 |
| 0.5 | 7.4 | 0.2 | 0.9998 | 64.9 | 4.4 | 0.9976 |
| 1 | 7.1 | 0.2 | 0.9996 | 59.2 | 6.1 | 0.9946 |
| 1.5 | 7.3 | 0.4 | 0.9983 | 55.6 | 10.0 | 0.9835 |

| | | |
|---|---|---|
| Average ± SD | 7.1 ± 0.4 mM⁻¹s⁻¹ | 59.2 ± 4.2 mM⁻¹s⁻¹ |

TABLE 7
T₁ and T₂ relaxivities (r₁ and r₂) for agarose in each concentration
of MnCl₂ with the associated confidence intervals and R²

| | T₁ | | | T₂ | | |
|---|---|---|---|---|---|---|
| MnCl₂ Conc | r₁ Agarose | Conf Int | | r₂ Agarose | Conf Int | |
| (mM) | (w/w %⁻¹s⁻¹) | (±) | R² | (w/w %⁻¹s⁻¹) | (±) | R² |
| 0 | −1.3 × 10⁻² | 1.2 × 10⁻² | 0.7895 | 9.7 | 0.7 | 0.9986 |
| 0.01 | −1.5 × 10⁻² | 2.9 × 10⁻² | 0.4820 | 9.5 | 0.9 | 0.9973 |
| 0.03 | −1.1 × 10⁻² | 3.6 × 10⁻² | 0.2281 | 9.4 | 0.7 | 0.9982 |
| 0.06 | −2.1 × 10⁻² | 1.1 × 10⁻² | 0.1089 | 8.5 | 0.5 | 0.9991 |
| 0.15 | 8.7 × 10⁻² | 2.3 × 10⁻² | 4.952 × 10⁻⁵ | 7.7 | 1.7 | 0.9854 |
| 0.5 | 1.4 × 10⁻² | 5.9 × 10⁻² | 0.1652 | 8.6 | 6.1 | 0.8691 |

| | | |
|---|---|---|
| Average ± SD | 1.4 × 10⁻² ± 5.7 × 10⁻² (w/w %⁻¹s⁻¹) | 8.9 ± 0.7 (w/w %⁻¹s⁻¹) |

### Relaxation Curve

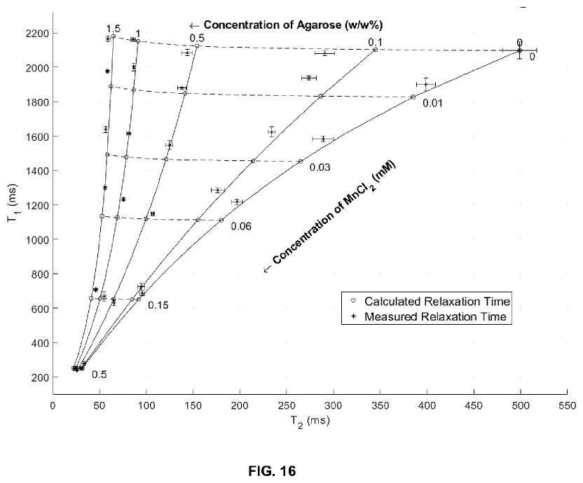

To visualize the possible range of relaxation times, the T₂ relaxation times were plotted against the T₁ relaxation times for each combination of MnCl₂ and agarose seen in FIG. 16. Each line represents the relaxation times over the range of MnCl₂ from 0-0.5 mM, with the line style relating to the concentration of agarose. The X and Y error bars represent the triplicate sample standard deviation value for the T₂ and T₁ relaxation times, respectively.

The sample without any agarose or MnCl₂ present can be seen at the top right of the plot. This represents the baseline relaxation time of the carrageenan gel, as well as the highest combination of both T₁ and T₂ relaxation values. Additions of any modifier to the carrageenan gel caused a reduction in relaxation time from this point as seen in the plot. The rate at which the T₁ relaxation time was reduced is greatly affected by the concentration of MnCl₂ for all concentrations of agarose. Contrarily, the concentration of agarose had no noticeable trend on the T₁ relaxation. Both MnCl₂ and agarose reduced the T₂ relaxation time, however, the degree to which MnCl₂ affected the relaxation time decreased with increased agarose concentration. At high concentrations of agarose, increased amounts of MnCl₂ had less impact on T₂.

Relationship Between T₁ and T₂ the Relaxation Modifiers

Using the linear regression technique to determine the relaxivities of the contrast agents in combination with the relaxation equation, the associated parameters were determined to create a model describing the relaxation times of this material with respect to the concentrations of MnCl2 (mM) and agarose (w/w %), where T₁⁰=2098 ms and T₂⁰=499 ms.

A graphical representation of the calculated relaxation times can be shown in FIG. 16 displaying the range of possible values, as well as the associated concentrations of agarose and MnCl₂ required. A comparison between the calculated T₁ and T₂ relaxation times and their respective measured values are shown.

### Placenta Mould Design and 3D Printing

### Segmented 3D Placenta Model

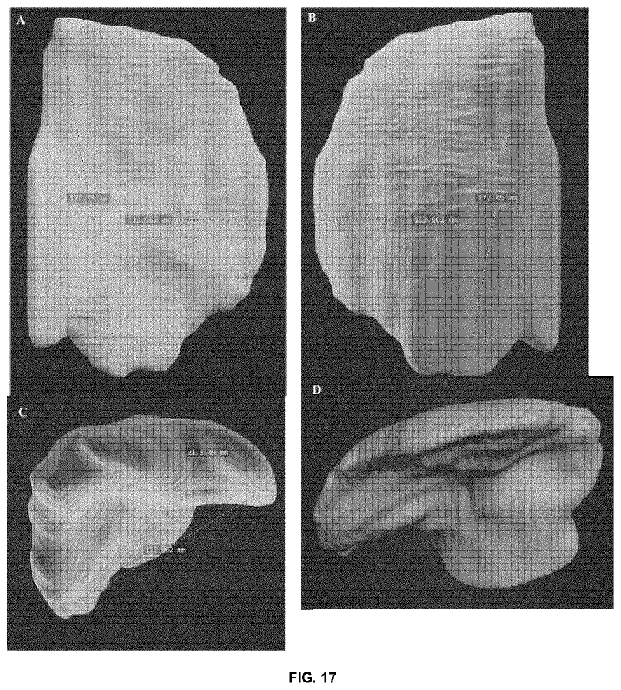

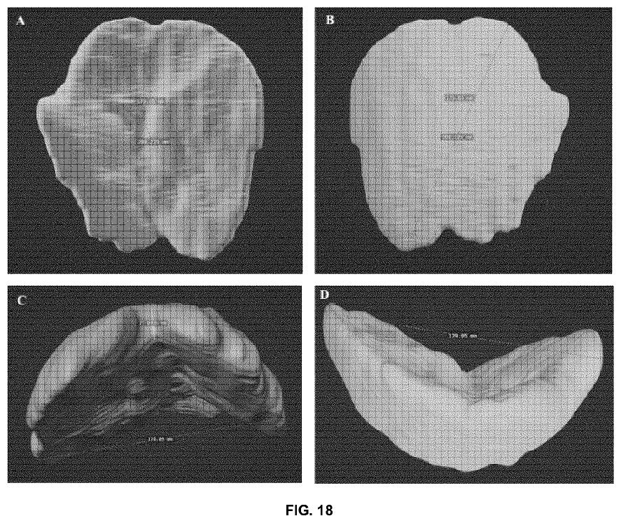

From the third-trimester MRI data set provided, 5 fetal scans were selected, and the placenta was manually segmented using the Amira segmentation software. The largest diameter and the thickness of the placenta were measured using the built-in measuring tools in AMIRA. Additionally, the uniformity of the placenta was assessed [56]. From the five segmentations, two placentas were selected that fell within the range of the average 3rd trimester placenta. The STL files were imported into another 3D modeling software, Blender, and the largest diameter and thickness were measured again, seen in FIGS. 17 and 18.

The first model, labeled Model 1, displayed a largest diameter of 178 mm, with a thickness of 21 mm. The second model, labeled Model 2, displayed a largest diameter of 208 mm, with a thickness of 21 mm. The apparent largest width was measured in addition to the largest diameter. Model 1 displayed a width of 114 mm, while Model 2 displays a width of 179 mm. When compared with the largest diameter, Model 2 displayed the highest amount of uniformity, this could be seen visually, and with the largest diameter and width being closer in size than Model 1. In addition, Model 1 had an additional section of the placenta extending from the side. This irregular shape, while differing from a uniform model, could additionally propose some unnecessary challenges in mould creation, 3D printing, and casting in regard to stability.

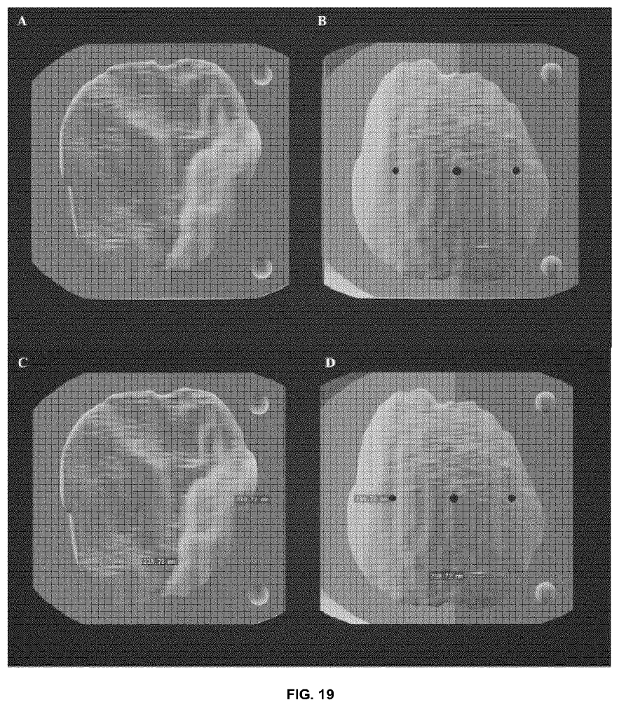

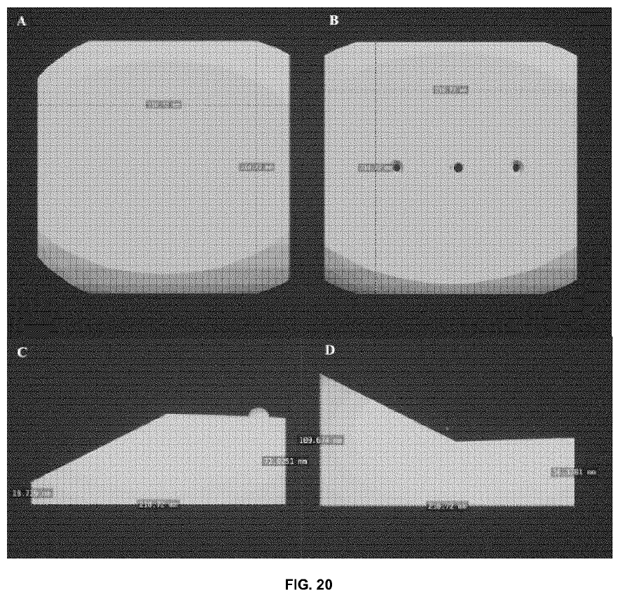

Due to these specified reasons, Model 2 was selected to represent a healthy 3rd trimester placenta. From the generated STL, a negative mould of Model 2 was generated using the 3D modelling software Blender shown in FIGS. 19 and 20. The mould was designed to only split apart in two halves to minimize the exposed sealed edges. Deep grooves, or overhangs in the mould caused by an improper separation may increase the difficulty of removing the phantom from the mould, increasing the chances of the gel splitting, tearing, or catching on the edges. As such, the way the mould split could be designed to facility removal of the cast phantom from the case.

Three injection sites were created at the top of the mould to allow for even filling of the hydrogel, and to prevent any air bubbles, or air pockets to form inside the mould. To finish, the outer edges of the mould were rounded to minimize warping during the 3D printing process, and to reduce the amount of filament required.

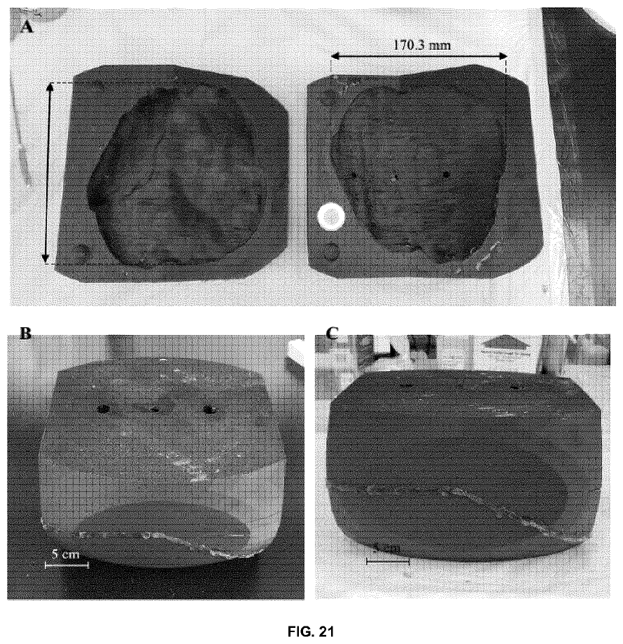

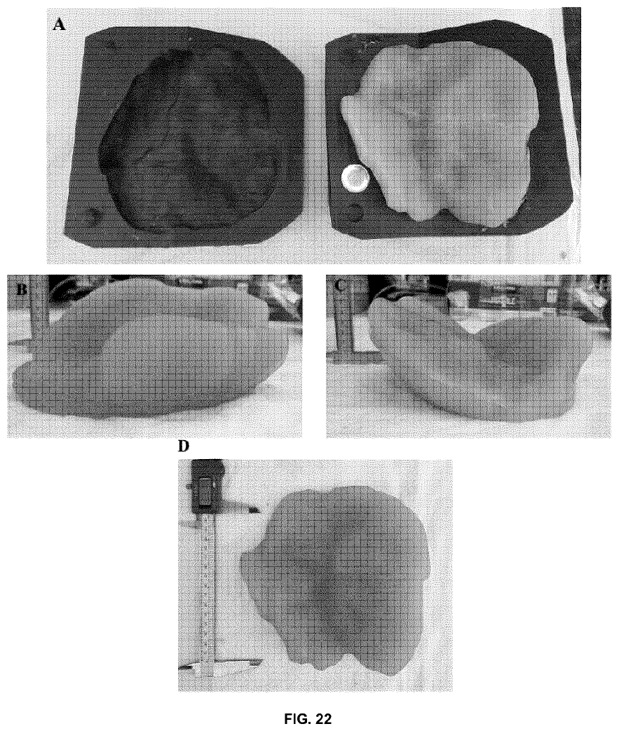

The mould was successfully printed using the Zortax™ m300 filament printer with PLA filament shown in FIG. 21. PLA filament was used due to its ability to capture fine details (minimum wall thickness of 0.8 mm), as well as its higher resistance to warping when compared to other filament types such as ABS (Acrylonitrile Butadiene Styrene) [39], [46]. Each half of the mould print took approximately 20 hours to print and resulted in minimal warping.

### Phantom Relaxation Validation Measurements

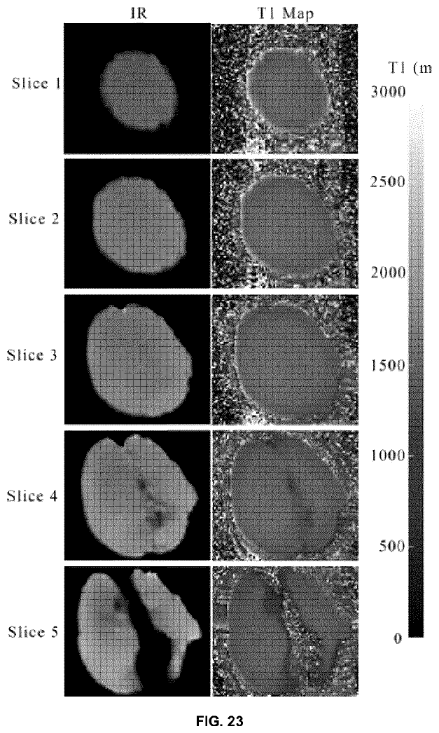

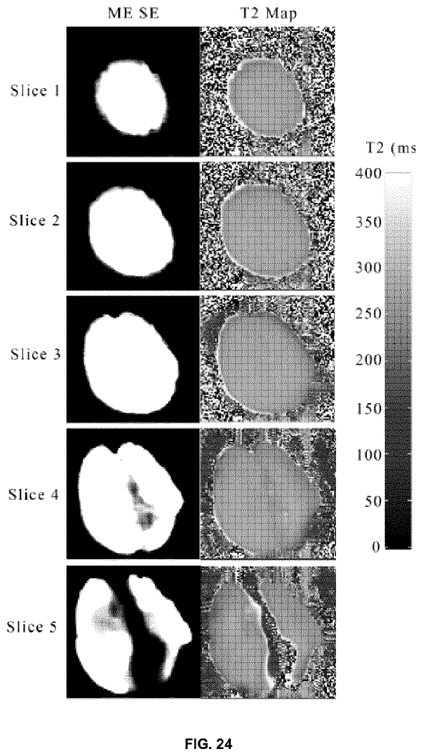

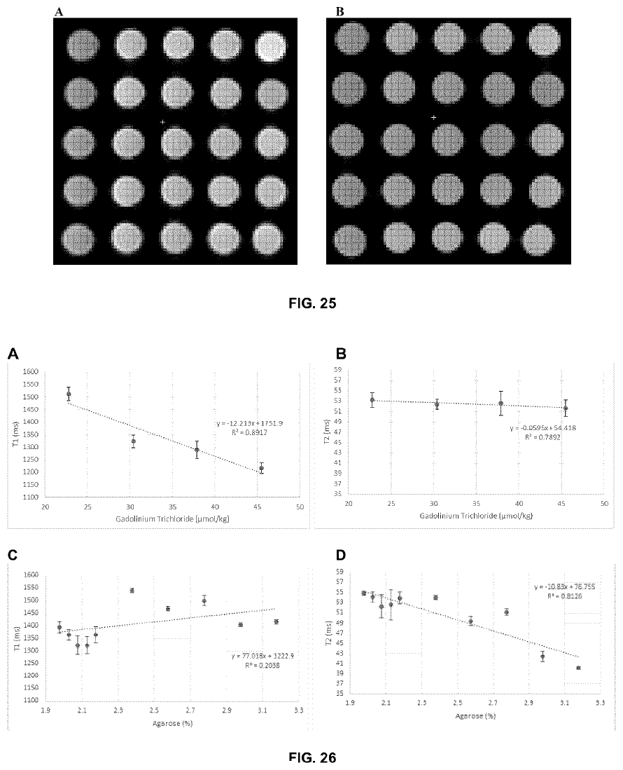

The placenta phantom cast from the 3D printed mould was imaged using the Skyra 3.0 T scanner seen in FIGS. 23 and 24. The T₁ and T₂ relaxation times were extracted for each slice using an inversion recovery and a multi-echo spin echo sequence, respectively. There were a total of 5 slices spaced out through the area of the placenta phantom, the measured T₁ and T₂ relaxation times are shown in Table 8. The placenta phantom showed similar relaxation times throughout slices 1-4 between the range of 1499-1508 ms for T₁, and 278-282 ms for T₂. Slice 5, the topmost slice, showed slightly lower relaxation times of 1449 ms for T₁ and 275 ms for T₂. When compared with the measured values of the placental tissue, 1500±50 ms for T₁ and 275±25 ms for T₂, considering the standard deviation, the measured relaxation time of the placenta phantom falls within the desired range.

TABLE 8
Measured T₁ and T₂ relaxation times and their associated standard
deviations of the placenta phantoms measured at 3T.

| Slice | T₁(ms) | SD (ms) | T₂(ms) | SD (ms) |
|---|---|---|---|---|
| 1 | 1497 | 28 | 281 | 4 |
| 2 | 1502 | 35 | 282 | 4 |
| 3 | 1508 | 30 | 278 | 8 |
| 4 | 1499 | 28 | 280 | 5 |
| 5 | 1449 | 12 | 275 | 3 |

The relaxation time for each slice was measured, slice 1 being the bottom most-slice showing the maternal facing side of the placenta, and slice 5 is the topmost showing the fetal facing side of the placenta.

### Dielectric Measurement

The dielectric constant (ϵ′) and conductivity (σ) was measured using the Keysight dielectric assessment measuring device. The averaged values over three trials associated with the frequency of a 3T MRI (127.5 MHZ) were selected and summarized in Table 9 with their associated standard deviation.

TABLE 9
Dielectric constant (ε′) using and conductivity (σ)
measurements using the Keysight high temperature probe.

Dielectrics at 127.5 MHz

| | Value | SD |
|---|---|---|
| ε′ (F/m) | 79.8 | 2.9 |
| σ (S/m) | 1.85 | 1.11E−2 |

### Discussion

An MR-phantom of an average healthy 3^{rd} trimester human placenta was developed to mimic the accurate gross anatomical structure and dimensions, as well as the magnetic and dielectric properties. This was completed through the development of a carrageenan agarose-MnCl₂ material capable of simulating a wide range of magnetic relaxation times. Associated relaxation formulae were created to determine the concentrations of agarose and MnCl₂ required to create a material mimicking the relaxation times of a healthy third trimester placenta. A negative mould of an average-sized third trimester placenta was modelled through segmentation of a placenta using a fetal MRI dataset. The carrageenan was poured into the mould to cast the placenta phantom accurately replicating the gross anatomical structure and dimensions. Relaxation measurements were completed using the Skyra 3T scanner to confirm the accuracy of the relaxation values, and the dielectrics were measured using the Keysight dielectric assessment kit.

### Carrageenan Agarose-MnCl₂ Phantom Material

### Agarose-MnCl₂ Relaxometry

A carrageenan based, MnCl₂ and agarose doped hydrogel material was successfully created to simulate a wide range of relaxation times for both T₁ and T₂. The material was created using fixed concentrations of carrageenan, NaCl, and glutaraldehyde as an exemplary antimicrobial agent, with varying concentrations of MnCl₂ and agarose. The experiment was performed in triplicate to verify and compare the obtained results. The measured relaxation times for each triplicate were similar in value with a low standard deviation; an average deviation of 1.9% between the three values, with the largest difference being 4.3%. The resulting relaxation times for both T₁ and T₂ are summarized and plotted in FIG. 16. The developed material was found to exhibit relaxation times of 240-2165 ms for T₁ and 23-499 ms for T₂.

Both carrageenan and agarose have been reported to have been used as a hydrogel base for phantom casting due to their elasticity and resistance in cracking. While their physical properties may be similar, agarose differs from carrageenan due to its difference in relaxation properties. Agarose has a strong effect on the T₂ relaxation, and therefore, if used as a solidifying agent, the rigidity of the gel depends on the T₂ relaxation time required. In comparison, carrageenan has little effect on relaxation time while still providing sufficient gel strength [37]. Consequently, 3 w/w % carrageenan was chosen to act as the primary solidifying agent, and agarose as a T₂ modifier, with the added benefit of also increasing the strength of the gel.

Increasing the concentration of agarose resulted in a decrease of the T₂ relaxation time; however, this had no statistical significance in decreasing T₁. With the introduction of agarose into the solution, the gel initially acts as a linear polymer with single coils. After exposure to sufficient heating, during the cooling process, intramolecular hydrogen bonding occurs creating double helices that aggregates into a 3D network. This 3D network facilitates interactions between the polar sites of the gel molecules with water, creating local magnetic field gradients. These gradients effectively decrease the transverse magnetization, increasing the rate at which the spins dephase, resulting in a shorter T₂ relaxation [47].

Increasing the concentration of MnCl₂ resulted in a decrease in both T₁ and T₂ relaxation times. Due to MnCl₂'s paramagnetic properties, rapid chemical exchange occurs between the bulk water molecules and the water molecules bound to the metal ion, resulting in rapid exchange with the surrounding bulk fluid [48]. This leads to a decrease in both the T₁ and T₂ relaxation time of the average water proton present in the bulk fluid. The more paramagnetic ions present for the water to bind, the higher the decrease in relaxation time.

MnCl₂ exhibited a T₁ relaxivity (r₁) between 6.3-7.4 mM⁻¹s⁻¹ and a T₂ relaxivity (r₂) of 53.6-64.9 mM⁻¹s⁻¹ for the varying concentrations of agarose. The high r₂ of MnCl₂ demonstrated its stronger effect on decreasing T2 when compared with Gadolinium based contrast agents (r₂<10 mM⁻¹s⁻¹) [49], [50]. This higher r₂ allowed for this material to include a wider range of relaxation values, specifically, the high T1 and T2 relaxation times of the placenta.

MnCl₂ exhibited an average T₁ relaxivity (r₁) of 7.1±0.4 mM⁻¹s⁻¹ and an average T₂ relaxivity (r₂) of 59.2±4.2 mM⁻¹s⁻¹ for the varying concentrations of agarose. The high r₂ of MnCl₂ demonstrated its stronger effect on decreasing T2 when compared with Gadolinium-based contrast agents (r₂<10 mM⁻¹s⁻¹) [49], [50]. This higher r₂ allowed for this material to demonstrate a wider range of relaxation values, thus accommodating phantoms with tissues with high T₁ and T₂ relaxation times. When comparing the relaxivities of MnCl₂ with the literature, the r₁ is in agreement with other studies 6.4-7.4 mM⁻¹s⁻¹ [51], however, when comparing the r₂ values, the r₂ measured in this study is lower than those reported elsewhere (108-117 mM⁻¹s⁻¹). While this value may differ, these studies were performed using aqueous phantoms without the presence of any other contrast agents. It is expected to observe a difference in MnCl₂ relaxivity dependent on the environmental macromolecular content [53]. Since this study involved the use of a gelling agent, as well as an additional contrast agent, it is more difficult to make a more meaningful comparison. A similar study from Jenkins et, al investigated only the R₁ effects of MnCl₂ that involved a gel solution as well as an aqueous solution environment. The reported r₁ for the gel phantom was in agreement with this study reporting a value of 7.16 mM⁻¹s⁻¹ using the same IR sequence.

### Relaxation Equations

From the selected range of concentrations of both MnCl₂ and agarose, a wide range of phantoms with relaxation times equivalent to not only the placenta, but numerous human tissues can be produced. To determine the exact concentrations required for the creation of a desired tissue equivalent phantoms, relaxation formulae were determined describing the relationship between the T₁ and T₂ relaxation times (ms), and the concentrations of MnCl₂ (mM) and agarose (w/w %).

The combination of multiple relaxation modifiers allows for independent adjustments of either T₁ or T₂ within the range of relaxation times provided. Using the equations provided, the concentrations of MnCl₂ and agarose can be calculated to produce a phantom with a chosen relaxation time. Using a series of measured relaxation times as reference [54], [55], the composition of a placenta phantom, as well as sample compositions of other human tissues are shown in Table 10.

When considering the structural integrity of the phantom, the 3 w/w % carrageenan was sufficient for form retaining ability and handling without the worry of the phantom breaking. As a result, the reliance on agarose for structural stability is not required and thus can be used in low quantities, or not at all, to achieve the desired relaxation values without sacrificing structural integrity.

TABLE 10
Concentrations of MnCl₂ and agarose required, to develop a phantom
that mimic the relaxation times of the desired tissue.

| | T₁ | T₂ | MnCl₂ | Agarose |
|---|---|---|---|---|
| Tissue | (ms) | (ms) | (mM) | (w/w %) |
| Placenta | 1450-1550 | 275-285 | 3.20 × 10⁻³ | 0 |
| Blood | 1932 | 275 | 6.04 × 10 | 0.14 |
| Gray matter | 1820 | 99 | 1.17 × 10 | 0.83 |
| Uterus | 1514 | 79 | 2.78 × 10 | 1.01 |
| Heart | 1471 | 47 | 3.21 × 10 | 1.94 |
| Skeletal muscle | 1412 | 42 | 3.65 × 10 | 2.19 |
| Kidney | 1194 | 56 | 5.35 × 10 | 1.42 |
| White matter | 1084 | 69 | 6.48 × 10 | 0.97 |
| Spinal Cord | 993 | 78 | 7.63 × 10 | 0.70 |
| Liver | 812 | 42 | 1.10 × 10 | 1.71 |

When comparing the measured relaxation times with the calculated relaxation times using the relaxation formula, the average difference is within ±5% for T¹ and ±6% for T². There are points that vary as much as ±13% for T1, and ±18% for T2, however, most of these occur when modeling combinations of relaxation times with T¹ above 2000 ms. Since most human tissues exhibit relaxation times of under 2000 ms for T¹ [34], [35], these higher differences in relaxation times will not impact the quality of producing materials with human equivalent relaxation times.

Table 10 encompasses only a small number of tissues that can be simulated utilizing this developed material. Given the extremely wide range of relaxation times capable of being produced, high reproducibility, and ease and safety of preparation, this material is ideal for studies involving anatomical models to be used with MRI. These phantoms can replace human volunteers to decrease the amount of time and cost required for the development of MRI pulse sequences.

When comparing this hydrogel material to currently existing MRI phantom hydrogel material containing gadolinium [36], the tissue mimicking material of the present disclosure is able to mimic a wider range of relaxation values. Specifically, it has been shown that this material can mimic relaxation times of tissues with both high T₁ and T₂ values, such as blood and the placenta, as well as tissues with low T₁ and T₂ such as fat.

### Anthropomorphic Placenta Phantom

### Mould Printing and Casting

A two-piece plastic mould of an average healthy 3^{rd} trimester placenta was printed using PLA filament. The print was completed without any major distortions or warping causing geometrical inaccuracies in the final cast. When assembled, the layers fit snug; however, when filled with water, leakage still occurred between the layers of the two halves. To ensure no liquid leaks out of the mould, a silicone adhesive was used on the inner and outer sections of the mould. A weight was placed on top of the mould while the adhesive was set to dry to ensure a complete seal.

Previous attempts of mould filling had issues with casting 100% of the placenta without any missing sections, most notably the very top rounded edge of the placenta. When filling the mould with the desired hydrogel material, it was found that the entire mould can be properly filled by using each injection holes numerous times to avoid the presence of any air bubbles. Once the mould appeared to be full, some gentle movements were performed to allow the hydrogel solution to completely fill the gaps, and for any air bubbles present to escape through an injection hole. Additional solution was then added to the mould to fill this space. This process was repeated until the mould could not contain any more solution.

Once the mould was filled, the cast was allowed to set completely before any attempts were made to open the mould, for example for 24 hours. With some force, the silicone seal could be broken, and the top half of the mould removed with ease. The bottom half of the mould was more difficult to remove due to the thinner edges of the placenta geometry. Caution was used when removing the placenta phantom to not tear any pieces. With force being applied one side at a time, the phantom was carefully removed. Due to the sharp edges caused by the slight overhangs on the bottom pieces of the mould, additional caution was taken to avoid scraping off the outer sections of the carrageenan gel.

Once removed, the resulting placenta phantom cast holds its own weight when standing and retains full detail of the pre-segmented placenta.

### Validation Relaxation Measurement

The placenta phantom was cast using 0.032% MnCl₂ without any agarose present. The predicted relaxation times at this concentration were calculated to be 1527 ms for T₁ and 272 ms for T₂. The resulting relaxation times varied between 1450-1508 ms for T₁ and 275-282 ms for T₂. While a majority of the relaxation times were close to the desired values, the largest deviation in relaxation time occurred at thinner edges of the phantom. During the casting process, these edges are located at the bottom of the mould. Without wishing to be bound by theory, this slight difference in relaxation times could be caused by additional relaxation modifiers settling closer to the bottom causing minor inhomogeneities, decreasing the relaxation times. Nevertheless, even with the shorter relaxation time in thinner edges of the phantom, the entirety of the phantom exhibit's relaxation times within the given uncertainty range desired to mimic the placenta (1500±50 ms for T₁ and 275±25 ms for T₂).

Depending on the size of the desired phantom, it may be desired to prevent water-loss over time due to evaporation. The decrease in water inside the phantom can cause an apparent increase in the concentrations of the relaxation modifiers. As a result, the relaxation times can decrease proportional to the amount of water mass lost. Proper storage protocols of the phantom may be followed to improve stability of time. Examples of proper storage can include sealing the phantom in an airtight container in a cool environment (that is, stored in a fridge at temperatures of approximately 4° C.). For longer term storage, the phantom can be stored in deionized water preventing any water loss from the phantom.

### Dielectric Measurement

The Foundation for Research on Information Technologies in Society (IT'IS, Swiss Federal Institute of Technology, Zurich) reports the dielectric constant (ε′) and the conductivity (σ) of the placenta to be 77 F/m and 1.25 S/m respectively at 127.5 MHz. Using the Keysight™ high temperature probe, the placenta phantom was measured to have the following dielectric properties at 127.5 MHZ: ∈′=79.8 F/m and σ=1.85 S/m. To modify the conductivity of the phantom, NaCl was used in amounts reported to simulate blood, a tissue demonstrating similar dielectric properties [36]. The phantom successfully simulates the dielectric constant of the placenta, with a percent difference of 3.6%. Conversely, the conductivity of the phantom is larger than the values reported for the placenta, differing by 38%.

The concentration of NaCl required was determined using an existing carrageenan gel with a gadolinium-based relaxation modifier [36], whereas the proposed material in this thesis utilized MnCl₂. It was reported that not only does NaCl affect the conductivity of the carrageenan gel, the concentration of gadolinium also had a significant impact on the conductivity [56]. Therefore, the reported difference between the measured and theoretical value of conductivity may be explained by the substitution of MnCl₂ for GdCl₃.

### Conclusion

An MR-phantom of an average third-trimester human placenta simulating the relaxation times and dielectric properties of the tissue has been developed. For example:

A. A tissue mimicking material capable of mimicking a range of relaxation times and dielectric properties, including those required of the placenta was developed.

B. An anatomically correct mould was designed of an average 3rd trimester placenta trough segmentations of an MRI data set

C. The mould design was 3D printed and a placenta phantom was cast using the developed material that accurately simulated the relaxation times and dielectrics of the placenta.

The placenta mimicking material was achieved through the development of a carrageenan hydrogel material, utilizing MnCl₂, agarose, and NaCl as T₁, T₂, and dielectric modifiers, respectively. Relaxation formulae were determined to describe the relationship between each relaxation time and the concentrations of agarose and MnCl₂ shown in in the present Example. Using these formulae, it was determined that a carrageenan hydrogel doped with about 0.01 mM to about 0.05 mM would produce a material with relaxation times mimicking those of a third trimester placenta. For example, it was shown that about 0.032 mM of MnCl₂ produced a material that exhibited a T₁ relaxation time of 1527 ms and a T₂ relaxation time of 272 ms, thus mimicking the relaxation times of a 3^{rd} trimester placenta. Additionally, it was determined that including a concentration of about 0.3 w/w % to about 1 w/w %, for example about 0.656 w/w % NaCl would modify the dielectric properties of the hydrogel material to exhibit a dielectric constant of 79.8±2.9 F/m and a conductivity of 1.83±1.11E⁻² S/m, thus, mimicking the dielectric constant of the placenta.

Healthy 3^{rd} trimester placentas were segmented from a fetal MRI data set, creating a two-piece negative mould of the 3D placenta volume. This mould was successfully printed using the Zortax m300 filament-based 3D printer, then filled with the carrageenan, MnCl₂, and NaCl hydrogel, resulting in the final placenta phantom.

This carrageenan, MnCl₂, agarose, and NaCl hydrogel phantom material provided the ability to cast not only a placenta phantom, but a wide range of tissues mimicking their relaxation times and dielectric properties. While previous methods have failed to create a placenta phantom that is able to capture both the anatomical structure, and tissue properties relating the magnetic relaxation times and dielectric properties, the placenta phantom design of the present disclosure was able to complete all these objectives rapidly and accurately. This anthropomorphic placental phantom can be used for examination of physiology and pathology via MRI through the unique ability to rapidly develop and test new imaging sequences specifically designed for placental imaging without the need for human participants.

### Example 3 Muscle Mimicking Material

### Sample Preparation of Carrageenan+Agarose+Gadolinium+NaCl (CAGN)

For creating muscle phantoms, 3 w/w % of carrageenan, agarose in the ranges of 1.976-3.176 w/w %, GdCl3 in the range of 22.8-45.5 μmol/kg, 0.291 w/w % of NaCl, and 0.03 w/w % of sodium azide were mixed in different concentrations to prepare a total of thirteen samples.

All chemicals were pre-measured and dissolved in distilled water to create 50 mL samples. Samples in solution were heated to 90° C. in beakers to completely dissolve carrageenan and agarose then cooled to 70° C. before the samples were transferred into 50 mL falcon tubes. The resulting samples were cooled to room temperature and stored in a fridge until MRI scanning.

### Characterisation of Imaging Properties

Each sample's T₁ and T₂ relaxation times of five slices of the transverse plane were measured and collected using a 3.0 T scanner (Skyra, Siemens, Erlangen, Germany). An Inversion Recovery sequence with varied inversion times (TI=23, 150, 250, 500, 1000, 2000, 4000 ms) and a fixed echo time (TE=8.1 ms) and repetition time (TR=9000 ms) was used to acquire the T₁ relaxation times. T₂ values were acquired using a multi-echo sequence with varied echo times (TE=8.5, 17, 25.5, 34, 42.5, 51, 59.5, 68, 76.5, 85, 93.5, 102, 110.5, 119, 127.5, 136, 144.5, 153, 161.5, 170. 178.5, 187, 195.5, 204, 212.5, 221, 229.5, 238, 246.5, 255, 263.5, 272 ms) and a fixed repetition time (TR=500 ms). The T₁ and T₂ relaxation times of the phantom samples were measured and collected by post-processing the acquired MRI images on Segment (Medviso, Lund, Sweden).

### Graphs and Statistical Analysis

Scatter plots of T₁ and T₂ values of each type of tissue mimicking material were graphed as a function of various relaxation times modifiers (FIG. 26) to observe how the relaxation times were affected by each chemical. To compare the goodness of fit, R² or X², of the trendline in each figure was plotted with their respective function equations. The R² indicates that the observed data closely fit regression line. R² values range from 0 to 1 and as it gets closer to 1, it indicates the observed data perfectly fitted to the regression line. The X² or chi-square measures how a function model compares to actual observed data. A low value of chi-square indicates there is a high correlation between the model and the actual observed data. In addition, the standard deviation of each grouped data was plotted as error bars on each figure (FIG. 26). In the relaxometry testing, one sample per chemical formula was created and five transverse planes from different heights of a sample tube were scanned to measure the T₁ and T₂ relaxation times. Thus, the error bar of for each data point corresponds to the homogeneity of that sample.

### Dielectric Measurements

### Sample Preparation of CAGN

Thirteen samples of muscle CAGN phantoms with the same formula used in CAGN relaxometry testing were prepared in cell culture plates employing the same manufacturing method.

In the 13 samples, the concentrations of carrageenan, sodium azide, and NaCl were fixed. However, the fixed NaCl concentration of each tissue phantom resulted in much lower conductivity values than the actual tissue values. The dielectric constant and conductivity data obtained in the measurement of 13 samples showed that both gadolinium and agarose did not significantly affect the dielectric properties of the samples in the range that were chosen.

Therefore, one formula which resulted in the appropriate T1 and T2 values that matched with muscle was selected. Eight samples were prepared which had fixed amount of relaxation times modifiers but varied amount of NaCl to test the effect of NaCl on dielectric properties and observe if appropriate conductivities which simulate the actual tissues are achievable.

For creating muscle phantoms, 0.291-3.091 w/w % of NaCl, 3 w/w % of carrageenan, 3.176% of agarose, 30.4 μmol/kg of GdCl3 and 0.03 w/w % of sodium azide were mixed in different concentrations to prepare a total of eight samples.

Once the measured conductivity values of samples with different NaCl concentration is plotted on graphs with linear trendline and equations using Excel (Microsoft, Redmond, Washington), the concentration of NaCl to create CAGN samples that simulate appropriate conductivity of muscle tissue was calculated. To ensure the calculated NaCl concentration can result in appropriate conductivity, a sample that contains the calculated amount of NaCl was created and measured.

### Characterisation of Dielectric Constant and Conductivity

A Keysight N5232B PNA-L Network Analyzer (Keysight, Santa Rosa, California) and a high-temperature probe N1501A (Keysight, Santa Rosa, California) were used to measure the dielectric constant and conductivity of each sample as a function of frequency in the range of 1-201 Mz. Keysight material measurement suite 2018 (Keysight, Santa Rosa, California) collected dielectric constant (ε′) and dielectric loss (ε″) values in excel charts. Conductivities of each sample were calculated using equation 3, where ω=γB, γ=42.57747×10⁶ rad·s⁻¹·T⁻¹, B=3.0T, εₒ=8.85×10⁻¹² F/m, and tan δ=ε″/ε′.

$$σ = {ε}_{0} \times ω \times {ε}^{′} \times tan δ \qquad ( 3 )$$

### Graphs and Statistical Analysis

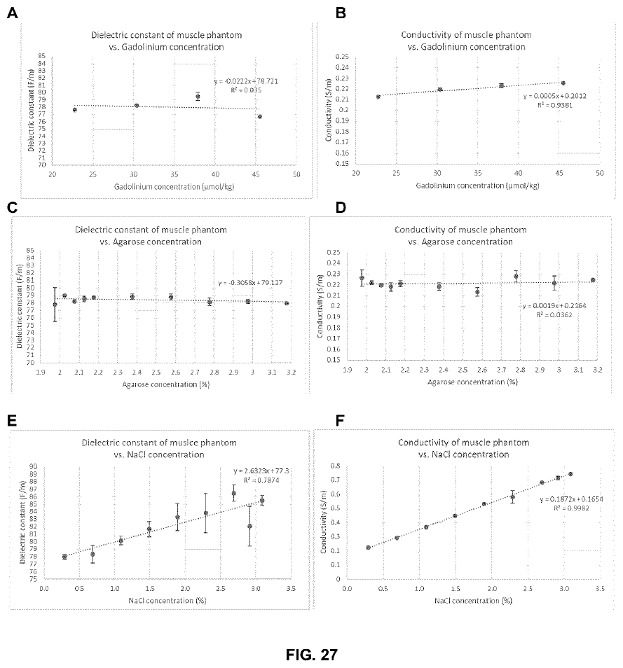

Scatter plots of dielectric constant and conductivity values of each tissue mimicking materials were graphed as a function of various chemical concentrations (FIG. 27) to observe how the dielectric properties were affected. To compare the goodness of fit, R² of the trendline in each figure was plotted with their respective function equations. In addition, the standard deviation of each grouped data was plotted as error bars on each figure (FIG. 27). The regression lines from different figures were compared by using an ANCOVA test to determine if there is a significant difference among linear trend lines from different data graphs. ANCOVA was performed on a spreadsheet available on a webpage named VassarStats [74] which is built for this specific test. In addition, we performed a one sample t-test and regression slope tests using Excel (Microsoft, Redmond, Washington) for determining if there is a significant difference within a sample group and if a slope is significantly different from zero, respectively. P values that are smaller than 0.05 were considered significant.

### Mechanical Testing

A motion system is implemented in the fetal gross body phantom to simulate the body movement in the amniotic fluid. The motion system consists of an MRI compatible motor and plastic compartment which repeatedly stretches and compresses the phantom in certain directions. Prior to the implementation of a motion system, the mechanical strength of the gross body phantom material was evaluated to ensure the material can tolerate the mechanical stress applied. To evaluate the material's resistance to stretch and compression, shear and compression tests were performed and each moduli of samples were collected. The purpose of the mechanical test was to create a reference for designing a motion implementation and for selecting actuators. The motor strength and motion magnitude are coordinated based on this reference to reproduce fetal motion.

### Characterisation of Mechanical Properties

The thickness and diameter of each sample were measured using digital calipers. Equilibrium mechanical properties of the samples in both compression and shear were then assessed using a two-axis (compression-shear) Mach-1 Micromechanical Testing System (Biomomentum, Laval, PQ, Canada) equipped with a six-axis load cell, as described previously [75]-[77].

For a compression test, samples were first pre-loaded (5 mN) which was defined as the zero-strain state. Samples were then subjected to sequential, uniaxial, unconfined compressions of 2% strain to a maximum of 10% strain (total of five steps). At each step, the resulting compressive force was recorded (at 10 Hz) until equilibrium was reached (force decay<2 mN/min). The equilibrium compressive stress was calculated as the equilibrium compressive force normalized by the cross-sectional area of the sample and was plotted as a function of the applied strain. The equilibrium compression modulus was then determined from a numerical derivative of the equilibrium stress-strain curve at each step strain.

The same approach was used for shear testing, except that after pre-loading (5 mN compression). Samples were then subjected to a sequential step of simple linear shears of 1% strain to a maximum of 5% strain. A total of five samples were tested for each experimental group, in both compression and shear.

### Image Segmentation, Surface Reconstruction and Design of Molds

Prior to the design and 3D printing of the mold, a de-identified MRI dataset of a 35-week fetus was selected to be reconstructed in a 3D model. A number of MRI datasets were previously acquired and used. Among those MRI datasets, one was selected based on the fetal age (35-37 week), the developmental condition of the fetus, and the lack of imaging artifacts.

The reconstructed 3D images were then used as organ surface files which were loaded onto the commercial modeling software Blender (Blender Foundation, Amsterdam, Netherland), and Meshmixer™ (Autodesk, San Rafael, California, USA) to create the design of the molds. The mold design files were then printed by various 3D printers.

### 3D Mold Printing

A resin 3D printer (Form 2, Formlabs, Somerville, Massachusetts, USA) and a plastic 3D printer (Zortax m300, Zortax Olsztyn, Poland) were selected for printing the compartments of the molds. The 3D printing materials that were used by the resin printer and the plastic printer were standard black resin (Formlabs, Somerville, Massachusetts, USA) and HIPS (Zortax, Olsztyn, Poland), respectively.

Different printing methods were chosen to fabricate each fetal gross body phantom based on their material properties. For constructing the gross body phantom, indirect 3D printing/casting mold method was selected as the gross body phantom will be constructed with silicone rubber which has structural and chemical stability even when it was exposed to either air or water, making it especially relevant to tests with the phantom surrounded by amniotic fluid. The gross body phantom mold was designed by encasing the 3D-reconstructed gross body model in a solid block and subtracting the model from the block. This provided the negative space needed for the tissue-mimicking materials used to produce phantoms [68], [71].

### Material Testing and Phantom Construction Results

### Relaxometry Testing

### Results of CAGN Relaxometry Testing

For muscle CAGN phantom, the T1 and T2 relaxation times were found to range between 1216-1540 ms and 40-55 ms, respectively. Results are shown in Table 11.

TABLE 11
Relaxation times of various CAGN phantoms relative to
the concentration of agarose and gadolinium trichloride

| | Composition of phantom | | | | Relaxation times | |
|---|---|---|---|---|---|---|
| | Carrageenan | Agarose | GdCl₃ | NaCl | T1 | T2 |
| | % | % | μmol/kg | % | ms | ms |
| Muscle #1 | 3.00 | 2.076 | 22.8 | 0.291 | 1512 | 53 |
| Muscle #2 | 3.00 | | 30.4 | 0.291 | 1323 | 52 |
| Muscle #3 | 3.00 | | 37.9 | 0.291 | 1289 | 53 |
| Muscle #4 | 3.00 | | 45.5 | 0.291 | 1216 | 52 |
| Muscle #5 | 3.00 | 1.976 | 30.4 | 0.291 | 1395 | 55 |
| Muscle #6 | 3.00 | 2.026 | | 0.291 | 1365 | 54 |
| Muscle #7 | 3.00 | 2.126 | | 0.291 | 1323 | 53 |
| Muscle #8 | 3.00 | 2.176 | | 0.291 | 1364 | 54 |
| Muscle #9 | 3.00 | 2.376 | | 0.291 | 1540 | 54 |
| Muscle #10 | 3.00 | 2.576 | | 0.291 | 1467 | 49 |
| Muscle #11 | 3.00 | 2.776 | | 0.291 | 1500 | 51 |
| Muscle #12 | 3.00 | 2.976 | | 0.291 | 1403 | 42 |
| Muscle #13 | 3.00 | 3.176 | | 0.291 | 1416 | 40 |

As depicted by the regression slopes in FIGS. 26A and B, the concentration of gadolinium trichloride was found to be more effective on shortening the T₁ (r²=0.8917) rather than the T₂ (r²=0.7891) of muscle CAGN samples. In case of concentration of agarose in the muscle CAGN samples, it significantly affects T₂ relaxation as shown in FIG. 13(d) (r²=0.8126). In FIG. 26C, the T₁ relaxation times decreased between 1.976-2.176% of agarose, however, then T₁ value suddenly increased by 176.46 ms and again decreased as the agarose concentration increased (r²=0.2088).

The regression slope test was done on each slope in FIG. 26. The regression slope test demonstrated that effect of gadolinium on T₁ values of the phantom was statistically significant (P<0.05) while the effect was found to be not statistically significant on T₂ (P>0.05). On the other hand, the effect of agarose on T₂ was statistically significant (P<0.05) while the effect of agarose on T1 was not (P>0.05).

### Relaxation Times and the Concentration of T1/T2 Modifiers

Factors that affect T1 and T2 relaxation times are generally based on molecular size, motion, and interactions [73]. Crosslinks form bridges across linear polymer chains to create large, branched molecules. The molecular motion of these larger molecules, created by crosslinking, is generally more limited, which shortens T1 and T2 [73]. This implies the correlation between the relaxation times and the density of crosslinks. Crosslinks in a polymer network decrease both T1 and T2 relaxation times [78], [79]. Other factors that possibly influence the relaxation time values are proton density and freely moving protons [72], [73].

Concentration of Agarose and gadolinium Trichloride: Increasing agarose concentration shortened the T2 relaxation time of CAGN phantoms. Agarose and carrageenan are linear polymers that are initially randomly distributed as single coils when it is dissolved in water at high temperature. These linear polymers begin to form double helices by forming intramolecular hydrogen bonding with other coils as the temperature of solution decreases and eventually aggregate into a 3D network. The 3D network increases molecular size and results in limited molecular motion. As the molecular motion is limited, the T1 and T2 relaxation times decrease. T2 relaxation time also increases as the interaction between water structure with polar sites of gel molecules increases [80]. The sample with lower concentration of agarose has more water content and thus, has longer relaxation times compared to the sample with higher concentration of agarose.

Increasing gadolinium trichloride concentration hypothetically shortens both T1 and T2 relaxation times. The impurity in polymer increases as foreign atoms and ions are introduced. These foreign atoms and ions affect organization of chain folding and therefore, affects the 3D network of polymers. As a result, the number of smaller 3D networked molecules increases as more foreign atoms and ions are present in the sample. This will shorten both T1 and T2 due to an increase in tumbling rate of molecules in a sample. However, the observed T1 relaxation times more rapidly decreased with increasing concentration of gadolinium trichloride as shown in FIG. 26A, while the observed T2 relaxation times only marginally yet non-statistically affected by the concentration of gadolinium as shown in FIG. 26B.

Gadolinium induces both longitudinal and transverse magnetic relaxation times because of its paramagnetic properties [81], [82]. However, it was found to be that gadolinium has a more dominant effect in decreasing T1 than decreasing T2 as shown in FIG. 26. The extent of effectiveness of gadolinium in T1 and T2 depends on the baseline of relaxation times when a material is not mixed with any contrast agent [81], [82].

The inverse of observed relaxation times or relaxation rates are the sum of relaxation rates of a material and the contrast agent [81].

$$1 / {T}_{1 obs} = 1 / {T}_{1 m} + 1 / {T}_{1 c}$$

$$1 / {T}_{2 obs} = 1 / {T}_{2 m} + 1 / {T}_{2 c}$$

where T_{1obs} and T_{2obs} are the observed relaxation times, and T₁ₘ and T₂ₘ are the relaxation times of a pure material. T_{1c} and T_{2c} are relaxation times attributed by a contrast agent and can be calculated by following equations:

$$1 / {T}_{1 c} = {r}_{1} [ C ]$$

$$1 / {T}_{2 c} = {r}_{2} [ C ]$$

where r₁ and r₂ are specific relativities of the contrast agent, measured in units of L/mmol-s, and [C] is the concentration of the contrast agent. The value of specific relaxivities of gadolinium contrast agents are not much different from each other [81]. And thus, resulting 1/T_{c} and 1/T_{2c} would be similar. However, when 1/T_{c} and 1/T_{2c} are substituted to equations for 1/T_{1obs} and 1/T_{2obs}, respectively, the degree of effectiveness of 1/T_{1c} on 1/T_{1obs} would be much greater compared to that of 1/T_{2c} on 1/T_{1obs}. Without wishing to be bound by theory, this could be because of two reasons: 1) the observed relaxation rate is the sum of inverse relaxation times of material and contrast agents 2) the T1 relaxation times of a tissue material is often 5-10 times longer than that of T2 relaxation times [81], [82].
Comparison with Relaxation Times of Human Muscle Tissue

Literature reported T1 and T2 relaxation times for human muscle tissue are about 898 to about 1420 ms and about 29 to about 50 ms respectively. [69], [70] The measured T1 and T2 of muscle CAGN samples that matched with actual muscle tissues ranged 1403-1416 ms, and 40-42 ms, respectively.

### Dielectric Measurements

### Results of CAGN Dielectric Measurements

For muscle CAGN samples, the dielectric constant was found to range between 76.65-85.49 F/m and the conductivity ranged between 0.212-0.741 S/m. Results are shown in Tables 16 to 18.

TABLE 12
Dielectric properties of muscle CAGN phantom relative to agarose concentration. The concentrations
of gadolinium and NaCl are fixed at 30.4 μmol/kg and 0.291%, respectively.

| | | | | | | | | | | |
|---|---|---|---|---|---|---|---|---|---|---|
| Agarose | 1.976 | 2.026 | 2.076 | 2.126 | 2.176 | 2.376 | 2.576 | 2.776 | 2.976 | 3.176 |
| concentration (%) | | | | | | | | | | |
| Dielectric | 77.758 | 78.947 | 78.189 | 78.515 | 78.677 | 78.807 | 78.751 | 78.093 | 78.173 | 77.940 |
| constant (F/m) | | | | | | | | | | |
| Conductivity (S/m) | 0.226 | 0.222 | 0.219 | 0.218 | 0.221 | 0.218 | 0.213 | 0.228 | 0.221 | 0.224 |

TABLE 13
Dielectric properties of muscle CAGN phantom relative to gadolinium
trichloride concentration. The concentrations of agarose and
NaCl are fixed at 3.176% and 0.291%, respectively

| | | | | |
|---|---|---|---|---|
| Gadolinium | 22.8 | 30.4 | 37.9 | 45.5 |
| concentration | | | | |
| (μmol/kg) | | | | |
| Dielectric | 77.610 | 78.189 | 79.412 | 76.647 |
| constant (F/m) | | | | |
| Conductivity (S/m) | 0.212 | 0.219 | 0.223 | 0.225 |

TABLE 14
Dielectric properties of muscle CAGN phantom relative to NaCl concentration. The concentration
of gadolinium and agarose are fixed at 30.4 μmol/kg and 3.176%, respectively.

| | | | | | | | | | |
|---|---|---|---|---|---|---|---|---|---|
| NaCl concentration (%) | 0.291 | 0.691 | 1.091 | 1.491 | 1.891 | 2.291 | 2.691 | 2.9126 | 3.091 |
| Dielectric | 77.94 | 78.28 | 80.12 | 81.63 | 83.25 | 83.78 | 86.46 | 82.02 | 85.49 |
| constant (F/m) | | | | | | | | | |
| Conductivity (S/m) | 0.224 | 0.291 | 0.366 | 0.444 | 0.530 | 0.578 | 0.679 | 0.713 | 0.741 |

A Regression slope test was performed on each data set on every graph in FIG. 27 to analyze the effect of gadolinium, agarose, and NaCl on dielectric properties of each tissue CAGN phantom samples. The test demonstrated that NaCl concentration affected both dielectric constant and conductivity values of muscle CAGN samples (P<0.05). The conductivity of muscle CAGN samples was significantly affected by gadolinium concentration (P<0.05). However, the dielectric constants were not affected by the concentration of either agarose or gadolinium (P>0.05).

### Dielectric Properties and Chemical Concentrations

Concentration of gadolinium trichloride, agarose, and NaCl: The relationship between the dielectric properties and concentrations of relaxation modifiers and NaCl in the CAGN phantom was studied. For this study, the dielectric constant, e′, and the dielectric loss factor, ε″ of each sample at 127.5 MHz was collected. The increasing concentration of NaCl linearly increased both dielectric properties of CAGN samples as shown in FIG. 27E. The results shown in FIG. 27B demonstrated that the conductivity of the muscle CAGN samples are significantly affected by addition of the gadolinium.

Alteration in chemical concentration and molecular structure in materials results in change in internal electric field strength of the material. Addition of ionizable chemicals including NaCl increases internal electric field strength through ionic and electronic polarization within a sample, thus increase the dielectric constant and conductivity of the sample. Gadolinium trichloride is also ionizable chemical when it is dissolved in water. However, it did not effectively affect the dielectric constant as much as NaCl and only affected several samples' conductivity. This is because only a very small amount of gadolinium trichloride was added to each sample. Compared to the concentration of NaCl which occupied 0.031-3.091 w/w % of a sample, gadolinium trichloride only consisted of 0.006-0.0022 w/w %. The amount of gadolinium trichloride and the concentration range may be insufficient to observe its effect on dielectric properties. Increasing the concentration of agarose decreased the conductivity of several CAGN samples. A previous study reported the relationship between decreasing electric field strength of agarose gel and increasing agarose concentration [83].

Comparison with Dielectric Properties of Human Tissues

The literature reported dielectric constant and conductivity of human tissue are about 64 F/m and 0.717 S/m respectively.

For muscle CAGN samples, the dielectric constant and conductivity were found to range 76.65-85.49 F/m and 0.212-0.741 S/m, respectively. At the concentrations of gadolinium, agarose, and NaCl were 30.4 μmol/kg, 3.176%, and 2.913%, respectively, the dielectric constant and conductivity of the phantom were found to be 83.78 F/m and 0.713 S/m, respectively. The measured conductivity of the sample with those concentrations was only 0.6% different from the actual muscle tissue value. The dielectric constant value of the sample was 10% different from the human tissue value.

### Image Segmentation, Surface Reconstruction and Design of the Moulds

An MRI dataset of a healthy 35-week fetus was selected for 3D reconstruction. The fetus was clinically confirmed to have a normally developed gross body and brain. The gray matter and white matter are easily distinguishable in the image.

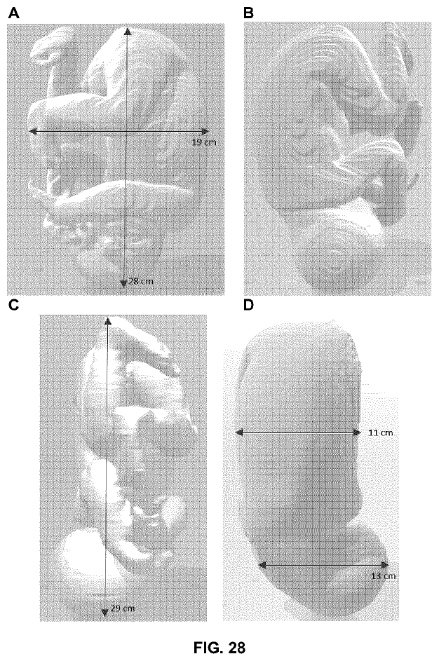

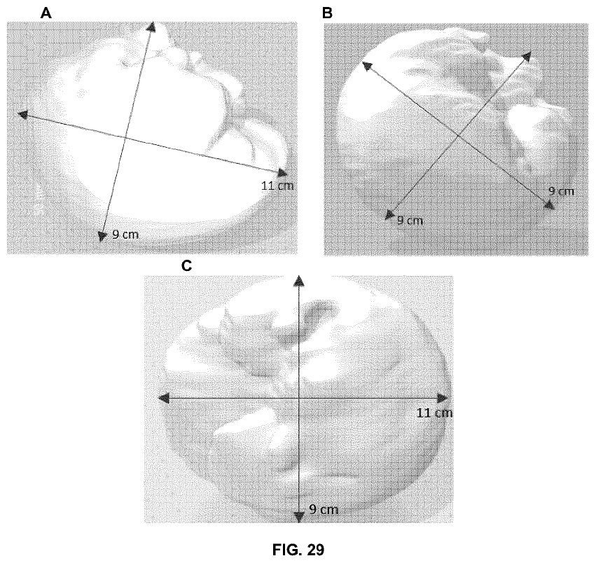

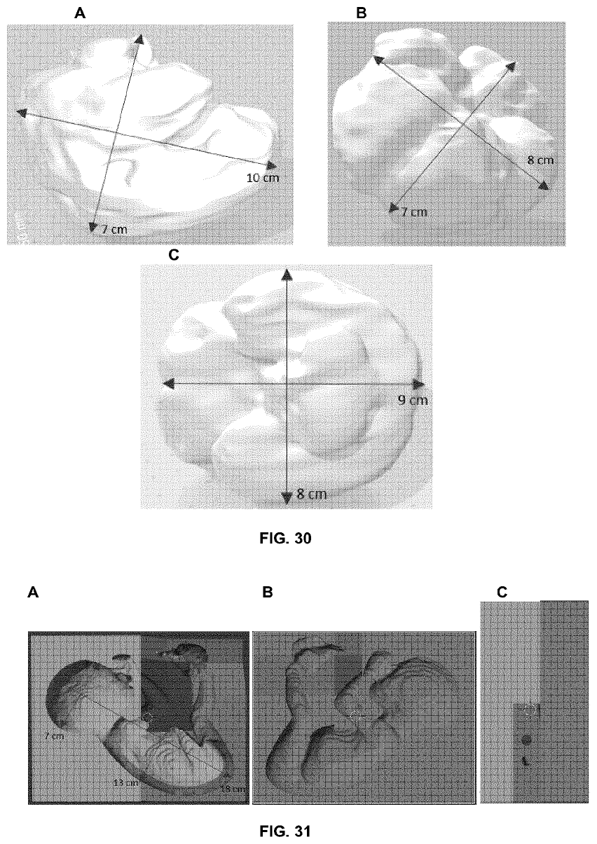

For segmentation, the fetal gross body including the head, trunk and limbs were differentiated from the maternal organs, umbilical cord, and the amniotic fluid. The differentiated regions on each slide of image in xy, yz, and xz planes, were traced and colored on the program. Once the tracing on each slide was complete, the segmented dataset was reconstructed in a 3D image of the gross fetal body (FIG. 28) or the fetal brain (FIGS. 29 and 30) by using the surface generation tool of the program. A surface smoothing option was applied during the process of surface generation to reduce uneven surface, but carefully done to not reduce too much volume.

The brain phantom was designed to have two chambers: the outer chamber for gray matter and inner chamber for white matter. Thus, two different segmented files were created. For segmentation of gray matter, the entire brain, which included the region of cerebrum, cerebellum, diencephalon, and ventricles, was selected, and was traced on each slide of MRI image for 3D reconstruction (FIG. 29). For segmentation of white matter, the brain region except outer gray matter was selected and traced on each slide of MRI image for 3D reconstruction (FIG. 30).

### 3D Printing of Moulds

### Preliminary Mould Printing and Casting

A half scale size of a gross fetal body mold was printed for testing the efficiency of the mold design. A pre-segmented MRI data of a 22-week-old fetus which had a relatively smaller body volume compared to a 35-week-old fetus was used to create a mold design shown in FIG. 31. The mold was designed to have six parts and two injection holes added on one the parts on the top of the mold as shown in FIG. 31C.

All parts were assembled together and applied with an adhesive bond along the edges of the inner empty space of the mold. The assembled mold was also tied with rubber bands to intensify the sealing so that a muscle mimicking material would not leak out of the mold. A muscle tissue mimicking material was prepared and poured through the two injection holes to fill approximately half of the inner space of the mold. And then it was vacuumed to remove any remaining air in the mould. This step was repeated until the tissue mimicking material filled the entire space inside of the mold.

If it is desired to avoid leakage of the muscle mimicking material while vacuuming, the number of injection holes can be increased to accelerate the silicone injection process, and to increase exits for air bubbles during vacuuming and to allow the muscle mimicking material evenly distributed throughout the inner space of the mold. Alternatively or additionally, a sealant on the outside gaps between the assembled parts can be used.

To facilitate removal of the phantom, a lubricant (e.g. Vaseline™) can be used on the inner surface of the casting mold.

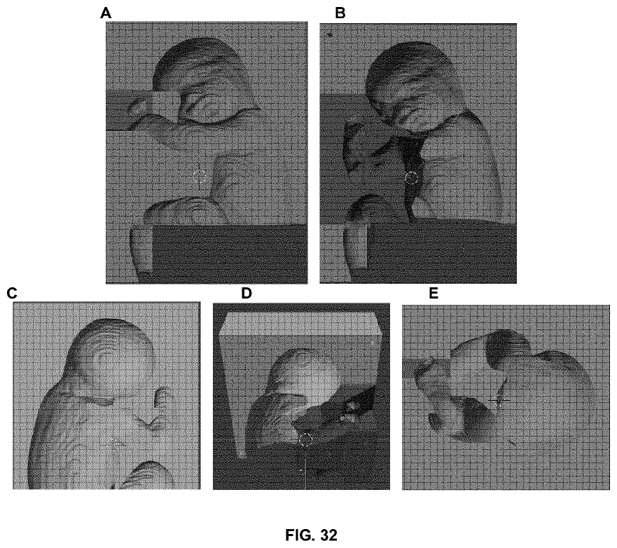

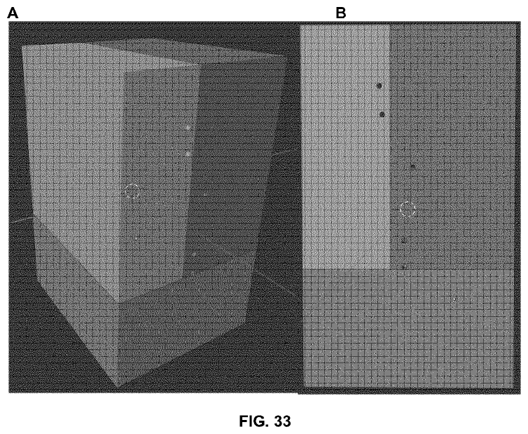

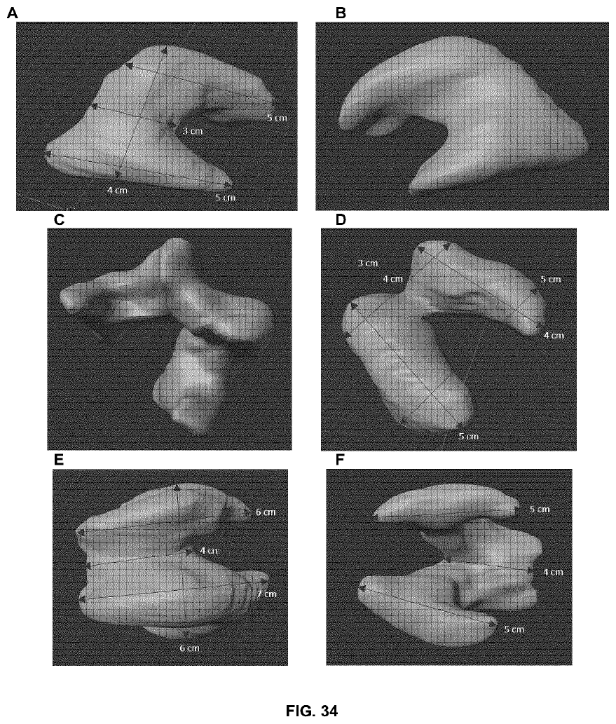

The surface roughness shown on the surface of the negative fetal volume in FIGS. 31A and B was caused by the gap between MRI 2D slices, i.e. the MRI spatial resolution and sampling rate. The gravid abdomen MRI data sets contained similar number of slides for each xy, yz, and xz planes regardless of gestational age. However, since the size of the 22-week-old fetus was smaller than a 35-week-old fetus, fewer imaging slices were obtained for the 22-week-old fetal body. This caused a rougher surface of the reconstructed 22-week-old gross fetal body compared to that of a 35-week-old fetus shown in FIG. 32A to E. However, this rough surface of the 22-week-old fetus was not an issue.

### Gross Body Phantom Mould

The gross body phantom mold was designed to be printed as seven parts as shown in FIG. 32, to facilitate removal of the body phantom after injection and solidification of the material. Each part is depicted with a different color to better visualize the layout of 3D printed parts. Five injection holes (two on the head region, three on the back region) with 0.4 mm diameters which connect the outer surface to the inner surface of the casting mold were created on the top parts shown in FIGS. 32 A and C.

Prior to 3D printing, the orientation of each mold compartment on the printing stage was adjusted to minimize the number of support structures, which were automatically generated by a program associated with the printer, between the printed object and the printing stage or between two surfaces of the printed object. The support structures prevent deformation of the printed object due to gravity or temperature change, however, they must be removed neatly so that the phantom casting would not be affected and produced a phantom with a dented surface due to an unremoved part of a support structure. Once a part of the mold is printed, any generated support structures were removed and sanded to smoothen the surface.

Afterward, Vaseline (Unilever, London, United Kingdom) was applied on the inner surfaces of each compartment, to prevent attachment of the phantom material to the surface and thus facilitate the removal of phantom from the mold after solidification of the material. All seven pieces of the gross body phantom are assembled together, and sealant was applied between the joints between the parts. To test the sealing of the resulting gross body phantom mold, water was poured through the five injection holes, and no leakage of water was observed.

### Brain Phantom Mould

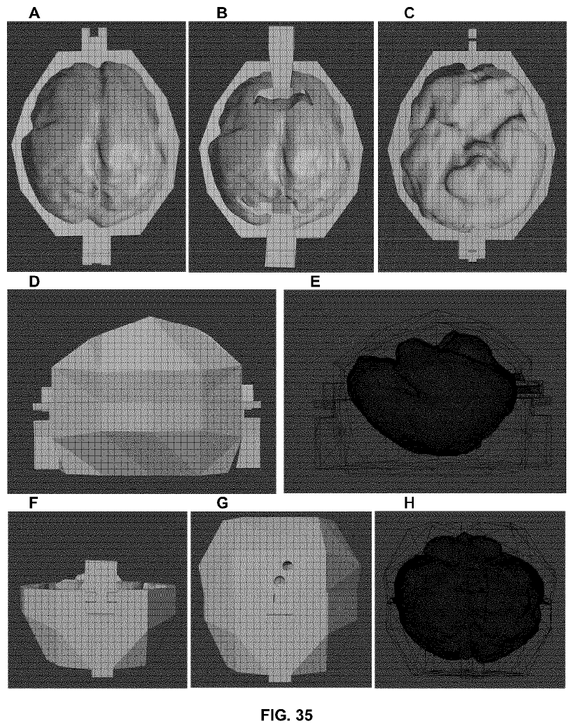

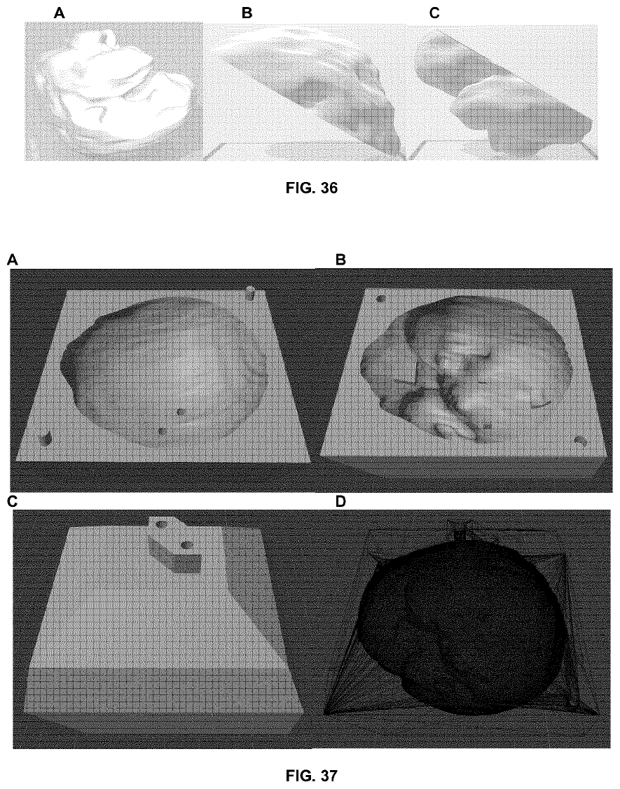

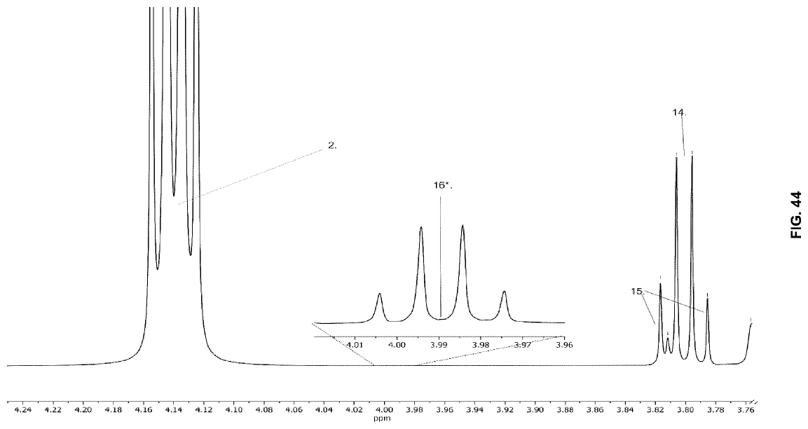

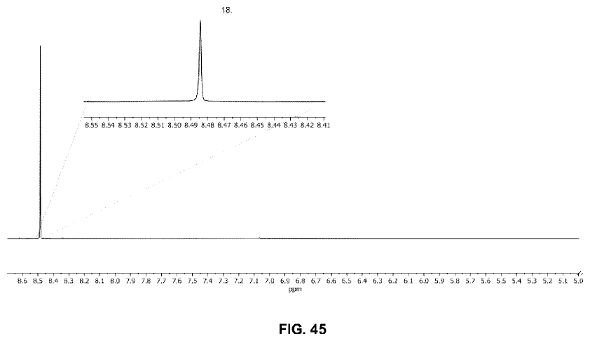

The method of creating brain phantom mold was designed with several steps. To begin with creating the brain phantom, the lateral ventricle as shown in FIG. 44 was 3D printed. Once the lateral ventricle was printed, the white matter phantom casting was prepared by assembling the white matter brain mold with the scaffolds as shown in FIG. 45B. The previously printed lateral ventricle was placed on the top of the scaffolds so that the lateral ventricle would not be displaced or lose its orientation. The white matter mold was filled with a CAGN solution formulated to simulate the relaxation times and conductivity of the white matter tissue. After the white matter CAGN solution becomes a solid gel, the scaffold was removed by sliding it laterally so that the scaffold would not disrupt the interface between the ventricle and the white matter CAGN gel. Once the scaffold is removed, the other half of the brain mold was put on top and the same CAGN solution was injected through the injection holes shown in FIG. 35G. The resulting phantom consisted of the ventricles and white matter. It was stored in the white matter shell shown in FIG. 36.

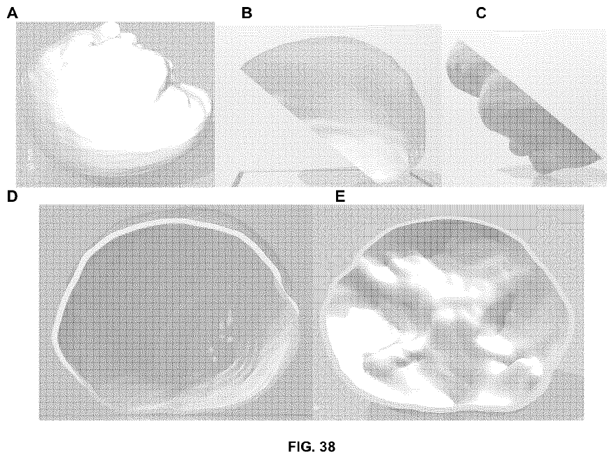

Then the white matter shell was placed on the pegs in the gray matter phantom mold shown in FIG. 37B which supported the white matter shell to be in the appropriate position. The gray matter phantom mold was then closed with the other half as shown in FIG. 37C and injected with the CAGN solution formulated to simulate the relaxation times and conductivity of the gray matter tissue. When the resulting phantom is removed from the gray matter phantom mold, the pegs will leave holes on the surface of the resulting phantom which was filled with the same CAGN solution. The reason for using pegs in the gray matter phantom instead of using a scaffold is that the weight of the white matter phantom shell that is containing the ventricle phantom and white matter gel phantom may be too heavy for a scaffold to stably support. The resulting phantom casted from the gray matter phantom mold can be stored in the gray matter shell shown in FIG. 38 to prevent potential water loss or contact with a phantom of the gross fetal body.

### Conclusion

Chemical formulation was identified for simulating the relaxation times of muscle tissues. For simulating the muscle, we found that CAGN (e.g. 3% carrageenan, 2.976-3.176% agarose, 30.4 μmol/kg gadolinium, and 0.291% NaCl) produced T1 of 987-1416 ms and T2 of 40-49 ms that fall into the relaxation time range of the muscle tissue (Table 11, respectively).

It is contemplated and shown herein that CAGN based material of the present application is suitable for mimicking muscle tissues.

The dielectric measurement was done on the CAGN for collecting the data of dielectric constant (ε′) and conductivity (σ). CAGN formulations were identified for simulating the conductivity of muscle tissues. For simulating the muscle, for example, CAGN (e.g. 3% carrageenan, 3.176% agarose, 30.4 μmol/kg gadolinium, and 2.913% NaCl) produced the conductivity of 0.713 S/m that closely matched the muscle tissue value (Table 14).

The anatomical shape of the fetal gross body and the brain were simulated through 3D-printed molds. A selected MRI dataset of a 35-week fetus was used as a template for designing 3D-printed molds of fetal gross body and the brain. The 3D-images of fetal gross body and the brain were reconstructed and used for designing 3D-printed molds of fetal gross body and the brain. Different printing methods were chosen to fabricate each fetal gross body and brain phantom based on the properties of each tissue-mimicking material. For constructing the gross body phantom, indirect 3D printing/casting mold method was selected.

For constructing the brain phantom, which includes gray matter, white matter, and lateral ventricles, both direct and indirect 3D-printing methods were adopted. The gray matter and white matter phantoms are casted using 3D-printed mold to simulate the anatomy of the brain. Each casted phantom of gray matter and white matter are stored in 3D-printed shells to prevent water loss and potential changes in material properties caused by the direct contacts between different hydrogels.

### Example 4 Amniotic Fluid Mimicking Composition

### Nuclear Magnetic Resonance (NMR) Spectroscopy and Amniotic Fluid

The relatively cost-effective and reproducible technique of NMR has proven extremely advantageous in disease detection and prognosis in-vivo [103], [106], [107]. A vast number of studies had been conducted to compare the metabolic fingerprint of patient samples against databases of samples collected from healthy individuals. The interactions between a sample of interest and its environment can be modeled by its chemical profile in the NMR spectrum, and can be applied to discern metabolites and biomarkers for diagnosing disease [92], [108], [109]. Consequently, this technique can be further applied to the study of amniotic fluid (AF) and its metabolites in the aim of diagnosing disease, or to assess fetal health throughout gestation.

By applying the foundations of MRS in AF studies, researchers can analyze the correlation between certain biomarkers and disease. Many studies that have quantified human AF have attempted to profile the entirety of its contents, and some have even noted metabolites which may indicate certain growth defects such as spina bifida [106], [109]. Although further research is required to understand more about each disease and its cause, the application of MRS on AF allows for a non-invasive method of diagnosing disease. This can be further developed to establish a novel prenatal routine that replaces amniocentesis, and be offered to all pregnant women regardless of their age, family history or physician.

Amniocentesis is a highly invasive procedure and is often performed earlier in pregnancy, at around 15-20 weeks of gestation, as needed [111], [112]. As a result, there is limited data available for AF that is representative of the entire pregnancy. Most studies analyzed AF at birth or near-term and characterized the metabolites using NMR techniques [84], [91].

MRS allows for the measure of concentrations of chemical components within tissues, and is based on the same physical principles as magnetic resonance imaging (MRI). While MRS is a powerful tool to use in vivo, NMR techniques offer higher resolution and can be used to evaluate the accuracy of artificial AF profiles [97], [98], [99]. To simulate precise quantitative measurements, it is desirable that the AF mimicking composition should be constructed to meet literature values and be representative.

### Literature Reported AF Metabolite and Concentrations

Literature reported AF metabolites and their concentrations are listed in Table 15.

TABLE 15
AF Metabolites and Concentrations

| | | | Study* | | | | | | |
|---|---|---|---|---|---|---|---|---|---|
| Metabolite | | | 1 | 2 | 3 | 4 | 5 | 6 | 7 |
| alanine | mean | umol/L | 126 | | 689 | 156 | 457 | 194 | 152 |
| | s.d. | | 26 | | | 66 | 119 | | |
| glycine | mean | umol/L | 73 | | | 139 | | 185 | 152 |
| | s.d | | 25 | | | 28 | | | |
| proline | mean | umol/L | 102 | | | 130 | | 103 | 132 |
| | s.d | | 17 | | | 58 | | | |
| valine | mean | umol/L | 49 | 323 | 198 | 54 | 168 | 67 | 44 |
| | s.d | | 16 | | | 22 | 52 | | |
| glutamine | mean | umol/L | 91 | 310 | | | | 223 | 277 |
| | s.d | | 30 | | | | | | |

*Each study was numbered according to the order in which they were read and recorded.
1. Lind, T et. al (1971)¹¹⁴
2. Cohn, B. R et al (2009)¹¹⁵
3. Wilson et al (1971)¹¹³
4. Reid et al (1971)⁹⁹
5. Sims et al (1993)⁹⁰
6. Levy, H. L and Montag, P. P (1969)¹¹⁶
7. Cockburn et al. (1973)¹¹⁷

### pH and Solubility Calculations

As the components of the artificial AF are predominantly water and water-soluble amino acids, it is desirable to maintain the solubility and pH conditions closely to what is observed in vivo. This is to minimize the common-ion effect and Le Chatelier's principle from affecting solute concentrations, particularly in polyprotic acids, which can skew results in the NMR spectrum [95], [106]. The dissociation equilibrium of each analyte in a volume was calculated in isolation of the others, and the resultant concentrations of all ionic species recorded. Subsequently, a new equilibrium for each analyte was found with these new initial solute concentrations, and the resultant new equilibrium concentrations of ionic species recorded. This process was repeated for 10 generations, until the intergenerational change in total proton concentration was less than 0.005% of the variance of the predicted equilibrium concentration. Conjugate bases of dissociated polyprotic acids were introduced as separate species to the calculation in later generations with their respective acid dissociation constants.

To achieve target pH of 7.25 and osmolality of 225 mM, as found in the literature review in AF [88], [114], an initial solution osmolality from all dissociated ionic species at equilibrium and an initial pH from the equilibrium proton concentration were calculated. The surplus of NaOH needed to sequester protons to reach the target pH was then found, and a new solution osmolality recorded. Finally, an according amount of HCl and NaOH required to reach the target osmolality was calculated for the artificial AF.

The resultant masses of HCl and NaOH needed to attain the target pH and osmolality AF were added to the experimental procedure.

### Experimental Procedure

The composition of AF is roughly 98-99% water (v/v), with the remainder being constituents of the cell [88]. The inorganic compounds such as sodium, chloride, and carbon dioxide (CO₂) exist in concentrations that mimic the extracellular environment of the cell and make up half of the remaining 1-2% of AF [88], [95], [118]. Organic materials make up the rest, balanced with proteins and small concentrations of carbohydrates that vary over the gestational period [119]. From the literature review conducted, 17 amino acids and simple sugars were identified [88], [95]. In accordance with studies that determined osmolality and pH of amniotic fluid, metabolites identified were mixed in solution to create a 100 mL artificial AF sample. Table 16 provides a summary of the metabolites and their physiological range of concentrations according to our literature search results.

Initially, the calculated average concentrations of each metabolite were used to determine individual masses of each respective metabolite for a 100 ml sample artificial AF. Metabolites whose mass required to prepare 100 mL artificial AF were less than LOQ of an analytical balance (1 mg) were serially mass-diluted from a concentrated stock preparation to reduce error. Once dilutions were created, each metabolite was then added to deionized water with continuous stirring, allowing for complete dissolution.

Upon the addition of the final metabolite, an internal standard was added at a known concentration. Calcium formate (trace-CERT) was used as a quantitative standard and chemical shift reference. Internal standards are pure compounds which are unrelated to the analyte, and contain the nucleus of interest, while having resonance which does not overlap with those of the metabolites in the sample [109], [120]. This standard's concentration was then used to determine those of the sample analytes. The standard in this experiment was expected to resonate between 7.5 and 8.5 ppm, occurring away from the analytes, which cluster between 0 and 4 ppm. The pH values were then measured and titrated to the target pH using concentrated NaOH and HCl to establish physiological conditions. NaOH and HCl were then added in equal parts to attain the target osmolality (225 mM [117], [121]). After producing the initial mixture of artificial AF, the sample was lyophilized and reconstituted in deuterated water (D2O), to better attenuate the solvent signal from overwhelming analyte peaks.

Glucose, an extremely important metabolite used in various clinical applications also acts as an important AF biomarker for various diseases. In previous studies conducted [95], [98], glucose was used to determine development of fetal abnormalities such as fetal hypoxia and energy metabolism. This metabolite is not only important, but abundantly found across AF samples in the literature. Although glucose prevails through various regions of the NMR spectra, it often overshadows other metabolites in the same vicinity along the spectrum. Previous AF characterization studies reported the presence of both alpha and beta glucose, which exist as isomers in solution, and can be detected distinctly on an NMR spectrum. To determine glucose concentrations with reference to literature, two separate experiments were run in tandem. The first included all metabolites and additives to the AF, as mentioned in the protocol, while the second omitted glucose only. The purpose of this experiment was to observe the variation in the spectra as a result of glucose addition.

TABLE 16
Metabolite Concentrations and Specifications in Amniotic Fluid

| | Molecular | Concentration | Literature 1H | |
|---|---|---|---|---|
| | Weight | in AF | Chemical Shift | |
| Metabolite | (g/mol) | (umol/L)* | (ppm)** | pKa** |
| citrate | 294.10 | 385.66 | 2.52 (d), 2.65 | 3.05, −4.2 |
| | | | (d) | |
| glucose | 180.16 | 2293.33 | 3.23 (dd), 3.40 | 11.3, −3 |
| | | | (m), 3.46 (m), | |
| | | | 3.52 (dd), 3.72 | |
| | | | (m), 3.82 (m), | |
| | | | 3.89 (dd), 4.63 | |
| | | | (d), 5.22 (d) | |
| lactic acid | 90.08 | 11443.33 | 1.32 (d), 4.10 | 3.78, −3.7 |
| | | | (q) | |
| alanine | 89.09 | 295.66 | 1.47 (d), 3.77 | 2.47, 9.48 |
| | | | (q) | |
| cystine | 240.29 | 66.33 | 3.18 (dd), 3.38 | 1.56, 9.34 |
| | | | (dd), 4.10 (dd) | |
| ethanolamine | 61.08 | 44 | 3.13 (d), 3.81 | 15.61, 9.55 |
| | | | (d) | |
| glutamic acid | 147.13 | 41 | 2.04 (m), 2.12 | 1.88, 9.54 |
| | | | (m), 2.34 (m), | |
| | | | 3.75 (dd) | |
| glycine | 75.07 | 137.25 | 3.54 (s) | 2.31, 9.24 |
| histidine | 155.16 | 49 | 3.16 (dd), 3.23 | 1.85, 9.44 |
| | | | (dd), 3.98 (dd), | |
| | | | 7.09 (d), 7.90 | |
| | | | (d) | |
| lysine | 146.19 | 105.25 | 1.46 (m), 1.71 | 2.74, 10.29 |
| | | | (m), 1.89 (m), | |
| | | | 3.02 (t), 3.74 (t) | |
| proline | 115.13 | 116.75 | 1.99 (m) 2.06 | 1.94, 11.33 |
| | | | (m), 2.34 (m), | |
| | | | 3.33 (dt), 3.41 | |
| | | | (dt), 4.12 (dd) | |
| glutamine | 146.15 | 225.25 | 2.13 (m), 2.45 | 2.15, 9.31 |
| | | | (m), 3.76 (t) | |
| serine | 105.09 | 76 | 3.82 (dd), 3.96 | 2.03, 8.93 |
| | | | (m) | |
| taurine | 125.15 | 119 | 3.25 (t), 3.42 (t) | −1.5, 9.34 |
| threonine | 119.12 | 118 | 1.32 (d), 3.57 | 2.21, 9.00 |
| | | | (d) 4.24 (m) | |
| valine | 117.15 | 129 | 0.97 (d), 1.03 | 2.72, 9.60 |
| | | | (d), 2.26 (m) | |
| | | | 3.60 (d) | |
| creatinine | 113.12 | 96.35 | 3.03 (s), 4.05 | 9.21, 4.96 |
| | | | (s) | |

### NMR Spectroscopy

A standard 1H NMR (699.80 MHZ) and a 2D 1H-1H zTOCSY NMR (699.80 MHZ) from the Varian pulse sequence library was acquired at 25° C. using an Agilent DD2 spectrometer equipped with a 5 mm sample tube in a 1H-19F {13C/15N} Triple Resonance Cold Probe. The 1H NMR was acquired with a pulse width of 9.3 microseconds (transmitter power of 53 db), 256 scans, a d1 delay of 10.1 seconds, and an acquisition time of 20.04 seconds totaling 455 k points in the FID. The 2D zTOCSY NMR was acquired with a pulse width of 9.3 microseconds (transmitter power of 53 db), 16 scans, 200 increments, a gain of 30, a d1 delay of 1 seconds, a spectral width in the F1 and F2 axes of 3930 Hz, and an acquisition time of 0.0918 s totaling 722 points.

### Statistical Analysis

All metabolites that comprised the artificial AF were analyzed amongst literature and experimental values to determine statistical equivalence (see appendix). To compare the concentration of metabolites in the artificial AF and literature derived values, a non-parametric test was first conducted. The Mann Whitney U Test, also known as Mann Whitney Wilcoxon or Wilcoxon Rank Sum Test, was used to determine whether the two populations have the same distribution. This test was conducted at a significance of alpha=0.05.

Upon determining the similarities in the spread of the data, a two-sample paired T-test was performed to determine whether these averages are statistically similar or significantly different from one another. The null hypothesis for this test states that both means are statistically similar, at alpha=0.05.

Finally, upon comparing the means of the two separate groups, we conducted an ANOVA to determine significance of variance in each metabolite in either group. Metabolites which were found to be statistically significantly different between the groups were further analyzed using t-tests at alpha=0.05.

### Results

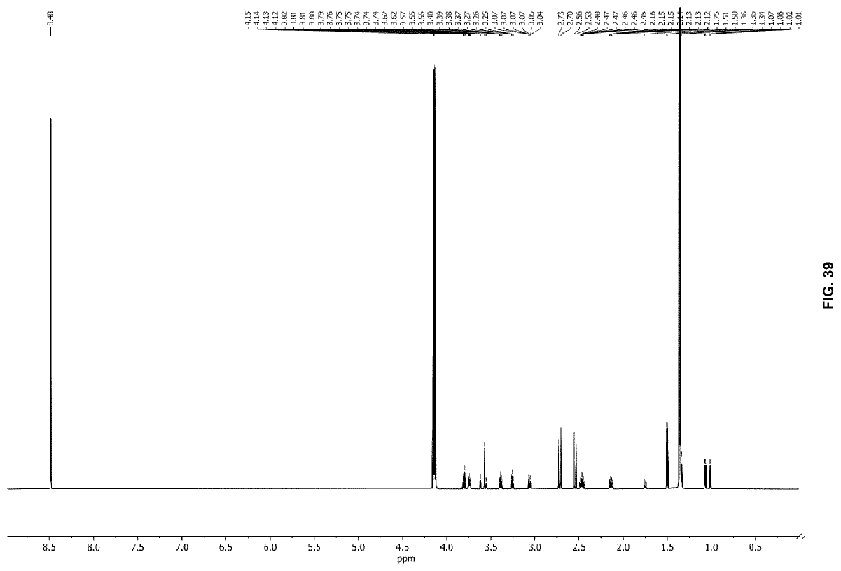

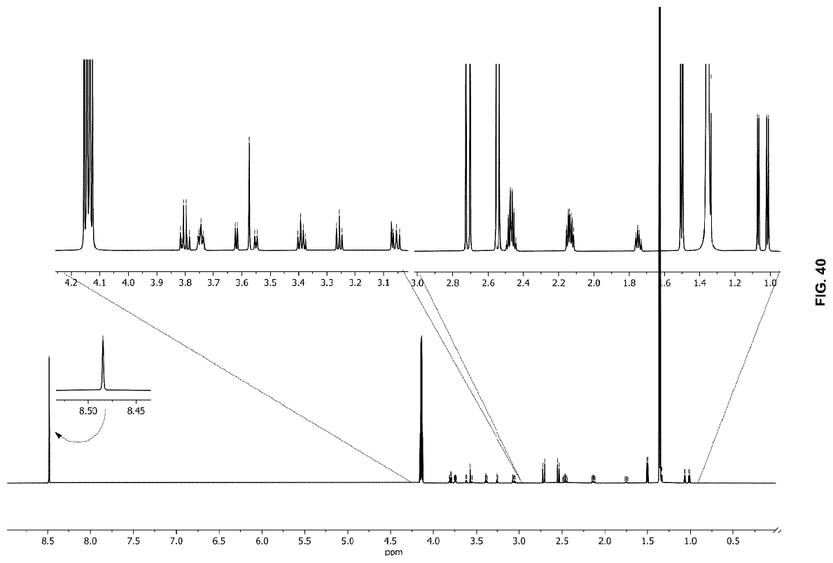

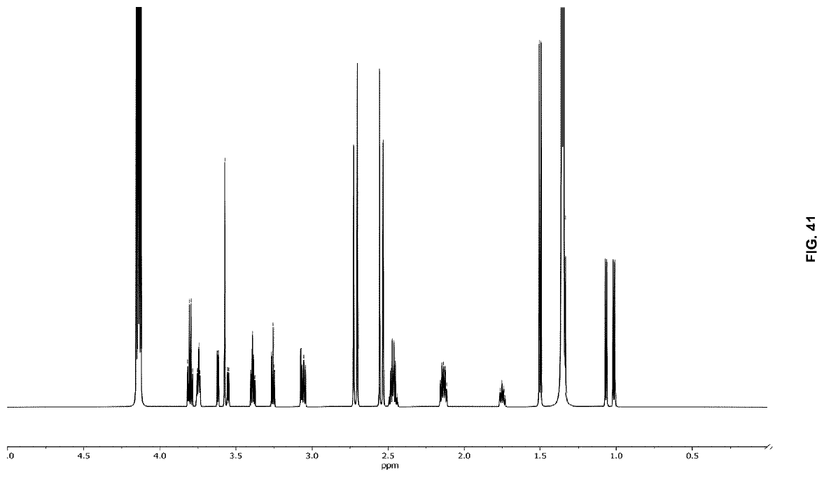

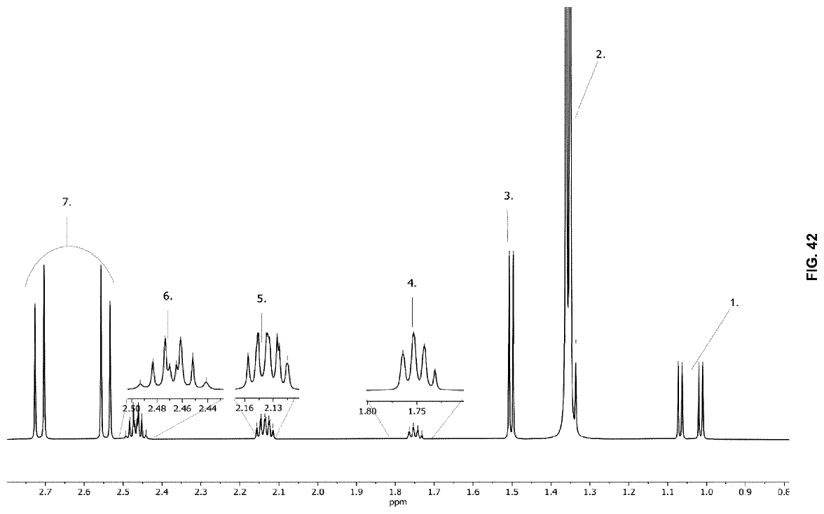

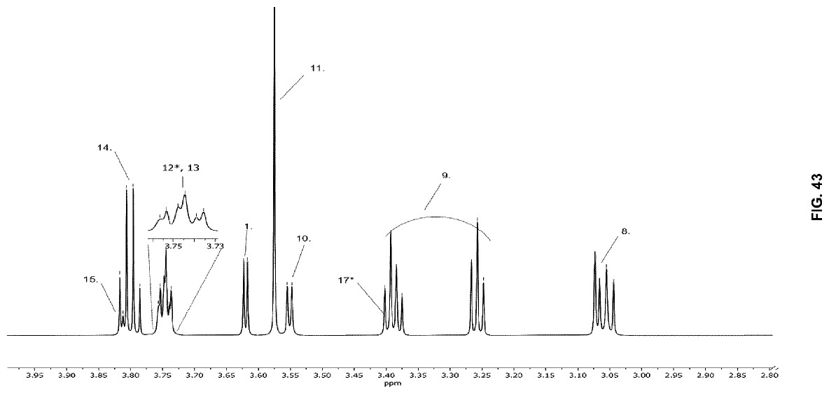

The entire 1D 1H-NMR spectrum of the artificial AF is shown in FIG. 39, encapsulating 0-9 ppm to capture all the metabolites. FIGS. 40 and 41 depict magnifications of the spectrum of interest, showing their occurrence amongst other metabolites and the solvent, deuterated water (D₂O). FIGS. 42 to 45 focus on smaller ranges of the spectrum and identify the metabolites which were found in each range with peak assignments respective to each metabolite. ‘**’ indicates overlapping peaks that could not be quantified accurately. Although integration of these metabolites were not possible, the respective peaks appear in the NMR spectra and are noted in the figures below. All peaks in the spectra are respectively identified using the Human Metabolomics Database (HMDB).

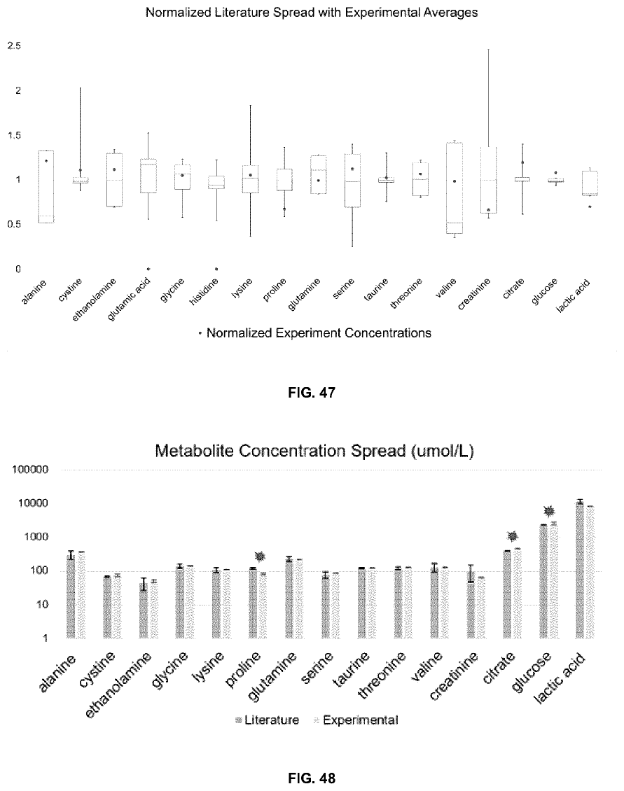

The calculated concentrations of each metabolite in the artificial AF from NMR spectroscopy are compared with those found in the literature from equivalent NMR studies of biological AF. After normalizing the data, ANOVA and non-parametric T-tests results are shown in FIG. 47 and illustrate the differences between the observed concentrations for each metabolite used in the artificial AF.

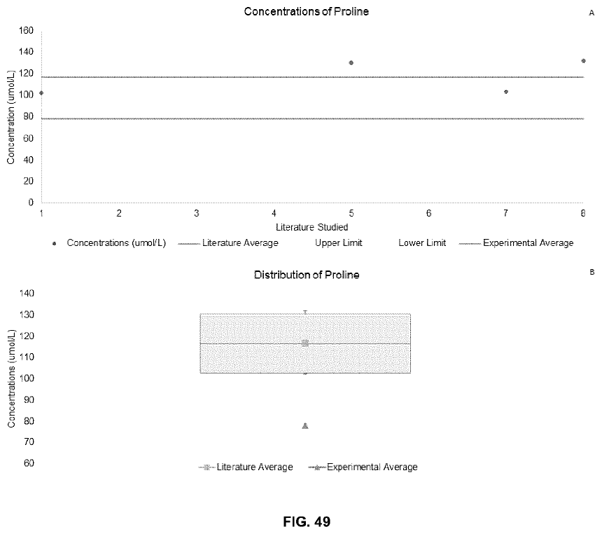

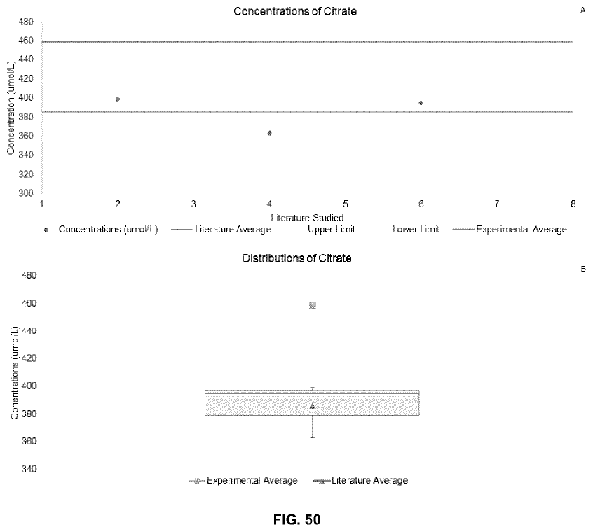

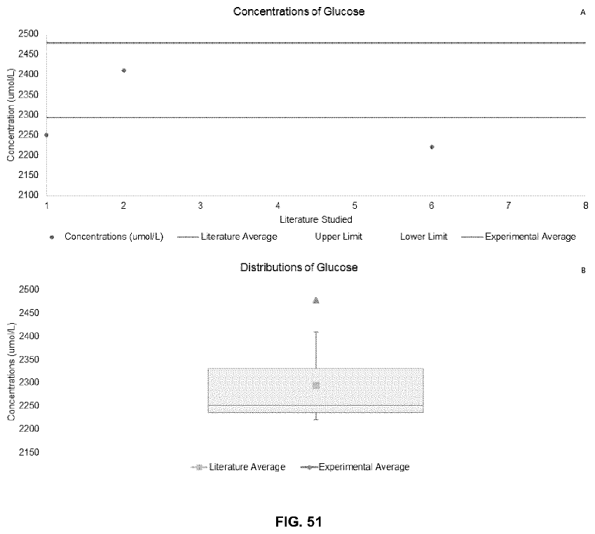

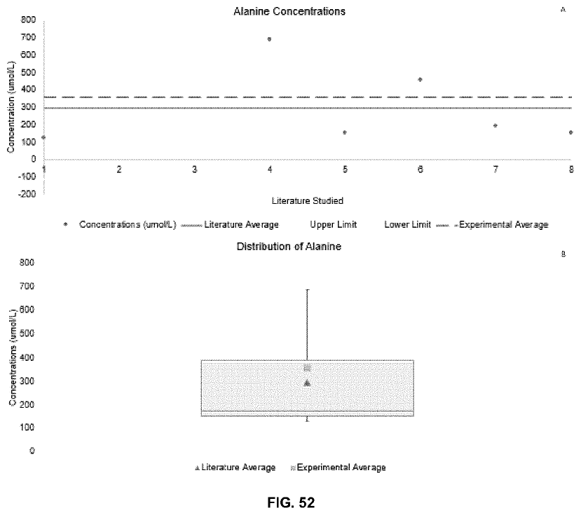

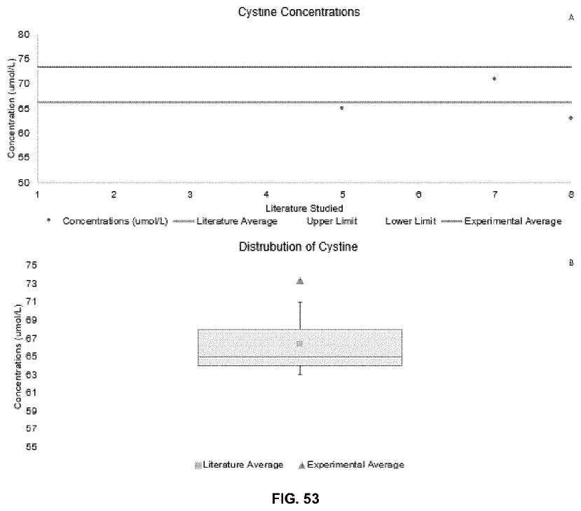

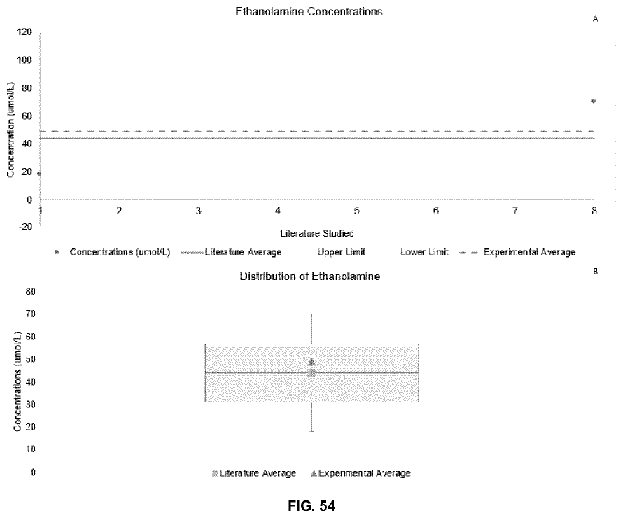

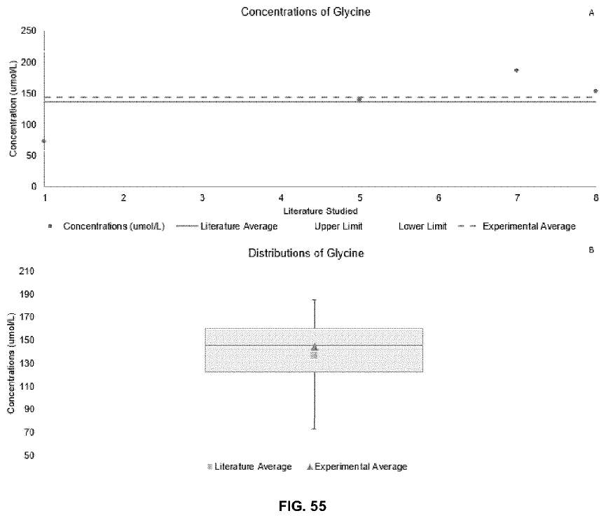

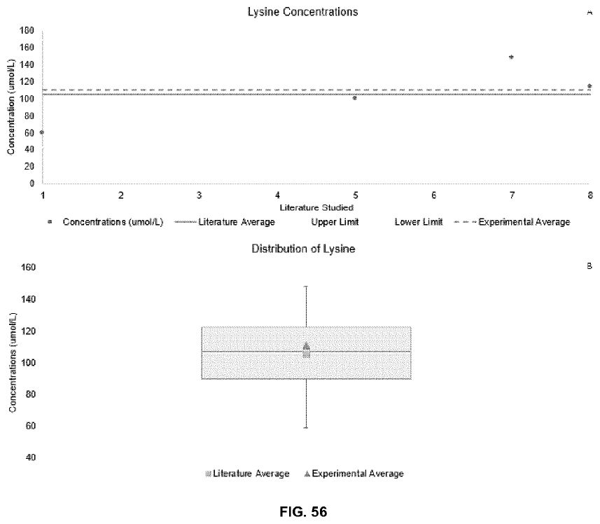

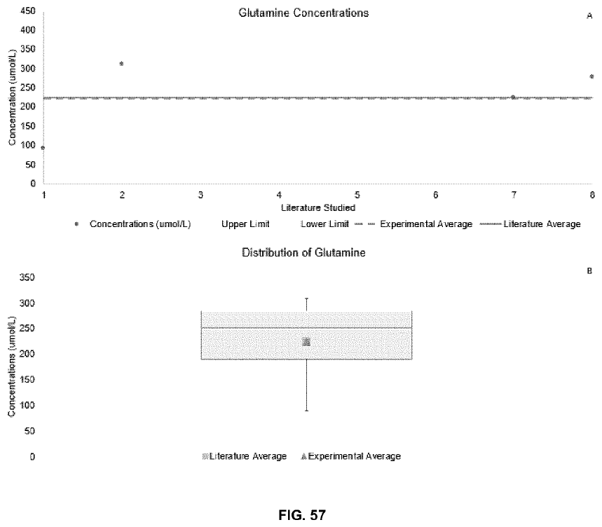

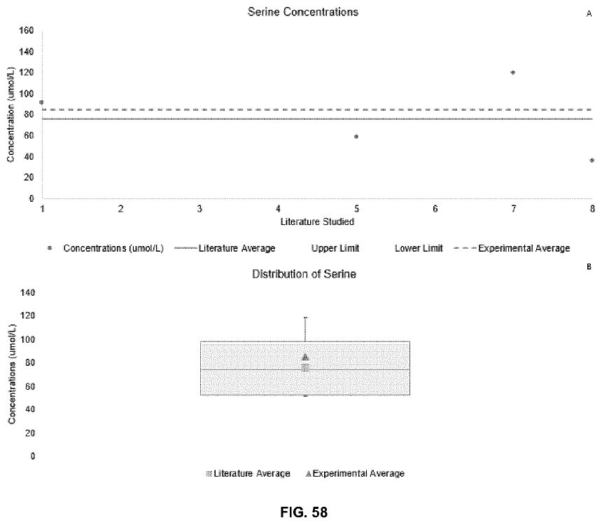

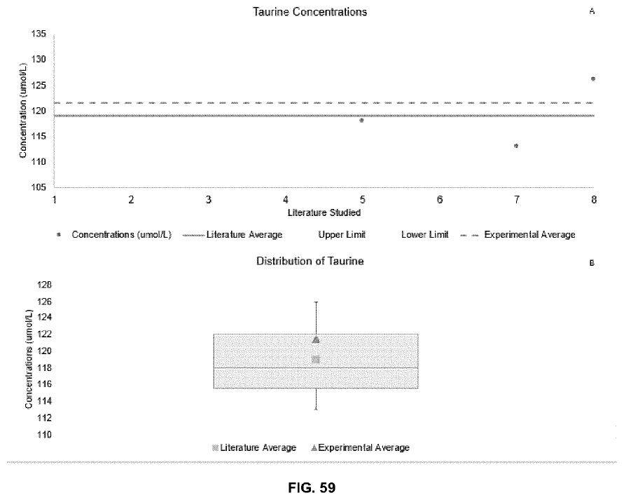

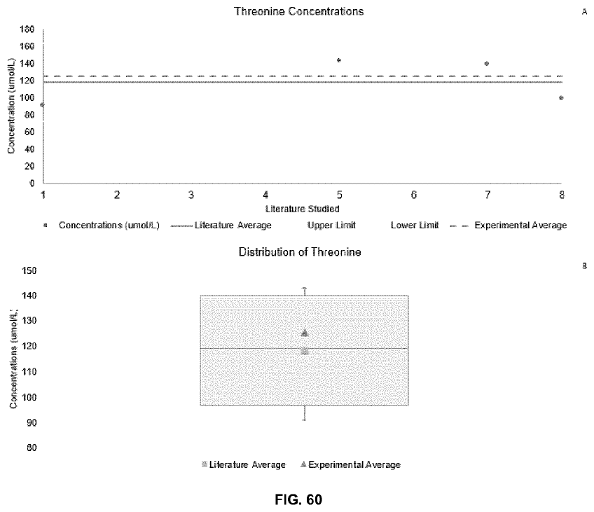

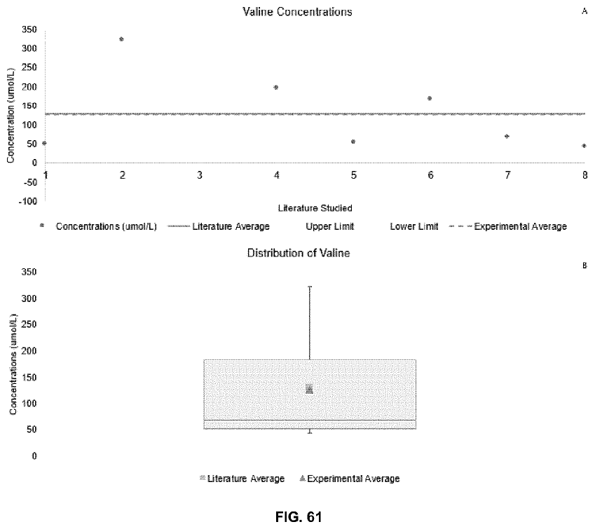

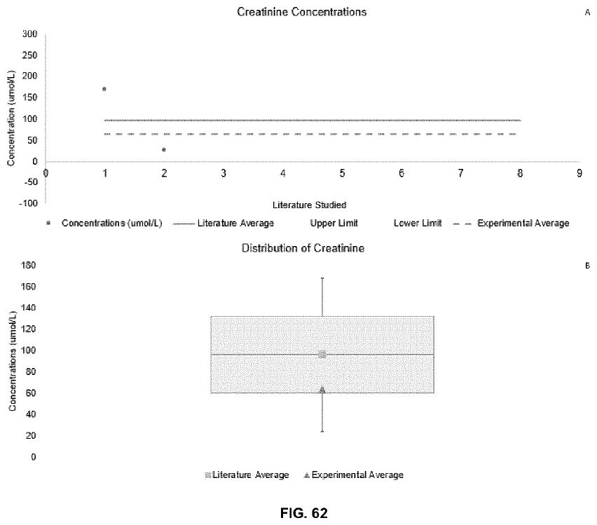

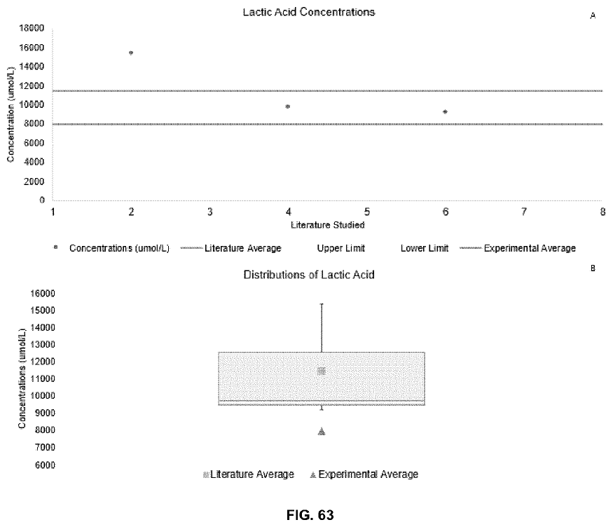

Metabolites proline, citrate and glucose yielded concentration results that were significantly different from anticipated literature values; (pₚᵣₒₗᵢₙₑ=0.005, p_{citrate}=0.007, p_{glucose}=0.04993, at a=0.05, FIG. 41). These results were then further analyzed using an ANOVA and T-tests to determine true differences in the data and are represented in FIGS. 49 to 51. The distribution of these metabolite concentrations was represented, along with the experimental values, to visualize where the values fell within the spread of literature data. These figures show the spread of each individual metabolite as they appear in the literature, and how these values compared with the experimentally derived concentrations. Also included are the error bars for each metabolite, showing the differences in two group means for these metabolites. Consulted literatures and their respective averages are also presented in the figures below. First, the various concentrations of respective metabolites are shown using a Bland-Altman plot. The upper and lower limits are indicated, along with data collected from chosen literature. Finally, a box-and-whisker plot was produced for each metabolite to visualize the variance in the data and compare the literature average to the experiment averages derived.

Glucose concentrations from the experiment were found to be significantly different from those in the literature (p=0.04993). Although the significance of this comparison is weak, it is imperative to determine the effects of either of the two states on fetal health and well-being. In artificial AF, glucose was present in two different states (alpha+beta), consistent with literature [122]. Carbohydrates, such as glucose, exist in solution as hemiacetals. Due to its several alcohol groups, glucose often exists in its two stable states at equilibrium. These configurations, alpha and beta, differ only in their spatial compositions. The difference in the glucose concentration between literature and experimental values differ due to the presence of these two glucose isomers in solution [87], [100].

Similarly, proline and citrate were also found to be statistically different from their literature counterparts (p (proline)=0.005 and p (citrate)=0.007). Both metabolites fall within heavily congested areas of the NMR spectrum, with proline at 1.99, 2.06, 2.34, 3.33, 3.41 and 4.12 ppm; and citrate at 2.52 and 2.65 ppm (Table 16). Both metabolites were heavily shadowed by other metabolites in this region, which can contribute to error.

Comparison of Experimentally Determined Concentrations with Literature Values

A Two-Sample T-test (T-Test) determined that the experimentally derived AF and literature values are statistically equivalent (p=0.41).

An ANOVA was performed to determine statistical significance between the mean concentrations of each metabolite in literature and experimental data. At the p<0.05 level for the three conditions, [F(1,28)=0.0519, p=0.82144]. Although the ANOVA test revealed no significant differences between the experimental and literature values, it revealed a statistically significant difference within the groups [F(1,14)=30.90, p=4.32089762073233E-08). Therefore, the null hypothesis that each metabolite shows equal means across the two groups was rejected.

To further explore the differences between the two groups for each metabolite, a T-test was performed. At the p<0.05 significance threshold, three metabolites were identified to have concentrations that differed significantly from the anticipated literature ranges. Proline (p=0.005), Citrate (p=0.007) and Glucose (p=0.04993) were all found to have concentrations that failed to reject the hypothesis that the mean concentrations across the groups were equal.

### Discussion

A protocol for making artificial AF was created based on the ranges of concentrations of AF metabolites as identified in literature and quantified via 1H-NMR. The artificial AF was then tested and confirmed to reproduce the anticipated spectral peaks, splitting patterns, and metabolite quantitative values as those of biological AF.

With the results of the ANOVA test, the means of concentration metabolites in the artificial AF was confirmed to not differ from those of metabolites in AF collected and compared in earlier literature (p=0.8214). In practice, finding a true spectral match between any AF and artificial AF sample may be impossible, and therefore, use the degree of resemblance as a reliable measure [102], [123]. NMR spectra of biomolecule solutions such as AF generate a large number of peaks in a small chemical shift range. Therefore, peaks generated by different species have a high chance of overlap, especially in aliphatic regions (˜1-4 ppm). As a result, the signal from compounds present in larger concentrations can overwhelm smaller concentration metabolites, rendering them impractical for analysis. Furthermore, there is a limitation in the available data on AF of pregnant women in late gestation, making it difficult to match spectra across populations with statistical significance. From the present studies, the NMR spectra observed in the artificial AF resembles that of existing literature [87], [95], [124], and metabolites were identified and integrated within the ranges reported in the Human Metabolome Database (HMDB), and are consistent with literature spectra.

The metabolites, histidine and glutamic acid, both have NMR peaks falling within the aliphatic range of 3.1-3.8 ppm and 2.0-2.8 ppm, respectively, which overlapped significantly with other metabolites. Furthermore, their concentrations are among the lowest of the metabolites investigated in this study. Therefore, the peak assignments for these metabolites were excluded from the analysis.

Findings for citrate were consistent with existing literature [125], which suggested that reproducibility of the metabolite in NMR is not always accurate. Citrate is often discussed as a significant metabolite, especially in reference to the citric acid cycle. In a study conducted to analyze the peak reproducibility of citrate, it was found that signals often double or disappear completely [125]. This phenomenon is not well understood and has been attributed by Ross et. al. to be due to the extreme sensitivity of citrate in the pH range of 4-8 [101], [125], [126]. In this region, the entire spin system of citrate is shifted and, thus, causes distortion in the peaks observed [101]. Citrate is a weak diprotic acid, and is heavily dependent on pH changes, which cause its electron density to shift.

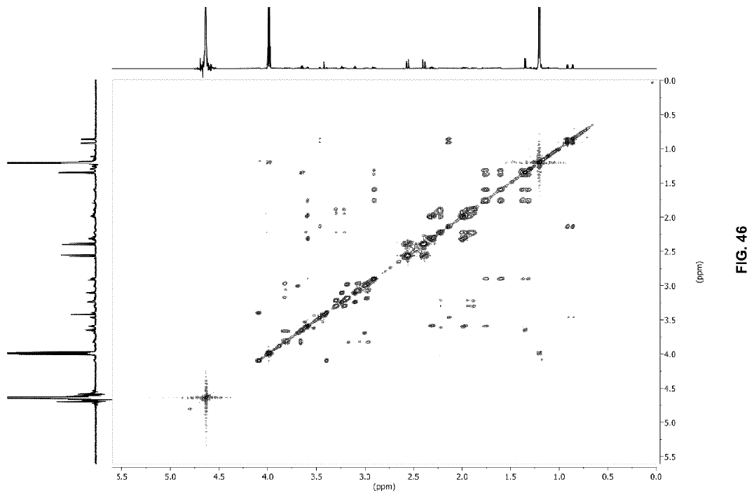

A 2D NMR acquisition was used to improve the resolution of the acquired spectrum and reduce the associated noise despite the relatively long acquisition times required [89], [95]. The output of a 2D NMR spectrum shows the cross peaks between the 1D H-NMR spectra laid against the x and y axis, which indicate J-coupling between the hydrogen nuclei and their neighboring counterparts (FIG. 46). The Total Correlation Spectroscopy (TOCSY) performed detected proton interactions unrestricted to the closest neighbours and instead, looked at spin systems. This allowed for the identification of larger, interconnected systems as well as mixtures. The 2D analysis gathered here distinguished interactions amongst metabolites used in the AF, and provided some explanation regarding the overlapping of NMR signals acquired.

NMR sequences are often analyzed using Fourier or Hadamard Transformations [89]. In this example, a Lorentzian quantification method was applied, following a Fourier transformation, at a frequency bin of 0.04 Hz. To calculate this, the total spectral window was divided by the number of points used in the Fourier transform from the spectrum. In other NMR specific studies, the Hadamard transform was able to pick out spectral regions of specific interest, while ignoring the rest of the spectrum and residual noise [95]. Similarly, there were extensive alterations to these transformations that could be developed to determine the ideal mode of spectral acquisition for the aim of this project.

### Conclusion

Spectroscopic studies have determined that AF metabolite concentrations correlate with gestational milestones [119]. Renal function, assessed using a combination of several concentrations of metabolites, such as indoxyl-sulphate, histidine, and formate, enabled to correlate kidney function with fetal growth [94], [113], [115]. Similarly, fetal metabolism, heart health, birth weight, and implications on maternal health, such as diabetes, have correlated with varying concentrations of amino acids found in AF [92], [98], [120]. Overall, spectroscopic analysis of AF is a promising fetal diagnostic tool which could also identify biomarkers of aneuploidies, preeclampsia, preterm delivery, spina bifida and low birth weight, to name a few [86], [87], [92], [94], [95], [115], [118], [120], [121], [124], [127]. The ability to simulate AF provides researchers with a tool to facilitate development of a non-invasive MRS-based fetal diagnostic tool to determine causes and correlations of disease with various gestational metabolites.

In this example, literature data on AF consistency close to or at birth was used to create a protocol for synthetic AF. Given that amino acid concentration does not change significantly between the 6th and 9th months of gestation [116], the established protocol could be used to synthesize third trimester AF, in general. It can be understood that availability of AF data from early gestation would permit creating a protocol for AF at earlier gestational periods using the methodology developed herein.

An artificial AF has been developed and validated using 1H-NMR spectroscopy. While NMR offers significantly higher resolution compared with MRS, the former was used in this study because it facilitated an accurate comparison with the available data from the literature, which were all acquired in-vitro using NMR as well.

Current in-vivo NMR methods done on intact live species often produce increased line widths, causing distortion. The applicability of 1H-NMR and other modes of metabolomic imaging can be significantly increased if reduction of spectral lines were possible. In a study conducted to image breast cancers using metabolomic techniques, magnetic resonance spectroscopic imaging (MRSI) was used as an alternative to the single-voxel spectroscopy (SVS) used often in MR spectroscopy studies [85], [104], [105]. In SVS studies, the signals from a single region are detected and read, while MRSI employs a multi-voxel approach, obtaining signals from multiple regions at the same time to provide information of spatial distribution of metabolites [93]. This approach then uses one metabolite as a standard, similar to quantitative NMR standards used in this paper, to determine relative quantities of other metabolites. These methods have been used in detecting the metabolic changes in Parkinson's disease, allowing for improvement in disease management and diagnostic accuracy [93].

It can be understood that signal acquisition can be improved with for example adjustments in the magnetic field, reducing voxel sizes or in applying shimming processes. Shimming is done to homogenize the applied magnetic field, and thus to produce high quality NMR measurements [128]. There are a variety of shimming methods and procedures, an example being: FASTMAP (fast, automated shimming technique by mapping along projections). This approach has been demonstrated in the liver, muscle, in the septum of the heart of a live mouse and in humans [110]. LOCMAT (localized magic angle turning) has been used in previous studies on the liver and heart of a live mouse, at relatively low magnetic fields (2T). As discussed in a paper by Wind, Hu and Majors, this process was successful in analyzing areas in the body at low fields, and they hypothesize even better resolution improvements with incrementing higher magnetic fields [107].

### Example 5 Carrageenan-Based Fetal Tissue Mimicking Composition

Additional carrageenan-based compositions were prepared and T1 and T2 relaxometry measured. It has been shown herein that T1 and T2 relaxometry have been optimized to match different target values.

Into 50 mL deionized water, 3.2799 g NaCl were massed and dissolved to make a 1.1255 mol/L stock saline solution. 5 mL of this stock saline solution was then transferred to each of six 50 mL-volumetric flasks. To each flask, 30 uL 50% w/w glutaraldehyde was added. Deionized water was added to bring each flask solution to the calibrated 50 mL mark. The six solutions were transferred to six beakers respectively. To the beakers, 0, 0.25, 0.50, 0.75, 1.00, 1.25 g of carrageenan were weighed and added respectively to make 0, 0.5, 1.0, 1.5, 2.0, and 2.5% w/w carrageenan mixtures. The mixtures were stirred with a glass rod to disperse and hydrate the powdered carrageenan evenly. A water bath was brought to a slow boil over a hot plate with boiling chips. In succession, each beaker containing a carrageenan mixture was submerged in the water bath, a magnetic stir rod added, and a watch glass placed atop the beaker to prevent water loss. The contents were stirred continuously at 600 rpm to allow event heat distribution. The mixtures were allowed to heat until complete swelling of the carrageenan matrix, and the mixture rendered transparent, >5 min. Stirring was then reduced to <100 rpm to promote the nucleation of dissolved gases. The liquid mixtures were transferred to 50 ml conical base tubes and loosely capped. The conical tubes were placed in a vacuum chamber, and a vacuum pressure of 10 inHg was applied cyclically in 2-min intervals, further promoting the escape of dissolved gasses. The conical tubes were then capped tightly, and the lids wrapped in parafin substrate film (Parafilm) to reduce water loss, before being allowed to cool to ambient temperature, completing gelling. The solution tubes were then stored continuously at 4° C.

Two hours prior to MR measurement of relaxation properties, the sample tubes were removed from 4° C. to equilibrate with ambient temperature. A 2D multislice inversion recovery turbo spin echo (IR TSE) pulse sequence was used to acquire a T1 recovery curve of the sample tubes with inversion times (TI) 500, 1000, 2000, 3000 ms. A multiecho spin echo (MESE) pulse sequence was used to acquire a T2 relaxation curve of the sample tubes with echo times (TE) 15, 30, 45, 60, 75, 90, 105, 120, 135, 150, 165, 180, 195, 210, 225, 240, 255, 270, 285, 300, 315, 330, 345, 360, 375, 390, 405, 420, 435, 450 ms. Circular regions of interest (ROIs) were drawn of equal area on transverse slices of the IR TSE and MESE images in all slices intersecting the sample tubes. ROIs were inset from the edges of the sample tubes by 2 pixels to eliminate partial volume effects. The T1 recovery time was fit voxelwise across all measured TI. ROI average T1 was thus collected for each slice, and the slice T1s averaged across all slices for each sample tube to yield a sample average measured T1. Sample T2 was determined from MESE images similarly. The sample average T1 and T2 are provided in the table below.

TABLE 17
T₁ and T₂ relaxation time of carrageenan-based compositions

| % w/w | T₁ | T₂ |
|---|---|---|
| carrageenan | (ms) | (ms) |
| 0 | 2630.9 ± 34.9 | 2630.9 ± 16.8 |
| 0.5 | 2472.9 ± 63.5 | 1801.9 ± 15.7 |
| 1.0 | 2366.2 ± 53.5 | 1136.2 ± 26.6 |
| 1.5 | 2260.2 ± 51.8 | 815.7 ± 20.4 |
| 2.0 | 2144.8 ± 46.1 | 649.7 ± 7.7 |
| 2.5 | 2035.0 ± 40.6 | 422.4 ± 11.0 |

As shown herein, such as discussed below, the tissue mimicking composition of the present application can be adapted to obtain different target T1/T2 relaxation times by varying the concentration of MnCl₂ and/or agarose in the carrageenan-based composition. The r₁ and r₂ relaxivities of MnCl₂ and agarose were drawn from Table 6 and Table 7. Combinations of MnCl₂ and agarose concentrations were determined to match tissue phantom material relaxometric properties by solving the following system of equations:

$$\frac{1}{{T}_{1}} = \frac{1}{{T}_{{1}_{0}}} + {r}_{{1}_{{MnCl}_{2}}} [ {MnCl}_{2} ] + {r}_{{1}_{agarose}} [ agarose ]$$

$$\frac{1}{{T}_{2}} = \frac{1}{{T}_{{2}_{0}}} + {r}_{{2}_{{MnCl}_{2}}} [ {MnCl}_{2} ] + {r}_{{2}_{agarose}} [ agarose ]$$

where T₁_{₀} and T₂_{₀} are the measured T₁ and T₂ of one of the above fabricated carrageenan gel samples.

For example, literature T1 and T2 relaxometric values for placental tissue, fetal brain white matter (WM) and grey matter (GM) are tabulated in the below table, alongside gestational age (GA) of measurement.

TABLE 18
Literature T₁ and T₂ relaxation time of placental
and brain white matter and grey matter tissues

| Tissue | T₁ (ms) | T₂ (ms) | GA (weeks) | Reference(s) |
|---|---|---|---|---|
| GM | 1917 ± 104.4 | 158 ± 114 | 28-37 & 32.6 | [129] and [130] |
| WM | 2950 ± 122.4 | 158 ± 114 | 28-37 & 32.6 | [129] and [130] |
| Placenta | 1770 ± 173 | 55 ± 7 | 32.6 | [129] |

Taken in context with prior referenced tissue relaxometric properties, some examples of target T1 and T2 phantom tissue property ranges are summarized in the table below, spanning early 3rd trimester through adult tissue properties. It is contemplated that other target T1/T2 values can be used to mimic tissues of other (gestational) age.

TABLE 19
Target T1 and T2 ranges

| Tissue | T₁ (ms) | T₂ (ms) |
|---|---|---|
| GM | 1275-2021.4 | 44-272 |
| WM | 812.3-3072.4 | 44-272 |
| Placenta | 1450-1943 | 48-300 |

Applying the system of equations shown above, carrageenan concentration selected for T₁_{₀} and T₂_{₀} was determined by the highest carrageenan concentration such that the entire target range of T1 and T2 values resulted in non-negative [MnCl2] or [agarose]. The resultant tissue phantom compositions and reduced relaxometry ranges are summarized in the table below.

TABLE 20

| | [Carrageenan] | [MnCl₂] | [agarose] | T₁ | T₂ |
|---|---|---|---|---|---|
| Tissue | % w/wl | (μM) | (% w/w) | (ms) | (ms) |
| GM | 1.5 | 0-43.3 | 0-2.33 | 1274.4-2021.7 | 43.9-274.2 |
| WM | 0 | 0-116.4 | 0-2.51 | 812.4-2595.5 | 43.9-272.2 |
| Placenta | 3 | 5.9-34.8 | 0.01-2.16 | 1449.6-1944.0 | 47.9-301.3 |

Accordingly, different tissue mimicking material compositions can be obtained, in accordance with the teaching herein to obtain desired T1 and/or T2 properties, or average thereof.

While the present disclosure has been described with reference to examples, it is to be understood that the scope of the claims should not be limited by the embodiments set forth in the examples, but should be given the broadest interpretation consistent with the description as a whole.

All publications, patents and patent applications are herein incorporated by reference in their entirety to the same extent as if each individual publication, patent or patent application was specifically and individually indicated to be incorporated by reference in its entirety. Where a term in the present disclosure is found to be defined differently in a document incorporated herein by reference, the definition provided herein is to serve as the definition for the term.

### FULL CITATIONS OF DOCUMENTS REFERENCED IN THE DISCLOSURE

1. T. KUWATA ET AL., “ESTABLISHING A REFERENCE VALUE FOR THE FREQUENCY OF FETAL MOVEMENTS USING MODIFIED ‘COUNT TO 10’ METHOD,” JOURNAL OF OBSTETRICS AND GYNAECOLOGY RESEARCH, VOL. 34, NO. 3, PP. 318-323, 2008, DOI: HTTPS://DOI.org/10.1111/J. 1447-0756.2008.00791.X.
2. R. NATALE, C. NASELLO, AND R. TURLIUK, “THE RELATIONSHIP BETWEEN MOVEMENTS AND ACCELERATIONS IN FETAL HEART RATE AT TWENTY-FOUR TO THIRTY-TWO WEEKS' GESTATION,” AM J OBSTET GYNECOL, VOL. 148, NO. 5, PP. 591-595, March 1984, DOI: 10.1016/0002-9378 (84) 90754-3.
3. A. B. ROBERTS, D. LITTLE, D. COOPER, AND S. CAMPBELL, “NORMAL PATTERNS OF FETAL ACTIVITY IN THE THIRD TRIMESTER,” BJOG: AN INTERNATIONAL JOURNAL OF OBSTETRICS & GYNAECOLOGY, VOL. 86, NO. 1, PP. 4-9, 1979, DOI: HTTPS://DOI.org/10.1111/J. 1471-0528.1979.TB10674.X.
4. A. PIONTELLI, “DEVELOPMENT OF NORMAL FETAL MOVEMENTS,” 2010. HTTPS://BOOKS-SCHOLARSPORTAL-INFO.EZPROXY.LIB.RYERSON.CA/EN/READ?ID=/EBOOKS/EBOOKS2/SP RINGER/2011-02-17/1/9788847014022 (ACCESSED Feb. 28, 2021).
5. “PERISTALSIS|PHYSIOLOGY,” ENCYCLOPEDIA BRITANNICA. HTTPS://WWW.BRITANNICA.COM/SCIENCE/PERISTALSIS (ACCESSED Feb. 28, 2021).
6. P. MAD′A, “2. BOWEL MOVEMENTS. FUNCTIONS OF CELLS AND HUMAN BODY.” HTTP://FBLT.CZ/EN/SKRIPTA/IX-TRAVICI-SOUSTAVA/2-MOTILITA-GASTROINTESTINALNIHO-TRAKTU-A-JEJI-RIZENI/(ACCESSED Feb. 28, 2021).
7. P. V. LEEUWEN, K. M. GUSTAFSON, D. CYSARZ, D. GEUE, L. E. MAY, AND D. GRÖNEMEYER, “AEROBIC EXERCISE DURING PREGNANCY AND PRESENCE OF FETAL-MATERNAL HEART RATE SYNCHRONIZATION,” PLOS ONE, VOL. 9, NO. 8, P. E106036, August 2014, DOI: HTTP://DX.DOI.org.EZPROXY.LIB.RYERSON.CA/10.1371/JOURNAL.PON E.0106036.
8. J. VAN AMEROM, D. LLOYD, A. PRICE, M. MURGASOVA, AND P. ALJABAR, “FETAL CARDIAC CINE IMAGING USING HIGHLY ACCELERATED DYNAMIC MRI WITH RETROSPECTIVE MOTION CORRECTION AND OUTLIER REJECTION-VAN AMEROM-2018-MAGNETIC RESONANCE IN MEDICINE-WILEY ONLINE LIBRARY,” 2017. HTTPS://ONLINELIBRARY-WILEY-COM.EZPROXY.LIB.RYERSON.CA/DOI/FULL/10.1002/MRM.26686 (ACCESSED Feb. 28, 2021).
9. K. KE ET AL., “QUANTITATIVE MAGNETIC RESONANCE IMAGING PHANTOMS: A REVIEW AND THE NEED FOR A SYSTEM PHANTOM,” MAGN. RESON. MED., VOL. 79, NO. 1, PP. 48-61, January 2018, DOI: 10.1002/MRM.26982.
10. K. YOSHIMURA ET AL., “DEVELOPMENT OF A TISSUE-EQUIVALENT MRI PHANTOM USING CARRAGEENAN GEL,” MAGN. RESON. MED., VOL. 50, NO. 5, PP. 1011-1017, 2003, DOI: 10.1002/MRM. 10619.
11. K. HATTORI ET AL., “DEVELOPMENT OF MRI PHANTOM EQUIVALENT TO HUMAN TISSUES FOR 3.0-T MRI,” MED. PHYS., VOL. 40, NO. 3, 2013, DOI: 10.1118/1.4790023.
12. H. KATO ET AL., “COMPOSITION OF MRI PHANTOM EQUIVALENT TO HUMAN TISSUES,” MED. PHYS., VOL. 32, NO. 10, PP. 3199-3208, 2005, DOI: 10.1118/1.2047807.
13. S. WOOD ET AL., “CORRECTION: DESIGN AND FABRICATION OF A REALISTIC ANTHROPOMORPHIC HETEROGENEOUS HEAD PHANTOM FOR MR PURPOSES (PLOS ONE (2017) 12:8 (E0183168) DOI:
14.A. HELLERBACH, V. SCHUSTER, A. JANSEN, AND J. SOMMER, “MRI PHANTOMS-ARE THERE ALTERNATIVES TO AGAR?,” PLOS ONE, VOL. 8, NO. 8, P. E70343, August 2013, DOI: 10.1371/JOURNAL.PONE.0070343.
15. V. A, B. T, AND R. I, “PHYSICAL IMAGING PHANTOMS FOR SIMULATION OF TUMOR HETEROGENEITY IN PET, CT, AND MRI: AN OVERVIEW OF EXISTING DESIGNS,” MED. PHYS., VOL. 47, NO. 4, PP. 2023-2037, 2020, DOI: 10.1002/MP.14045.
16. F. E AND L. HH, “PHYSICAL AND NUMERICAL PHANTOMS FOR THE VALIDATION OF BRAIN MICROSTRUCTURAL MRI: A COOKBOOK,” NEUROIMAGE, VOL. 182, PP. 39-61, November 2018, DOI: 10.1016/J.NEUROIMAGE.2018.06.046.
17. I. DESPOTOVIĆ, B. GOOSSENS, AND W. PHILIPS, “MRI SEGMENTATION OF THE HUMAN BRAIN: CHALLENGES, METHODS, AND APPLICATIONS,” COMPUT. MATH. METHODS MED., VOL. 2015, 2015, DOI: 10.1155/2015/450341.
18. D. A ET AL., “A HUMAN POST-MORTEM BRAIN MODEL FOR THE STANDARDIZATION OF MULTI-CENTRE MRI STUDIES,” NEUROIMAGE, VOL. 110, PP. 11-21, April 2015, DOI: 10.1016/J.NEUROIMAGE.2015.01.028.
19. C. SJ ET AL., “AN ANTHROPOMORPHIC POLYVINYL ALCOHOL BRAIN PHANTOM BASED ON COLIN27 FOR USE IN MULTIMODAL IMAGING,” MED. PHYS., VOL. 39, NO. 1, PP. 554-561, 2012, DOI: 10.1118/1.3673069.
20. K. J. M. SURRY, H. J. B. AUSTIN, A. FENSTER, AND T. M. PETERS, “POLY (VINYL ALCOHOL) CRYOGEL PHANTOMS FOR USE IN ULTRASOUND AND MR IMAGING,” PHYS. MED. BIOL., VOL. 49, NO. 24, PP. 5529-5546, December 2004, DOI: 10.1088/0031-9155/49/24/009.
21. J. R. RICE, R. H. MILBRANDT, E. L. MADSEN, G. R. FRANK, E. J. BOOTE, AND J. C. BLECHINGER, “ANTHROPOMORPHIC 1H MRS HEAD PHANTOM,” MED. PHYS., VOL. 25, NO. 7, PP. 1145-1156, July 1998, DOI: 10.1118/1.598306.
22. K. AF ET AL., “A NOVEL MRI-COMPATIBLE BRAIN VENTRICLE PHANTOM FOR VALIDATION OF SEGMENTATION AND VOLUMETRY METHODS.,” J. MAGN. RESON. IMAGING, VOL. 36, NO. 2, PP. 476-482, 2012, DOI: 10.1002/JMRI.23612.
23. R. R. GALLAS, N. HÜNEMOHR, A. RUNZ, N. I. NIEBUHR, O. J ÄKEL, AND S. GREILICH, “AN ANTHROPOMORPHIC MULTIMODALITY (CT/MRI) PHANTOM PROTOTYPE FOR END-TO-END TESTS IN RADIATION THERAPY,” Z. MED. PHYS., VOL. 25, NO. 4, PP. 391-399, 2014, DOI: 10.1016/J.ZEMEDI.2015.05.003.
24.A. KOZANA, T. BOURSIANIS, G. KALAITZAKIS, M. RAISSAKI, AND T. G. MARIS, “NEONATAL BRAIN: FABRICATION OF A TISSUE-MIMICKING PHANTOM AND OPTIMIZATION OF CLINICAL T1W AND T2W MRI SEQUENCES AT 1.5 T,” PHYS. MEDICA, VOL. 55, PP. 88-97, November 2018, DOI: 10.1016/J.EJMP.2018.10.022.
25. K. KEENAN, K. F. STUPIC, M. A. BOSS, AND S. E. RUSSEK, “STANDARDIZED PHANTOMS FOR QUANTITATIVE CARDIAC MRI,” J. CARDIOVASC. MAGN. RESON. 2015 171, VOL. 17, NO. 1, PP. 1-2, February 2015, DOI: 10.1186/1532-429X-17-S1-W36.
26. X. YD, P. R, L. J, M. C, Z. ZS, AND Z. SK, “MRI CONTRAST AGENTS: CLASSIFICATION AND APPLICATION (REVIEW),” INT. J. MOL. MED., VOL. 38, NO. 5, PP. 1319-1326, 2016, DOI: 10.3892/IJMM.2016.2744.
27. “RELAXATION TIMES>>IT'IS FOUNDATION.” HTTPS://ITIS.SWISS/VIRTUAL-POPULATION/TISSUE-PROPERTIES/DATABASE/RELAXATION-TIMES/(ACCESSED Aug. 5, 2021).
28. “LIU, V. H. (2014). MAGNETIC RESONANCE IMAGING CONTRAST AGENTS FOR CHEMICAL SENSING (DOCTORAL DISSERTATION, MASSACHUSETTS INSTITUTE OF TECHNOLOGY).” HTTPS://DSPACE.MIT.EDU/HANDLE/1721.1/89844 (ACCESSED Aug. 5, 2021).
29. E. AD, “HOW MUCH CONTRAST IS ENOUGH?. DEPENDENCE OF ENHANCEMENT ON FIELD STRENGTH AND MR PULSE SEQUENCE,” EUR. RADIOL., VOL. 7 SUPPL 5, NO. SUPPL. 5, 1997, DOI: 10.1007/PL00006908.
30. M. SHULMAN ET AL., “QUANTITATIVE ANALYSIS OF FETAL MAGNETIC RESONANCE PHANTOMS AND RECOMMENDATIONS FOR AN ANTHROPOMORPHIC MOTION PHANTOM,” MAGN. RESON. MATER. PHYSICS, BIOL. MED., NO. 0123456789, 2019, DOI: 10.1007/S10334-019-00775-X.
31.C. M. SALAFIA ET AL., “PLACENTAL SURFACE SHAPE, FUNCTION, AND EFFECTS OF MATERNAL AND FETAL VASCULAR PATHOLOGY,” PLACENTA, VOL. 31, NO. 11, PP. 958-962, 2010, DOI: 10.1016/J.PLACENTA.2010.09.005.
32. M. K. YOUNOSZAI AND J. C. HAWORTH, “PLACENTAL DIMENSIONS AND RELATIONS IN PRETERM, TERM, AND GROWTH-RETARDED INFANTS.,” AM. J. OBSTET. GYNECOL., VOL. 103, NO. 2, PP. 265-271, 1969, DOI: 10.1016/S0002-9378 (16) 34400-3.
33. A. HELLERBACH, V. SCHUSTER, A. JANSEN, AND J. SOMMER, “MRI PHANTOMS-ARE THERE ALTERNATIVES TO AGAR?,” VOL. 8, NO. 8, 2013, DOI: 10.1371/JOURNAL.PONE.0070343.
34. M. RABIET, F. BRISSAUD, J. L. SEIDEL, S. PISTRE, AND F. ELBAZ-POULICHET, “POSITIVE GADOLINIUM ANOMALIES IN WASTEWATER TREATMENT PLANT EFFLUENTS AND AQUATIC ENVIRONMENT IN THE HÉRAULT WATERSHED (SOUTH FRANCE),” CHEMOSPHERE, VOL. 75, NO. 8, PP. 1057-1064, 2009, DOI: 10.1016/J.CHEMOSPHERE.2009.01.036.
35. E. M. GALE, I. P. ATANASOVA, F. BLASI, I. AY, AND P. CARAVAN, “A MANGANESE ALTERNATIVE TO GADOLINIUM FOR MRI CONTRAST,” J. AM. CHEM. SOC., VOL. 137, NO. 49, PP. 15548-15557, 2015, DOI: 10.1021/JACS.5B10748.
36. K. HATTORI ET AL., “DEVELOPMENT OF MRI PHANTOM EQUIVALENT TO HUMAN TISSUES FOR 3.0-T MRI,” MED. PHYS., VOL. 40, NO. 3, 2013, DOI: 10.1118/1.4790023.
37. K. YOSHIMURA ET AL., “DEVELOPMENT OF A TISSUE-EQUIVALENT MRI PHANTOM USING CARRAGEENAN GEL,” MAGN. RESON. MED., VOL. 50, NO. 5, PP. 1011-1017, 2003, DOI: 10.1002/MRM.10619.
38. K. E. KEENAN ET AL., “QUANTITATIVE MAGNETIC RESONANCE IMAGING PHANTOMS: A REVIEW AND THE NEED FOR A SYSTEM PHANTOM,” MAGN. RESON. MED., VOL. 79, NO. 1, PP. 48-61, 2018, DOI: 10.1002/MRM.26982.
39. V. FILIPPOU AND C. TSOUMPAS, “RECENT ADVANCES ON THE DEVELOPMENT OF PHANTOMS USING 3D PRINTING FOR IMAGING WITH CT, MRI, PET, SPECT, AND ULTRASOUND,” MED. PHYS., VOL. 45, NO. 9, PP. E740-E760, 2018, DOI: 10.1002/MP.13058.
40. P. GARCIA-POLO ET AL., “AN ANTHROPOMORPHIC MR PHANTOM OF THE GRAVID ABDOMEN INCLUDING THE UTERUS, PLACENTA, FETUS AND FETAL BRAIN,” INT. SOC. MAGN. RESON. MED., NO. MAY, P. 1545, 2015.
41. P. A. HASGALL ET AL., “IT'IS DATABASE FOR THERMAL AND ELECTROMAGNETIC PARAMETERS OF BIOLOGICAL TISSUES, VERSION 4.0,” IT′IS, 2018.
42. S. K. SEHMI, E. ALLAN, A. J. MACROBERT, AND I. PARKIN, “THE BACTERICIDAL ACTIVITY OF GLUTARALDEHYDE-IMPREGNATED POLYURETHANE,” MICROBIOLOGYOPEN, VOL. 5, NO. 5, PP. 891-897, 2016, DOI: 10.1002/MBO3.378.
43. CENTERS FOR DISEASE CONTROL AND PREVENTION, “GUIDELINE FOR DISINFECTION AND STERILIZATION IN HEALTHCARE FACILITIES, 2008; MISCELLANEOUS INACTIVATING AGENTS,” CDC WEBSITE, NO. MAY, PP. 9-13, 2013, [ONLINE]. AVAILABLE: HTTP://WWW.CDC.GOV/HICPAC/DISINFECTION_STERILIZATION/10_OMI SCAGENTS.HTML.
44. M. COUNOTTE, “TOXICOLOGISCH RAPPORT,” NO. DECEMBER, PP. 1-51, 2017.
45. C. M. SALAFIA ET AL., “PLACENTAL SURFACE SHAPE, FUNCTION, AND EFFECTS OF MATERNAL AND FETAL VASCULAR PATHOLOGY,” PLACENTA, VOL. 31, NO. 11, PP. 958-962, 2010, DOI: 10.1016/J.PLACENTA.2010.09.005.
46. A. P. VALERGA, M. BATISTA, J. SALGUERO, AND F. GIROT, “INFLUENCE OF PLA FILAMENT CONDITIONS ON CHARACTERISTICS OF FDM PARTS,” MATERIALS (BASEL)., VOL. 11, NO. 8, 2018, DOI: 10.3390/MA11081322.
47. Y. DWIHAPSARI, E. ASDIANTORO, AND N. MAULIDIYAH, “T2 QUANTIFICATION OF AGAROSE WITH CONTRAST AGENT IN MAGNETIC RESONANCE IMAGING,” J. PHYS. CONF. SER., VOL. 1505, NO. 1, 2020, DOI: 10.1088/1742-6596/1505/1/012044.
48. D. HAO, T. AI, F. GOERNER, X. HU, V. M. RUNGE, AND M. TWEEDLE, “REVIEW: MR PHYSICS FOR CLINICIANS MRI CONTRAST AGENTS: BASIC CHEMISTRY AND SAFETY,” DOI: 10.1002/JMRI.23725.
49. P. BRZOZOWSKI, “TISSUE EQUIVALENT GELLAN GUM GEL MATERIALS FOR CLINICAL MRI AND RADIATION DOSIMETRY,” NO. April 2019.
50. V. JACQUES, S. DUMAS, W.-C. SUN, J. S. TROUGHTON, M. T. GREENFIELD, AND P. CARAVAN, “HIGH RELAXIVITY MRI CONTRAST AGENTS PART 2: OPTIMIZATION OF INNER-AND SECOND-SPHERE RELAXIVITY,” INVEST RADIOL, VOL. 45, NO. 10, PP. 613-624, 2010, DOI: 10.1097/RLI.0B013E3181EE6A49.
51. J. T. NOFIELE AND H. L. M. CHENG, “ULTRASHORT ECHO TIME FOR IMPROVED POSITIVE-CONTRAST MANGANESE-ENHANCED MRI OF CANCER,” PLOS ONE, VOL. 8, NO. 3, 2013, DOI: 10.1371/JOURNAL.PONE.0058617.
52. T. G. ST PIERRE, P. R. CLARK, AND W. CHUA-ANUSORN, “SINGLE SPIN-ECHO PROTON TRANSVERSE RELAXOMETRY OF IRON-LOADED LIVER,” NMR BIOMED. NMR BIOMED, VOL. 17, PP. 446-458, 2004, DOI: 10.1002/NBM.905.
53. C. ANDERSEN AND F. T. JENSEN, “PRECISION, ACCURACY, AND IMAGE PLANE UNIFORMITY IN NMR RELAXATION TIME IMAGING ON A 1.5 T WHOLE-BODY MR IMAGING SYSTEM,” MAGN. RESON. IMAGING, VOL. 12, NO. 5, PP. 775-784, January 1994, DOI: 10.1016/0730-725X (94) 92202-0.
54. K. THANGAVEL AND E. Ü. SARITAŞ, “AQUEOUS PARAMAGNETIC SOLUTIONS FOR MRI PHANTOMS AT 3 T: A DETAILED STUDY ON RELAXIVITIES,” TURKISH J. ELECTR. ENG. COMPUT. SCI., VOL. 25, NO. 3, PP. 2108-2121, 2017, DOI: 10.3906/ELK-1602-123.
55. G. J. STANISZ ET AL., “T1, T2 RELAXATION AND MAGNETIZATION TRANSFER IN TISSUE AT 3T,” MAGN. RESON. MED., VOL. 54, NO. 3, PP. 507-512, 2005, DOI: 10.1002/MRM.20605.
56. E. CHO, “DEVELOPMENT OF ANTHROPOMORPHIC FETAL MRI PHANTOM,” RYERSON UNVIVERSITY, 2021.
57. D. BULAS AND A. EGLOFF, “BENEFITS AND RISKS OF MRI IN PREGNANCY,” SEMIN. PERINATOL., VOL. 37, NO. 5, PP. 301-304, October 2013, DOI: 10.1053/J.SEMPERI.2013.06.005.
58. R. GUPTA ET AL., “MAGNETIC RESONANCE IMAGING-A TROUBLESHOOTER IN OBSTETRIC EMERGENCIES: A PICTORIAL REVIEW,” INDIAN J. RADIOL. IMAGING, VOL. 26, NO. 1, PP. 44-51, March 2016, DOI: 10.4103/0971-3026.178292.
59. A. GHOLIPOUR, J. A. ESTROFF, AND S. K. WARFIELD, “ROBUST SUPER-RESOLUTION VOLUME RECONSTRUCTION FROM SLICE ACQUISITIONS: APPLICATION TO FETAL BRAIN MRI,” IEEE TRANS. MED. IMAGING, VOL. 29, NO. 10, PP. 1739-1758, October 2010, DOI: 10.1109/TMI.2010.2051680.
60. A. GHOLIPOUR ET AL., “FETAL MRI: A TECHNICAL UPDATE WITH EDUCATIONAL ASPIRATIONS,” CONCEPTS MAGN. RESON. PART BRIDG. EDUC. RES., VOL. 43, NO. 6, PP. 237-266, November 2014, DOI: 10.1002/CMR.A.21321.
61. M. S. JANSZ ET AL., “METRIC OPTIMIZED GATING FOR FETAL CARDIAC MRI,” MAGN. RESON. MED., VOL. 64, NO. 5, PP. 1304-1314, November 2010, DOI: 10.1002/MRM.22542.
62.A. HELLERBACH, V. SCHUSTER, A. JANSEN, AND J. SOMMER, “MRI PHANTOMS-ARE THERE ALTERNATIVES TO AGAR?,” PLOS ONE, VOL. 8, NO. 8, August 2013, DOI: 10.1371/JOURNAL.PONE.0070343.
63. J. S. HUBER, Q. PENG, AND W. W. MOSES, “MULTI-MODALITY PHANTOM DEVELOPMENT,” JANUARY 2007, VOL. 56, PP. 2944-2948, DOI: 10.1109/NSSMIC.2007.4436751.
64. E. OHMAE ET AL., “STABLE TISSUE-SIMULATING PHANTOMS WITH VARIOUS WATER AND LIPID CONTENTS FOR DIFFUSE OPTICAL SPECTROSCOPY,” BIOMED. OPT. EXPRESS, VOL. 9, NO. 11, PP. 5792-588, November 2018, DOI: 10.1364/BOE.9.005792.
65. V. S. VASSILIOU ET AL., “MAGNETIC RESONANCE IMAGING PHANTOMS FOR QUALITY-CONTROL OF MYOCARDIAL T1 AND ECV MAPPING: SPECIFIC FORMULATION, LONG-TERM STABILITY AND VARIATION WITH HEART RATE AND TEMPERATURE,” J. CARDIOVASC. MAGN. RESON. OFF. J. SOC. CARDIOVASC. MAGN. RESON., VOL. 18, NO. 1, P. 62, September 2016, DOI: 10.1186/S12968-016-0275-9.
66. E. IN, “DEVELOPMENT OF POLYMER-BASED GELS FOR MULTIMODAL MEDICAL IMAGING PHANTOMS,” THESIS, 2016.
67.I. MANO, H. GOSHIMA, M. NAMBU, AND M. IIO, “NEW POLYVINYL ALCOHOL GEL MATERIAL FOR MRI PHANTOMS,” MAGN. RESON. MED., VOL. 3, NO. 6, PP. 921-926, December 1986, DOI: 10.1002/MRM. 1910030612.
68. C. CHEUNG, T. LOOI, J. DRAKE, AND P. KIM, “MAGNETIC RESONANCE IMAGING PROPERTIES OF MULTIMODALITY ANTHROPOMORPHIC SILICONE RUBBER PHANTOMS FOR VALIDATING SURGICAL ROBOTS AND IMAGE GUIDED THERAPY SYSTEMS,” VOL. 8316, P. 67, February 2012, DOI: 10.1117/12.908274.
69. K. HATTORI ET AL., “DEVELOPMENT OF MRI PHANTOM EQUIVALENT TO HUMAN TISSUES FOR 3.0-T MRI,” MED. PHYS., VOL. 40, NO. 3, P. 032303, March 2013, DOI: 10.1118/1.4790023.
70. K. J. M. SURRY, H. J. B. AUSTIN, A. FENSTER, AND T. M. PETERS, “POLY (VINYL ALCOHOL) CRYOGEL PHANTOMS FOR USE IN ULTRASOUND AND MR IMAGING,” PHYS. MED. BIOL., VOL. 49, NO. 24, PP. 5529-5546, December 2004, DOI: 10.1088/0031-9155/49/24/009.
71. F. ADAMS ET AL., “SOFT 3D-PRINTED PHANTOM OF THE HUMAN KIDNEY WITH COLLECTING SYSTEM,” ANN. BIOMED. ENG., VOL. 45, November 2016, DOI: 10.1007/S10439-016-1757-5.
72. N. KOKABI, W. BAE, E. DIAZ, C. B. CHUNG, G. M. BYDDER, AND J. DU, “ULTRASHORT TE MR IMAGING OF BOVINE CORTICAL BONE: THE EFFECT OF WATER LOSS ON THE T1 AND T2* RELAXATION TIMES,” MAGN. RESON. MED., VOL. 66, NO. 2, PP. 476-482, August 2011, DOI: 10.1002/MRM.22859.
73. J. T. BUSHBERG, J. A. SEIBERT, E. M. LEIDHOLDT, AND J. M. BOONE, THE ESSENTIAL PHYSICS OF MEDICAL IMAGING. LIPPINCOTT WILLIAMS & WILKINS, 2011.
74. [R. LOWRY, “ANALYSIS OF COVARIANCE.” HTTP://VASSARSTATS.NET/VSANCOVA.HTML (ACCESSED Nov. 19, 2020).
75. S. WALDMAN, C. SPITERI, M. GRYNPAS, R. PILLIAR, AND R. KANDEL, “LONG-TERM INTERMITTENT SHEAR DEFORMATION IMPROVES THE QUALITY OF CARTILAGINOUS TISSUE FORMED IN VITRO,” J. ORTHOP. RES. OFF. PUBL. ORTHOP. RES. SOC., VOL. 21, PP. 590-6, August 2003, DOI: 10.1016/S0736-0266 (03) 00009-3.
76. S. D. WALDMAN, D. C. COUTO, M. D. GRYNPAS, R. M. PILLIAR, AND R. A. KANDEL, “A SINGLE APPLICATION OF CYCLIC LOADING CAN ACCELERATE MATRIX DEPOSITION AND ENHANCE THE PROPERTIES OF TISSUE-ENGINEERED CARTILAGE,” OSTEOARTHRITIS CARTILAGE, VOL. 14, NO. 4, PP. 323-330, April 2006, DOI: 10.1016/J.JOCA.2005.10.007.
77.S. D. WALDMAN, D. C. COUTO, M. D. GRYNPAS, R. M. PILLIAR, AND R. A. KANDEL, “MULTI-AXIAL MECHANICAL STIMULATION OF TISSUE ENGINEERED CARTILAGE: REVIEW,” EUR. CELL. MATER., VOL. 13, PP. 66-73; DISCUSSION 73-74, April 2007, DOI: 10.22203/ECM.V013A07.
78. H. I. MÄKELÄ, O. H. GRÖHN, M. I. KETTUNEN, AND R. A. KAUPPINEN, “PROTON EXCHANGE AS A RELAXATION MECHANISM FOR T1 IN THE ROTATING FRAME IN NATIVE AND IMMOBILIZED PROTEIN SOLUTIONS,” BIOCHEM. BIOPHYS. RES. COMMUN., VOL. 289, NO. 4, PP. 813-818, December 2001, DOI: 10.1006/BBRC.2001.6058.
79. R. I. CHELCEA, R. FECHETE, E. CULEA, D. E. DEMCO, AND B. BLUMICH, “DISTRIBUTIONS OF TRANSVERSE RELAXATION TIMES FOR SOFT-SOLIDS MEASURED IN STRONGLY INHOMOGENEOUS MAGNETIC FIELDS,” J. MAGN. RESON., VOL. 196, NO. 2, PP. 178-190, February 2009, DOI: 10.1016/J.JMR.2008.11.004.
80. Y. DWIHAPSARI, E. ASDIANTORO, AND N. MAULIDIYAH, “T2 QUANTIFICATION OF AGAROSE WITH CONTRAST AGENT IN MAGNETIC RESONANCE IMAGING,” J. PHYS. CONF. SER., VOL. 1505, P. 012044, March 2020, DOI: 10.1088/1742-6596/1505/1/012044.
81. AD ELSTER, “GADOLINIUM AND T1,” QUESTIONS AND ANSWERS IN MRI. HTTP://MRIQUESTIONS.COM/WHY-DOES-GD-SHORTEN-T1.HTML (ACCESSED Nov. 19, 2020)
82. M. ROHRER, H. BAUER, J. MINTOROVITCH, M. REQUARDT, AND H.-J. WEINMANN, “COMPARISON OF MAGNETIC PROPERTIES OF MRI CONTRAST MEDIA SOLUTIONS AT DIFFERENT MAGNETIC FIELD STRENGTHS,” INVEST. RADIOL., VOL. 40, NO. 11, PP. 715-724, November 2005, DOI: 10.1097/01.RLI.0000184756.66360.D3.
83. O. A. GLENN, “MR IMAGING OF THE FETAL BRAIN,” PEDIATR. RADIOL., VOL. 40, NO. 1, PP. 68-81, January 2010, DOI: 10.1007/S00247-009-1459-3.
84. LIU X, QUAN S, FUY, ET AL. STUDY ON AMNIOTIC FLUID METABOLISM IN THE SECOND TRIMESTER OF TRISOMY 21. J CLIN LAB ANAL. 2020; 34 (3): E23089. DOI: 10.1002/JCLA.23089
85. STORY L, DAMODARAM MS, ALLSOP J M, ET AL. BRAIN METABOLISM IN FETAL INTRAUTERINE GROWTH RESTRICTION: A PROTON MAGNETIC RESONANCE SPECTROSCOPY STUDY. AM J OBSTET GYNECOL. 2011; 205 (5): 483.E1-483.E8. DOI: 10.1016/J.AJOG.2011.06.032
86. CROITOR-SAVA A, BECK V, SANDAITE I, ET AL. HIGH-RESOLUTION 1H NMR SPECTROSCOPY DISCRIMINATES AMNIOTIC FLUID OF FETUSES WITH CONGENITAL DIAPHRAGMATIC HERNIA FROM HEALTHY CONTROLS. J PROTEOME RES. 2015; 14(11): 4502-4510. DOI: 10.1021/ACS.JPROTEOME.5B00131
87. GRAçA G, DUARTE IF, GOODFELLOW BJ, ET AL. POTENTIAL OF NMR SPECTROSCOPY FOR THE STUDY OF HUMAN AMNIOTIC FLUID. ANAL CHEM. 2007; 79 (21): 8367-8375. DOI: 10.1021/AC071278D
88. BONSNES R. COMPOSITION OF AMNIOTIC FLUID. CLIN OBSTET GYNECOL. 1966; 9(2): 440-448.
89. EMWAS A H M, SALEK R M, GRIFFIN J L, MERZABAN J. NMR-BASED METABOLOMICS IN HUMAN DISEASE DIAGNOSIS: APPLICATIONS, LIMITATIONS, AND RECOMMENDATIONS. METABOLOMICS. 2013; 9 (5): 1048-1072. DOI: 10.1007/S11306-013-0524-Y
90. SIMS C J, FUJITOT D T, BURHOLT D R, DADOKF J, ALLAN WILKINSON D. QUANTIFICATION OF HUMAN AMNIOTIC FLUID CONSTITUENTS BY HIGH RESOLUTION PROTON NUCLEAR MAGNETIC RESONANCE (NMR) SPECTROSCOPY. VOL 13.; 1993:473480-473480.
91. TARA F, LOTFALIZADEH M, MOEINDARBARI S. THE EFFECT OF DIAGNOSTIC AMNIOCENTESIS AND ITS COMPLICATIONS ON EARLY SPONTANEOUS ABORTION. ELECTRON PHYSICIAN. 2016; 8 (8): 2787-2792. DOI: 10.19082/2787
92. DUARTE IF, GOODFELLOW BJ, BARROS A, ET AL. METABOLIC CHARACTERISATION OF PLASMA IN JUVENILES WITH GLYCOGEN STORAGE DISEASE TYPE 1A (GSD1A) BY HIGH-RESOLUTION 1H NMR SPECTROSCOPY. NMR BIOMED. 2007; 20 (4): 401-412. DOI: 10.1002/NBM.1073
93. CIURLEO R, DI LORENZO G, BRAMANTI P, MARINO S. MAGNETIC RESONANCE SPECTROSCOPY: AN IN VIVO MOLECULAR IMAGING BIOMARKER FOR PARKINSON'S DISEASE? BIOMED RES INT. 2014; 2014. DOI: 10.1155/2014/519816
94. GRAçA G, DUARTE I F, BARROS A S, ET AL. 1H NMR BASED METABONOMICS OF HUMAN AMNIOTIC FLUID FOR THE METABOLIC CHARACTERIZATION OF FETUS MALFORMATIONS. J PROTEOME RES. 2009; 8 (8): 4144-4150. DOI: 10.1021/PR900386F
95. EMWAS A H, ROY R, MCKAY R T, ET AL. NMR SPECTROSCOPY FOR METABOLOMICS RESEARCH. METABOLITES. 2019; 9 (7). DOI: 10.3390/METABO9070123
96. RISK OF MISCARRIAGE FOLLOWING AMNIOCENTESIS OR CHORIONIC VILLUS SAMPLING: SYSTEMATIC REVIEW OF LITERATURE AND UPDATED META-ANALYSIS-SALOMON-2019-ULTRASOUND IN OBSTETRICS &AMP; GYNECOLOGY-WILEY ONLINE LIBRARY. ACCESSED Jul. 28, 2021. HTTPS://OBGYN.ONLINELIBRARY.WILEY.COM/DOI/FULL/10.1002/UOG.2 0353?CAMPAIGN=WOLEARLYVIEW
97. NILSSON S, RAMSTROM M, PALMBLAD M, AXELSSON O, BERGQUIST J. EXPLORATIVE STUDY OF THE PROTEIN COMPOSITION OF AMNIOTIC FLUID BY LIQUID CHROMATOGRAPHY ELECTROSPRAY IONIZATION FOURIER TRANSFORM ION CYCLOTRON RESONANCE MASS SPECTROMETRY. J PROTEOME RES. 2004; 3 (4): 884-889. DOI: 10.1021/PR0499545
98. GRAçA G, MOREIRA A S, CORREIA A J V, ET AL. MID-INFRARED (MIR) METABOLIC FINGERPRINTING OF AMNIOTIC FLUID: A POSSIBLE AVENUE FOR EARLY DIAGNOSIS OF PRENATAL DISORDERS? ANAL CHIM ACTA. 2013; 764:24-31. DOI: 10.1016/J.ACA.2012.12.023
99. REID D W J, CAMPBELL D J, YAKYMYSHYN L Y. QUANTITATIVE AMINO ACIDS IN AMNIOTIC FLUID AND MATERNAL PLASMA IN EARLY AND LATE PREGNANCY. PRELIMINARY REPORT. AM J OBSTET GYNECOL. 1971; 111(2): 251-258. DOI: 10.1016/0002-9378 (71) 90898-2.
100. SELI E, BOTROS L, SAKKAS D, BURNS D H. NONINVASIVE METABOLOMIC PROFILING OF EMBRYO CULTURE MEDIA USING PROTON NUCLEAR MAGNETIC RESONANCE CORRELATES WITH REPRODUCTIVE POTENTIAL OF EMBRYOS IN WOMEN UNDERGOING IN VITRO FERTILIZATION. FERTIL STERIL. 2008; 90(6): 2183-2189. DOI: 10.1016/J.FERTNSTERT.2008.07.1739
101. BENEDUCI A, CHIDICHIMO G, DARDO G, PONTONI G. HIGHLY ROUTINELY REPRODUCIBLE ALIGNMENT OF 1H NMR SPECTRAL PEAKS OF METABOLITES IN HUGE SETS OF URINES. ANAL CHIM ACTA. 2011; 685 (2): 186-195. DOI: 10.1016/J.ACA.2010.11.027
102. CASTILLO A M, BERNAL A, PATINY L, WIST J. A NEW METHOD FOR THE COMPARISON OF 1H NMR PREDICTORS BASED ON TREE-SIMILARITY OF SPECTRA. J CHEMINFORMATICS. 2014; 6 (1): 9-9. DOI: 10.1186/1758-2946-6-9
103. WIND R A, HU J Z. IN VIVO AND EX VIVO HIGH-RESOLUTION 1H NMR IN BIOLOGICAL SYSTEMS USING LOW-SPEED MAGIC ANGLE SPINNING. PROG NUCL MAGN RESON SPECTROSC. 2006; 49(3-4): 207-259. DOI: 10.1016/J.PNMRS.2006.05.003
104. BOLAN P J, NELSON M T, YEE D, GARWOOD M. IMAGING IN BREAST CANCER: MAGNETIC RESONANCE SPECTROSCOPY. BREAST CANCER RES. 2005; 7(4): 149-152. DOI: 10.1186/BCR1202
105. KUMAR V, DWIVEDI D K, JAGANNATHAN N R. HIGH-RESOLUTION NMR SPECTROSCOPY OF HUMAN BODY FLUIDS AND TISSUES IN RELATION TO PROSTATE CANCER. NMR BIOMED. 2014; 27 (1): 80-89. DOI: 10.1002/NBM.2979
106. WIND R A, HU J Z. IN VIVO AND EX VIVO HIGH-RESOLUTION 1H NMR IN BIOLOGICAL SYSTEMS USING LOW-SPEED MAGIC ANGLE SPINNING. PROG NUCL MAGN RESON SPECTROSC. 2006; 49(3-4): 207-259. DOI: 10.1016/J.PNMRS.2006.05.003
107. WIND R A, HU J Z, MAJORS P D. LOCALIZED IN VIVO ISOTROPIC-ANISOTROPIC CORRELATION1H NMR SPECTROSCOPY USING ULTRASLOW MAGIC ANGLE SPINNING. MAGN RESON MED. 2006; 55(1): 41-49. DOI: 10.1002/MRM.20740
108. MARSHALL DD, POWERS R. BEYOND THE PARADIGM: COMBINING MASS SPECTROMETRY AND NUCLEAR MAGNETIC RESONANCE FOR METABOLOMICS. PROG NUCL MAGN RESON SPECTROSC. 2017; 100:1-16. DOI: 10.1016/J.PNMRS.2017.01.001
109. BOCK J L. METABOLIC PROFILINGOF AMNIOTIC FLUID BY PROTON NUCLEAR MAGNETIC RESONANCE SPECTROSCOPY: CORRELATION WITH FETAL MATURATION AND OTHER CLINICAL VARIABLES. VOL 40.; 1994:56-61.
110. GHOSH BISWAS R, FORTIER-MCGILL B, AKHTER M, ET AL. EX VIVO COMPREHENSIVE MULTIPHASE NMR OF WHOLE ORGANISMS: A COMPLEMENTARY TOOL TO IN VIVO NMR. ANAL CHIM ACTA X. 2020; 6:100051. DOI: 10.1016/J.ACAX.2020.100051
111. LE MOYEC ‘FRANGOISE MULLER LAURENCE, EUGENE’ MICHEL, SPRAUL3 M. PROTON MAGNETIC RESONANCE SPECTROSCOPY OF HUMAN AMNIOTIC FLUIDS SAMPLED AT 17-18 WEEKS OF PREGNANCY IN CASES OF DECREASED DIGESTIVE ENZYME ACTIVITIES AND DETECTED CYSTIC FIBROSIS. VOL 27.; 1994:475-483.
112. GABBAY R, YOGEV Y, MELAMED N, BEN-HAROUSH A, MEIZNER I, PARDO J. PREGNANCY OUTCOME AFTER THIRD TRIMESTER AMNIOCENTESIS: A SINGLE CENTER EXPERIENCE. J MATERN FETAL NEONATAL MED. 2012; 25 (6): 666-668. DOI: 10.3109/14767058.2011.594119.
113. MCGOWAN P E, REGLINSKI J, WILSON R, WALKER J J, WISDOMS S, MCKILLOP JH. QUANTITATIVE 1H-NMR ANALYSIS OF AMNIOTIC FLUID. J PHARM BIOMED ANAL. 1993; 11 (8): 629-632. DOI: 10.1016/0731-7085 (93) 80167-Y
114. LIND T, BILLEWICZ W Z, CHEYNE G A. COMPOSITION OF AMNIOTIC FLUID AND MATERNAL BLOOD THROUGH PREGNANCY. J OBSTET GYNAECOL BR COMMONW. 1971; 78(6): 505-512. DOI: 10.1111/J.1471-0528.1971.TB00308.X
115. COHN B R, JOE B N, ZHAO S, ET AL. QUANTITATIVE METABOLIC PROFILES OF 2ND AND 3RD TRIMESTER HUMAN AMNIOTIC FLUID USING 1H HR-MAS SPECTROSCOPY. MAGN RESON MATER PHYS BIOL MED. 2009; 22 (6): 343-352. DOI: 10.1007/S10334-009-0184-0
116. LEVY H L, MONTAG P P. A QUANTITATIVE STUDY BY ION-EXCHANGE CHROMATOGRAPHY. VOL 3.; 1969:13-120.
117. COCKBURN F, GILES M, ROBINS S P, FORFAR J O. THE JOURNAL OF OBSTETRICS AND GYNAECOLOGY OF THE BRITISH COMMONWEALTH. VOL 80.; 1973:10-18.
118. UNDERWOOD M A, GILBERT W M, SHERMAN M P. AMNIOTIC FLUID: NOT JUST FETAL URINE ANYMORE. J PERINATOL. 2005; 25(5): 341-348. DOI: 10.1038/SJ.JP.7211290.
119. NELSON T R, GILLIES R J, POWELL D A, SCHRADER M C, MANCHESTERS D K, PRETORIUS D H. HIGH RESOLUTION PROTON NMR SPECTROSCOPY OF HUMAN AMNIOTIC FLUID. PRENAT DIAGN. 1987; 7(5): 363-372. DOI: 10.1002/PD.1970070511.
120. GRAçA G, GOODFELLOW B J, BARROS A S, ET AL. UPLC-MS METABOLIC PROFILING OF SECOND TRIMESTER AMNIOTIC FLUID AND MATERNAL URINE AND COMPARISON WITH NMR SPECTRAL PROFILING FOR THE IDENTIFICATION OF PREGNANCY DISORDER BIOMARKERS. MOL BIOSYST. 2012; 8 (4): 1243-1254.DOI: 10.1039/C2MB05424H.
121. MILES P, MAJ, MC, PEARSON J. AMNIOTIC FLUID OSMOLALITY IN ASSESSING FETAL MATURITY. OBSTET GYNECOL. 1969; 34(5): 701-706.
122. KOSAKA A, AIDA M, KATSUMOTO Y. RECONSIDERING THE ACTIVATION ENTROPY FOR ANOMERIZATION OF GLUCOSE AND MANNOSE IN WATER STUDIED BY NMR SPECTROSCOPY. J MOL STRUCT. 2015; 1093:195-200. DOI: 10.1016/J.MOLSTRUC.2015.03.038.
123. SARIGUL N, KORKMAZ F, KURULTAK i. A NEW ARTIFICIAL URINE PROTOCOL TO BETTER IMITATE HUMAN URINE. SCI REP. 2019; 9 (1): 1-11. DOI: 10.1038/S41598-019-56693-4.
124. ORCZYK-PAWILOWICZ M, JAWIEN E, DEJA S, HIRNLE L, ZABEK A, MLYNARZ P. METABOLOMICS OF HUMAN AMNIOTIC FLUID AND MATERNAL PLASMA DURING NORMAL PREGNANCY. PLOS ONE. 2016; 11 (4). DOI: 10.1371/JOURNAL.PONE.0152740.
125. HANIFA M A, MALTESEN R G, BODIL., ET AL. CITRATE NMR PEAK IRREPRODUCIBILITY IN BLOOD SAMPLES AFTER REACQUISITION OF SPECTRA. METABOLOMICS. 123AD; 16:7-7. DOI: 10.1007/S11306-019-1629-8.
126. LAURIDSEN M, HANSEN S H, JAROSZEWSKI J W, CORNETT C. HUMAN URINE AS TEST MATERIAL IN 1H NMR-BASED METABONOMICS: RECOMMENDATIONS FOR SAMPLE PREPARATION AND STORAGE. ANAL CHEM. 2007; 79 (3): 1181-1186. DOI: 10.1021/AC061354X.
127. AMORINI A, GIORLANDINO C, LONGO S, ET AL. METABOLIC PROFILE OF AMNIOTIC FLUID AS A BIOCHEMICAL TOOL TO SCREEN FOR INBORN ERRORS OF METABOLISM AND FETAL ANOMALIES. MOL CELL BIOCHEM. 2011; 359:205-216. DOI: 10.1007/S11010-011-1015-Y.
128. WEIGER M, SPECK T. SHIMMING FOR HIGH-RESOLUTION NMR SPECTROSCOPY. IN: ENCYCLOPEDIA OF MAGNETIC RESONANCE. JOHN WILEY & SONS, LTD; 2011. DOI: 10.1002/9780470034590.EMRSTM1228
129. J. STOUT ET AL., “T1 AND T2 MAPPING OF THE PLACENTA AND FETAL BRAIN WITH MAGNETIC RESONANCE FINGERPRINTING (MRF) DURING MATERNAL HYPEROXIA,” ISMRM, 2019.
130. GAGOSKI, B., PARK, D. J., RENVALL, V., ABACI-TURK, E., ADALSTEINSSON, E., WITZEL, T., WALD, L. L., GRANT, P. E., POLIMENI, J., “FETAL T1 MAPPING USING MULTI-INVERSION EPI AT 3T”, ISMRM ABSTRACTS, NO. 5423 (2018).

1. A gravid abdomen phantom comprising:
a motion assembly; and
a fetal phantom mounted to the motion assembly,
wherein the motion assembly is operable to simulate the movement of a prenatal fetus.

2. The gravid abdomen phantom of claim 1 further comprising a tank that is insertable into a bore of a magnetic resonance imaging scanner and the fetal phantom is positioned in the tank.

3. The gravid abdomen phantom of claim 2, wherein the motion assembly comprises
a motion platform for supporting the fetal phantom;
at least one actuator for controlling movement of the motion platform; and
at least one driving linkage extending between the at least one actuator and the motion platform,
wherein the motion platform is mounted to the tank for housing the fetal phantom.

4. The gravid abdomen phantom of claim 1, wherein the fetal phantom comprises a brain phantom and a body phantom.

5. The gravid abdomen phantom of claim 4, wherein the brain phantom comprises a brain grey matter mimicking material and a brain white matter mimicking material.

6.-127. (canceled)

128. A motion assembly for a gravid abdomen phantom having a fetal phantom, wherein the motion assembly comprises:
a motion platform for supporting the fetal phantom;
at least one actuator for controlling movement of the motion platform; and
at least one driving linkage extending between the at least one actuator and the motion platform,
wherein the motion platform is mounted to a tank for housing the fetal phantom and is insertable into a bore of a magnetic resonance imaging scanner.

129. The motion assembly of claim 128, wherein each actuator of the at least one actuator is external to the tank and each driving linkage of the at least one driving linkage extends through at least one of a respective port in the tank and an open end of the tank.

130. The motion assembly of claim 128, wherein the at least one actuator is drivingly connected to the motion platform by the at least one driving linkage to move the motion platform with at least one degree of freedom.

131. The motion assembly of claim 128, wherein the motion platform is submerged within a volume of fluid within the tank, optionally the fluid is an artificial amniotic fluid of the present disclosure.

132. The motion assembly of claim 128, wherein each actuator of the at least one actuator is at least one of a hydraulic actuator, a pneumatic actuator, a piezoelectric motor, and a stepper motor.

133. The motion assembly of claim 128, further comprising the fetal phantom drivingly mounted to the motion platform.

134. The motion assembly of claim 133, wherein the motion platform comprises a rod with an end that is insertable into a cavity of the fetal phantom for mounting the fetal phantom to the motion platform, optionally further comprising an adhesive for securing the fetal phantom to the rod.

135. (canceled)

136. The motion assembly of claim 128, further comprising a pump and a tube extendable from the pump to the fetal phantom, wherein the pump is adapted for urging at least one of air and artificial amniotic fluid through the tube for producing a respiratory motion in the fetal phantom, optionally wherein the pump is external to the tank and the tube extends through a respective port in the tank.

137. (canceled)

138. The motion assembly of claim 128, wherein the motion assembly comprises six actuators and six driving linkages wherein each actuator is operatively coupled one of the six driving linkages.

139. (canceled)

140. (canceled)

141. A gravid abdomen phantom comprising:
a tank that is insertable into a bore of a magnetic resonance imaging scanner;
a motion assembly; and
a fetal phantom positioned in the tank and mounted to the motion assembly, wherein the motion assembly is operable to simulate the movement of a prenatal fetus.

142. The gravid abdomen phantom of claim 141, further comprising a volume of artificial amniotic fluid held within the tank, optionally the artificial amniotic fluid comprises an amniotic fluid mimicking composition.

143. The gravid abdomen phantom of claim 141, further comprising a placenta phantom supported within the tank.

144. The gravid abdomen phantom of claim 143, wherein the placenta phantom is supported by at least one of a top wall and a bottom wall of the tank.

145. The gravid abdomen phantom of claim 141, wherein the motion assembly is defined according to claim 128.
